(19) United States
(12) Patent Application Publication
(10) Pub. No.: US 2025/0098439 A1
(43) Pub. Date: Mar. 20, 2025

(54) DISPLAY APPARATUS

(71) Applicant: Semiconductor Energy Laboratory Co., Ltd., Atsugi-shi, Kanagawa-ken (JP)

(72) Inventors: Yasuharu HOSAKA, Tochigi (JP); Yukinori SHIMA, Tatebayashi (JP); Masami JINTYOU, Shimotsuga (JP); Masataka NAKADA, Tochigi (JP); Junichi KOEZUKA, Tochigi (JP); Kenichi OKAZAKI, Atsugi (JP)

(21) Appl. No.: 18/729,577

(22) PCT Filed: Jan. 17, 2023
(86) PCT No.: PCT/IB2023/050379

§ 371 Date: Jul. 17, 2024

(30) Foreign Application Priority Data
Jan. 31, 2022 (JP) 2022-013380

(51) Int. Cl. H10K 59/124; H10K 59/123

(52) U.S. Cl. CPC H10K 59/124; H10K 59/123

(57) ABSTRACT

A display apparatus with high definition is provided. The display apparatus includes a transistor, a light-emitting device and a first insulating layer. The transistor includes a semiconductor layer, first to third conductive layers, and second and third insulating layers. The second insulating layer is provided over the first conductive layer and includes a first opening reaching the first conductive layer. The second conductive layer is provided over the second insulating layer and includes a second opening in a region overlapping with the first opening. The semiconductor layer is in contact with the top surface of the first conductive layer, the side surface of the second insulating layer, and the top surface and the side surface of the second conductive layer. The third insulating layer is provided over the semiconductor layer. The third conductive layer is provided over the third insulating layer. The first insulating layer is provided over the transistor. The first insulating layer and the third insulating layer include a third opening reaching the second conductive layer. The light-emitting device is provided over the first insulating layer and includes a pixel electrode, a common electrode, and an EL layer. The pixel electrode is electrically connected to the second conductive layer through the third opening. The EL layer includes a region in contact with the top surface and the side surface of the pixel electrode.

### TECHNICAL FIELD

One embodiment of the present invention relates to a display apparatus, a display module, and an electronic device. One embodiment of the present invention relates to a manufacturing method of a display apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a method of driving any of them, and a manufacturing method of any of them.

### BACKGROUND ART

Display apparatuses have been expected to be applied to a variety of uses. Usage examples of large-sized display apparatuses include a television device for home use (also referred to as TV or television receiver), digital signage, and a PID (Public Information Display). In addition, a smartphone and a tablet terminal each including a touch panel, and the like, are being developed as portable information terminals.

In recent years, display apparatuses for virtual reality (VR), augmented reality (AR), substitutional reality (SR), and mixed reality (MR) have been desired. VR, AR, SR, and MR are collectively referred to as extended reality (XR). Display apparatuses for XR have been expected to have higher definition and higher color reproducibility so that the sense of reality and the sense of immersion can be enhanced.

Light-emitting apparatuses including light-emitting devices (also referred to as light-emitting elements) have been developed as display apparatuses, for example. Light-emitting devices utilizing an electroluminescence (hereinafter referred to as EL) phenomenon (also referred to as EL devices or EL elements) have features such as ease of reduction in thickness and weight, high-speed response to input signals, and driving with a constant DC voltage power source, and have been used in display apparatuses.

Patent Document 1 discloses a display apparatus using an organic EL device (also referred to as organic EL element) for VR.

### REFERENCE

### Patent Document

[Patent Document 1] PCT International Publication No. 2018/087625

### SUMMARY OF THE INVENTION

### Problems to be Solved by the Invention

An object of one embodiment of the present invention is to provide a display apparatus with high definition. An object of one embodiment of the present invention is to provide a display apparatus with high resolution. An object of one embodiment of the present invention is to provide a display apparatus with high display quality. An object of one embodiment of the present invention is to provide a highly reliable display apparatus. An object of one embodiment of the present invention is to provide a novel display apparatus.

An object of one embodiment of the present invention is to provide a method of manufacturing a display apparatus with high definition. An object of one embodiment of the present invention is to provide a method of manufacturing a display apparatus with high resolution. An object of one embodiment of the present invention is to provide a method of manufacturing a display apparatus with high display quality. An object of one embodiment of the present invention is to provide a method of manufacturing a highly reliable display apparatus. An object of one embodiment of the present invention is to provide a method of manufacturing a display apparatus with a high yield. An object of one embodiment of the present invention is to provide a method of manufacturing a novel display apparatus.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is a display apparatus including a transistor, a light-emitting device, and a first insulating layer. The transistor includes a semiconductor layer, a first conductive layer, a second conductive layer, a third conductive layer, a second insulating layer, and a third insulating layer. The second insulating layer is provided over the first conductive layer and includes a first opening reaching the first conductive layer. The second conductive layer is provided over the second insulating layer and includes a second opening in a region overlapping with the first opening. The semiconductor layer is in contact with the top surface of the first conductive layer, the side surface of the second insulating layer, and the top surface and the side surface of the second conductive layer. The third insulating layer is provided over the semiconductor layer. The third conductive layer is provided over the third insulating layer. The first insulating layer is provided over the transistor. The first insulating layer and the third insulating layer include a third opening reaching the second conductive layer. The light-emitting device is provided over the first insulating layer. The light-emitting device includes a pixel electrode, a common electrode, and an EL layer interposed between the pixel electrode and the common electrode. The pixel electrode is electrically connected to the second conductive layer through the third opening. The EL layer includes a region in contact with the top surface and the side surface of the pixel electrode.

In the above-described display apparatus, the second insulating layer preferably has a stacked-layer structure of a fourth insulating layer and a fifth insulating layer over the fourth insulating layer. The fifth insulating layer preferably includes a region having a higher film density than the fourth insulating layer.

In the above-described display apparatus, the second insulating layer preferably has a stacked-layer structure of a fourth insulating layer and a fifth insulating layer over the fourth insulating layer. The fifth insulating layer preferably includes a region having a higher nitrogen content than the fourth insulating layer.

In the above-described display apparatus, the second insulating layer preferably includes a sixth insulating layer. The sixth insulating layer is preferably positioned between the fourth insulating layer and the first conductive layer. The sixth insulating layer preferably includes a region having a higher film density than the fifth insulating layer.

In the above-described display apparatus, the second insulating layer preferably includes a sixth insulating layer. The sixth insulating layer is preferably positioned between the fourth insulating layer and the first conductive layer. The sixth insulating layer preferably includes a region having a higher nitrogen content than the fifth insulating layer.

The above-described display apparatus preferably includes a layer. The pixel electrode preferably includes a fourth conductive layer and a fifth conductive layer over the fourth conductive layer. The fourth conductive layer preferably covers the top surface of the first insulating layer and the third opening. The fourth conductive layer preferably includes a concave portion along a shape of the side surface of the first insulating layer and the top surface of the second conductive layer. The layer is preferably provided to fill the concave portion. The fifth conductive layer preferably covers the top surface of the fourth conductive layer and the top surface of the layer.

In the above-described display apparatus, the layer is preferably an insulating layer.

In the above-described display apparatus, the layer is preferably a conductive layer.

The above-described display apparatus preferably includes a seventh insulating layer and an eighth insulating layer. The seventh insulating layer preferably covers the side surface and part of the top surface of the EL layer. The eighth insulating layer preferably covers the side surface and part of the top surface of the EL layer with the seventh insulating layer therebetween. The common electrode preferably covers the eighth insulating layer.

In the above-described display apparatus, the seventh insulating layer preferably contains an inorganic material. The eighth insulating layer preferably contains an organic material.

### Effect of the Invention

One embodiment of the present invention can provide a display apparatus with high definition. A display apparatus with high resolution can be provided. A display apparatus with high display quality can be provided. A highly reliable display apparatus can be provided. A novel display apparatus can be provided.

One embodiment of the present invention can provide a method of manufacturing a display apparatus with high definition. A method of manufacturing a display apparatus with high resolution can be provided. A method of manufacturing a display apparatus with high display quality can be provided. A method of manufacturing a highly reliable display apparatus can be provided. A method of manufacturing a display apparatus with a high yield can be provided. A method of manufacturing a novel display apparatus can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1 is a top view illustrating an example of a display apparatus.

FIG. 2 is a cross-sectional view illustrating an example of a display apparatus.

FIG. 3A is a top view illustrating an example of a transistor. FIG. 3B and FIG. 3C are cross-sectional views illustrating the example of the transistor.

FIG. 4 is a perspective view illustrating an example of a transistor.

FIG. 5A to FIG. 5C are perspective views each illustrating a structure of a transistor.

FIG. 6A is a top view illustrating an example of a transistor. FIG. 6B is a cross-sectional view illustrating an example of a transistor.

FIG. 7A is a top view illustrating an example of a transistor. FIG. 7B is a cross-sectional view illustrating an example of a transistor.

FIG. 8A and FIG. 8B are cross-sectional views each illustrating an example of a transistor.

FIG. 9A and FIG. 9B are cross-sectional views each illustrating an example of a transistor.

FIG. 10A is a top view illustrating an example of a transistor. FIG. 10B and FIG. 10C are cross-sectional views illustrating the example of the transistor.

FIG. 11A is a top view illustrating an example of a transistor. FIG. 11B is a cross-sectional view illustrating an example of a transistor.

FIG. 12 is a cross-sectional view illustrating an example of a transistor.

FIG. 13A is a top view illustrating an example of a transistor. FIG. 13B and FIG. 13C are cross-sectional views illustrating the example of the transistor.

FIG. 14A is a cross-sectional view illustrating an example of a display apparatus. FIG. 14B is a top view illustrating an example of a light-emitting device.

FIG. 15 is a cross-sectional view illustrating an example of a display apparatus.

FIG. 16A and FIG. 16B are cross-sectional views each illustrating an example of a display apparatus.

FIG. 17A and FIG. 17B are cross-sectional views each illustrating an example of a display apparatus.

FIG. 18A and FIG. 18B are cross-sectional views each illustrating an example of a display apparatus.

FIG. 19 is a cross-sectional view illustrating an example of a display apparatus.

FIG. 20 is a cross-sectional view illustrating an example of a display apparatus.

FIG. 21 is a top view illustrating an example of a display apparatus.

FIG. 22A and FIG. 22B are cross-sectional views each illustrating an example of a display apparatus.

FIG. 23A to FIG. 23E are cross-sectional views illustrating an example of a method for manufacturing a display apparatus.

FIG. 24A to FIG. 24D are cross-sectional views illustrating an example of a method for manufacturing a display apparatus.

FIG. 25A to FIG. 25C are cross-sectional views illustrating an example of a method for manufacturing a display apparatus.

FIG. 26A and FIG. 26B are cross-sectional views illustrating an example of a method for manufacturing a display apparatus.

FIG. 27A and FIG. 27B are cross-sectional views illustrating an example of a method for manufacturing a display apparatus.

FIG. 28A and FIG. 28B are cross-sectional views illustrating an example of the method for manufacturing a display apparatus.

FIG. 29A and FIG. 29B are cross-sectional views illustrating an example of a method for manufacturing a display apparatus.

FIG. 30A and FIG. 30B are cross-sectional views illustrating an example of a method for manufacturing a display apparatus.

FIG. 31A and FIG. 31B are cross-sectional views illustrating an example of a method for manufacturing a display apparatus.

FIG. 32A and FIG. 32B are cross-sectional views illustrating an example of a method for manufacturing a display apparatus.

FIG. 33A and FIG. 33B are cross-sectional views illustrating an example of a method for manufacturing a display apparatus.

FIG. 34A and FIG. 34B are cross-sectional views illustrating an example of a method for manufacturing a display apparatus.

FIG. 35A and FIG. 35B are cross-sectional views illustrating an example of a method for manufacturing a display apparatus.

FIG. 36A and FIG. 36B are cross-sectional views illustrating an example of a method for manufacturing a display apparatus.

FIG. 37A and FIG. 37B are cross-sectional views illustrating an example of a method for manufacturing a display apparatus.

FIG. 38A to FIG. 38G are diagrams each illustrating an example of a pixel.

FIG. 39A to FIG. 39K are diagrams each illustrating an example of a pixel.

FIG. 40 is a perspective view illustrating an example of a display apparatus.

FIG. 41 is a cross-sectional view illustrating an example of a display apparatus.

FIG. 42 is a cross-sectional view illustrating an example of a display apparatus.

FIG. 43 is a cross-sectional view illustrating an example of a display apparatus.

FIG. 44A to FIG. 44F are diagrams each illustrating structure a structure example of a light-emitting device.

FIG. 45A to FIG. 45C are diagrams each illustrating a structure example of a light-emitting device.

FIG. 46A and FIG. 46B are diagrams each illustrating a structure example of a light-receiving device. FIG. 46C to FIG. 46E are diagrams each illustrating a structure example of a display apparatus.

FIG. 47A to FIG. 47D are diagrams each illustrating an example of an electronic device.

FIG. 48A to FIG. 48F are diagrams each illustrating an example of an electronic device.

FIG. 49A to FIG. 49G are diagrams each illustrating an example of an electronic device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are indicated by the same reference numerals in different drawings, and the description thereof is not repeated. The same hatching pattern is used for portions having similar functions, and the portions are not especially indicated by reference numerals in some cases.

The position, size, range, or the like of each component illustrated in drawings does not represent the actual position, size, range, or the like in some cases for easy understanding. Thus, the disclosed invention is not necessarily limited to the position, size, range, or the like disclosed in the drawings.

Note that the term “film” and the term “layer” can be used interchangeably depending on the case or the circumstances. For example, the term “conductive layer” can be replaced with the term “conductive film”. As another example, the term “insulating film” can be replaced with the term “insulating layer”.

In this specification and the like, a device formed using a metal mask or an FMM (fine metal mask, high-definition metal mask) may be referred to as a device having an MM (metal mask) structure. In this specification and the like, a device formed without using a metal mask or an FMM may be referred to as a device having an MML (metal maskless) structure.

In this specification and the like, a structure in which at least light-emitting layers of light-emitting devices having different emission wavelengths are separately formed may be referred to as a SBS (Side By Side) structure. The SBS structure can optimize materials and structures of light-emitting devices and thus can extend freedom of choice of materials and structures, whereby the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other on the basis of the cross-sectional shape, properties, or the like in some cases. One layer may have two or three functions of the carrier-injection layer, the carrier-transport layer, and the carrier-blocking layer in some cases.

In this specification and the like, the light-emitting device includes an EL layer between a pair of electrodes. The EL layer includes at least a light-emitting layer. Examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a light-receiving device (also referred to as a light-receiving element) includes at least an active layer functioning as a photoelectric conversion layer between a pair of electrodes.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In this specification and the like, a tapered shape refers to such a shape that at least part of a side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat, and may have a substantially planar shape with a small curvature or a substantially planar shape with slight unevenness.

In this specification and the like, a mask layer (also referred to as a sacrificial layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

In this specification and the like, the expression “having substantially the same top surface shapes” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such cases are also represented by the expression “top surface shapes are substantially the same”.

### Embodiment 1

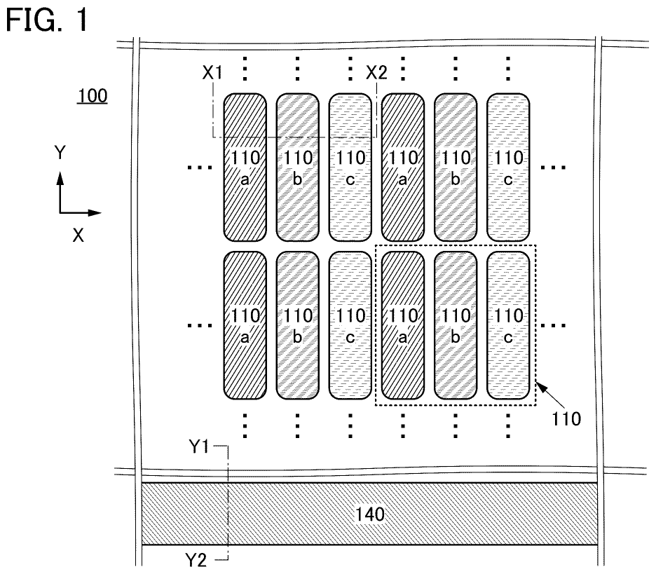

In this embodiment, a display apparatus of one embodiment of the present invention will be described with reference to FIG. 1 to FIG. 22.

FIG. 1 is a top view (also referred to as a plan view) illustrating a display apparatus 100 of one embodiment of the present invention. The display apparatus 100 includes a display portion in which a plurality of pixels 110 are arranged in a matrix and a connection portion 140 outside the display portion. The pixels 110 each include a plurality of subpixels. FIG. 1 illustrates the pixels 110 in two rows and two columns. As the structure where the pixels 110 each include three subpixels (a subpixel 110a, a subpixel 110b, and a subpixel 110c), the subpixels in two rows and six columns are illustrated. The connection portion 140 can also be referred to as a cathode contact portion.

Each subpixel includes a display device (also referred to as a display element). Examples of the display device include a liquid crystal device (also referred to as a liquid crystal element) and a light-emitting device. As the light-emitting device, an OLED (Organic Light-Emitting Diode) or a QLED (Quantum-dot Light-Emitting Diode) is preferably used, for example. Examples of a light-emitting substance included in the light-emitting device include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material). An LED (Light Emitting Diode) such as a micro-LED can also be used as the light-emitting device.

The emission color of the light-emitting device can be infrared, red, green, blue, cyan, magenta, yellow, white, or the like. Furthermore, color purity can be increased when the light-emitting device has a microcavity structure.

In the following description, a structure where a light-emitting device is used as the display device is given as an example.

A display apparatus of one embodiment of the present invention includes light-emitting devices separately formed for respective emission colors and can perform full-color display.

The top surface shapes of the subpixels illustrated in FIG. 1 correspond to the top surface shapes of the light-emitting regions of the light-emitting devices. Examples of the top surface shape of the subpixel include polygons such as a triangle, a quadrangle (including a rectangle and a square), and a pentagon; polygons with rounded corners; an ellipse; and a circle.

Each subpixel includes a pixel circuit controlling the light-emitting device. The pixel circuit is not necessarily placed in the range of the subpixel illustrated in FIG. 1 and may be placed outside the subpixel. For example, transistors included in a pixel circuit of the subpixel 110a may be placed within the range of the subpixel 110b illustrated in FIG. 1, or some or all of the transistors may be positioned outside the range of the subpixel 110a.

Here, to increase the definition of the display apparatus, the size of a pixel (subpixel) needs to be reduced. In order to reduce the size of a pixel (subpixel), both the size of a light-emitting device and the size of a pixel circuit need to be reduced. In particular, in the pixel circuit including a plurality of transistors, the area occupied by the transistors needs to be reduced. A transistor included in the display apparatus of one embodiment of the present invention includes a first conductive layer functioning as one of a source electrode and a drain electrode, a second conductive layer functioning as the other, and an insulating layer interposed between the first conductive layer and the second conductive layer. The insulating layer and the second conductive layer include an opening reaching the first conductive layer. The second conductive layer includes a region overlapping with the first conductive layer with the insulating layer therebetween. A semiconductor layer is provided to cover the opening. A gate insulating layer is provided over the semiconductor layer and a gate electrode is provided over the gate insulating layer. The channel length of the transistor corresponds to the length of the side surface of the insulating layer in the opening and is not affected by the performance of a light-exposure apparatus. Thus, the channel length can be a value smaller than that of the resolution limit of the light-exposure apparatus, which enables the transistor to have a minute size. Furthermore, the area occupied by the transistor can be reduced.

The light-emitting device included in the display apparatus of one embodiment of the present invention includes a pixel electrode, a common electrode, and an island-shaped EL layer interposed between the pixel electrode and the common electrode. The island-shaped EL layer can be formed by a photolithography method, for example. Specifically, pixel electrodes are formed for respective subpixels, and then a film to be the EL layer is formed across the plurality of pixel electrodes. After that, the film is processed by a photolithography method, so that one island-shaped EL layer is formed per pixel electrode. In this manner, the EL layer is divided for each subpixel and can be formed as the island-shaped EL layer. By a photolithography method, a miniaturized EL layer can be formed, so that a miniaturized light-emitting device can be achieved. In this manner, with the use of miniaturized transistors and light-emitting devices, a high-definition display apparatus can be achieved.

Note that although FIG. 1 illustrates the subpixel 110a, the subpixel 110b, and the subpixel 110c that have the same or substantially the same aperture ratio (also referred to as light-emitting regions that have the same or substantially the same size), one embodiment of the present invention is not limited thereto. The aperture ratio of each of the subpixel 110a, the subpixel 110b, and the subpixel 110c can be determined as appropriate. The subpixel 110a, the subpixel 110b, and the subpixel 110c may have different aperture ratios, or two or more of them may have the same or substantially the same aperture ratio.

The pixel 110 illustrated in FIG. 1 employs stripe arrangement. The pixel 110 illustrated in FIG. 1 is composed of three subpixels: the subpixel 110a, the subpixel 110b, and the subpixel 110c. The subpixel 110a, the subpixel 110b, and the subpixel 110c exhibit light of different colors. As examples of the subpixel 110a, the subpixel 110b, and the subpixel 110c, subpixels of three colors of red (R), green (G), and blue (B), subpixels of three colors of yellow (Y), cyan (C), and magenta (M), and the like can be given. The number of color types of subpixels is not limited to three and may be four or more. The four subpixels are subpixels of four colors of R, G, B, and white (W), subpixels of four colors of R, G, B, and Y, or subpixels of four types of R, G, B, and infrared light (IR), for example.

In this specification and the like, the row direction is referred to as X direction and the column direction is referred to as Y direction, in some cases. The X direction and the Y direction intersect with each other and are, for example, orthogonal to each other (see FIG. 1). FIG. 1 illustrates an example in which subpixels of different colors are arranged in the X direction and subpixels of the same color are arranged in the Y direction.

Although the top view (also referred to as a plan view) in FIG. 1 illustrates an example in which the connection portion 140 is positioned in one side of the display portion, the position of the connection portion 140 is not particularly limited. The connection portion 140 is provided in at least one of the upper side, the right side, the left side, and the lower side of the display portion in the top view, and may be provided so as to surround the four sides of the display portion. The top surface shape of the connection portion 140 is not particularly limited and can be a belt-like shape, an L shape, a U shape, a frame-like shape, or the like. The number of the connection portions 140 can be one or more.

### <Structure Example 1 of Display Apparatus>

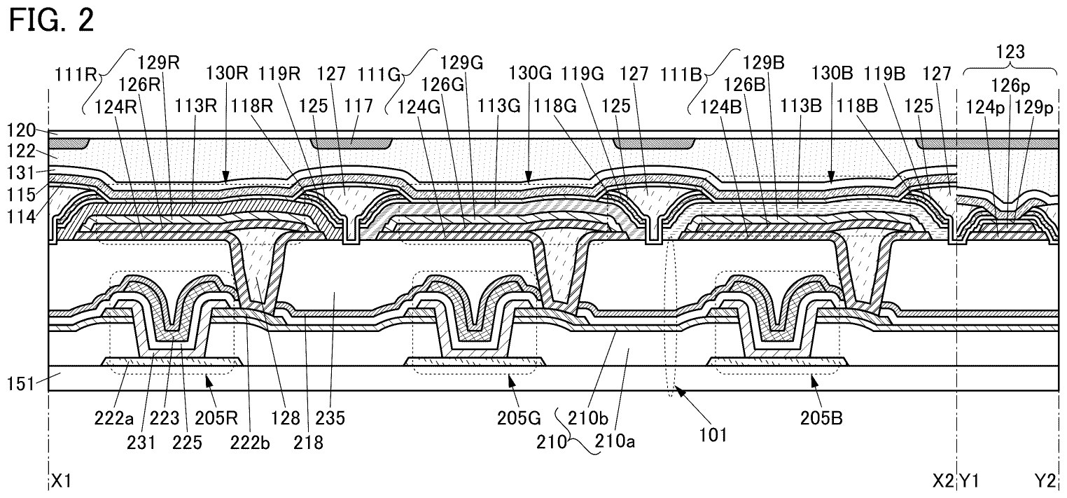

FIG. 2 is a cross-sectional view taken along the dashed-dotted line X1-X2 and the dashed-dotted line Y1-Y2 in FIG. 1.

As illustrated in FIG. 2, in the display apparatus 100, a light-emitting device 130R, a light-emitting device 130G, and a light-emitting device 130B are provided over a layer 101, and a protective layer 131 is provided to cover these light-emitting devices. A substrate 120 is attached onto the protective layer 131 with a resin layer 122.

The layer 101 includes a transistor 205R, a transistor 205G, and a transistor 205B. An insulating layer 218 and an insulating layer 235 over the insulating layer 218 are provided to cover the transistor 205R, the transistor 205G, and the transistor 205B. The insulating layer 218 and the insulating layer 235 include openings, and electrodes of the light-emitting device 130R, the light-emitting device 130G, and the light-emitting device 130B are provided to cover the openings.

Note that in the case of describing matters common to the light-emitting device 130R, the light-emitting device 130G, and the light-emitting device 130B, these light-emitting devices are sometimes referred to as a light-emitting device 130 by omitting the alphabets that distinguish them from each other. In the same manner, in the description common to the components that are distinguished by alphabets, such as the transistor 205R, the transistor 205G, and the transistor 205B, reference numerals without alphabets are sometimes used.

Each of the light-emitting device 130R, the light-emitting device 130G, and the light-emitting device 130B includes a pair of electrodes and a layer interposed between the pair of electrodes. The layer includes at least a light-emitting layer. One of the pair of electrodes included in the light-emitting device functions as an anode, and the other electrode functions as a cathode. The case where the pixel electrode functions as an anode and the common electrode functions as a cathode is described below as an example in some cases.

The light-emitting device 130R includes a pixel electrode 111R over the insulating layer 235, an island-shaped layer 113R over the pixel electrode 111R, a common layer 114 over the island-shaped layer 113R, and a common electrode 115 over the common layer 114. In the light-emitting device 130R, the layer 113R and the common layer 114 can be collectively referred to as an EL layer.

The light-emitting device 130G includes a pixel electrode 111G over the insulating layer 235, an island-shaped layer 113G over the pixel electrode 111G, the common layer 114 over the island-shaped layer 113G, and the common electrode 115 over the common layer 114. In the light-emitting device 130G, the layer 113G and the common layer 114 can be collectively referred to as an EL layer.

The light-emitting device 130B includes a pixel electrode 111B over the insulating layer 235, an island-shaped layer 113B over the pixel electrode 111B, the common layer 114 over the island-shaped layer 113B, and the common electrode 115 over the common layer 114. In the light-emitting device 130B, the layer 113B and the common layer 114 can be collectively referred to as an EL layer.

In this specification and the like, in the EL layers included in the light-emitting devices, the island-shaped layer provided in each light-emitting device is referred to as the layer 113R, the layer 113G, or the layer 113B, and the layer shared by the plurality of light-emitting devices is referred to as the common layer 114. Note that in this specification and the like, the layer 113R, the layer 113G, and the layer 113B are sometimes referred to as island-shaped EL layers, EL layers formed in an island shape, or the like, in which case the common layer 114 is not included.

The layer 113R, the layer 113G, and the layer 113B each have an island shape and are separated from one another. When the EL layer is provided in an island shape for each light-emitting device, a leakage current between adjacent light-emitting devices can be inhibited. This can prevent unintended light emission due to crosstalk, so that a display apparatus with extremely high contrast can be achieved. Specifically, a display apparatus having high current efficiency at low luminance can be achieved.

The display apparatus of one embodiment of the present invention can have any of a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 preferably includes a pixel circuit having a function of controlling the light-emitting device 130. The pixel circuit can include a transistor, a capacitor, and a wiring, for example. Note that the layer 101 may include one or both of a gate line driver circuit (a gate driver) and a source line driver circuit (a source driver) in addition to the pixel circuit. The layer 101 may further include one or both of an arithmetic circuit and a memory circuit.

The layer 101 can have a structure where a pixel circuit is provided over a semiconductor substrate or an insulating substrate. The layer 101 can have a stacked-layer structure in which a plurality of transistors are provided over a substrate 151 and an insulating layer is provided to cover these transistors, for example. FIG. 2 illustrates the transistor 205R, the transistor 205G, and the transistor 205B as transistors included in the layer 101.

Although there is no particular limitation on a material of the substrate 151, it is necessary that the substrate have heat resistance high enough to withstand at least heat treatment performed later. For example, a single crystal semiconductor substrate or a polycrystalline semiconductor substrate using silicon or silicon carbide as a material, a compound semiconductor substrate of silicon germanium or the like, an SOI substrate, a glass substrate, a quartz substrate, a sapphire substrate, a ceramic substrate, an organic resin substrate, or the like may be used as the substrate 151. Alternatively, any of these substrates over which a semiconductor element is provided may be used as the substrate 151. Note that the shape of the semiconductor substrate and the insulating substrate may be circular or square.

A flexible substrate may be used as the substrate 151, and the transistor 205R, the transistor 205G, and the transistor 205B may be formed directly over the flexible substrate. Alternatively, a separation layer may be provided between the substrate 151 and each of the transistor 205R, the transistor 205G, and the transistor 205B. The separation layer can be used to separate and transfer the display apparatus or part of the display apparatus formed thereover from the substrate 151 to another substrate. In that case, the transistor 205R, the transistor 205G, and the transistor 205B can also be transferred to a substrate having low heat resistance or a flexible substrate.

### [Structure Example 1 of Transistor]

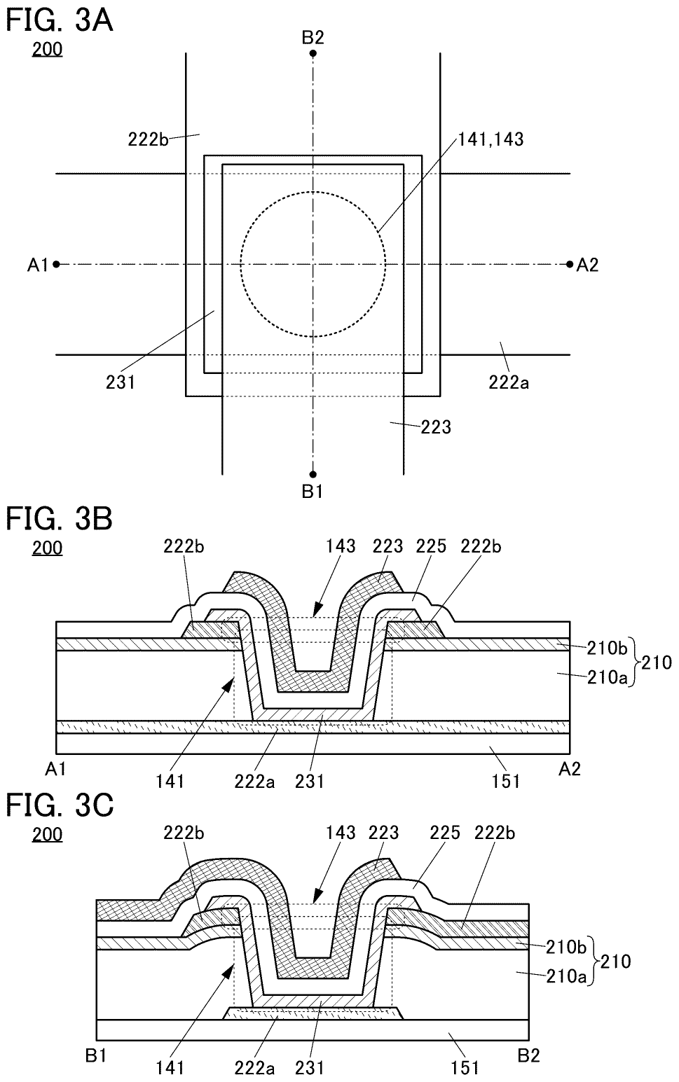

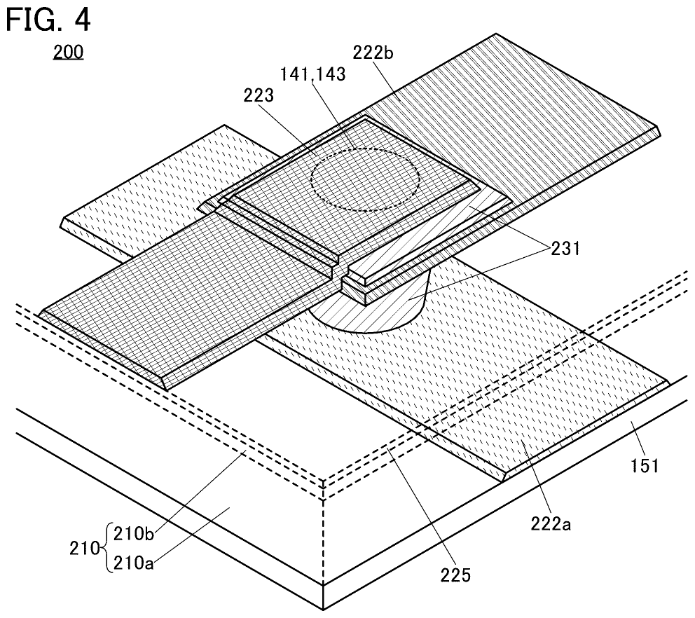

A transistor that can be used in the display apparatus of one embodiment of the present invention is described. FIG. 3A illustrates a top view of a transistor 200. FIG. 3B illustrates a cross-sectional view of a cut plane along the dashed-dotted line A1-A2 in FIG. 3A, and FIG. 3C illustrates a cross-sectional view of a cut plane along the dashed-dotted line B1-B2 in FIG. 3A. FIG. 4 illustrates a perspective view of the transistor 200. Note that in FIG. 3A, some components of the transistor 200 (a gate insulating layer and the like) are not illustrated. Some components are not illustrated in top views of transistors in the following drawings, as in FIG. 3A. For easy understanding, insulating layers in FIG. 4 are illustrated to be transparent with their outlines indicated by dashed lines.

The transistor 200 includes a conductive layer 223, an insulating layer 225, a semiconductor layer 231, a conductive layer 222a, a conductive layer 222b, and an insulating layer 210. The conductive layer 223 functions as a gate electrode. Part of the insulating layer 225 functions as a gate insulating layer. The conductive layer 222a functions as one of a source electrode and a drain electrode, and the conductive layer 222b functions as the other. In the semiconductor layer 231, the whole region that is between the source electrode and the drain electrode and overlaps with the gate electrode with the gate insulating layer therebetween functions as a channel formation region. In the semiconductor layer 231, a region in contact with the source electrode functions as a source region and a region in contact with the drain electrode functions as a drain region.

The conductive layer 222a is provided over the substrate 151, the insulating layer 210 is provided over the conductive layer 222a, and the conductive layer 222b is provided over the insulating layer 210. The insulating layer 210 includes a region interposed between the conductive layer 222a and the conductive layer 222b. The conductive layer 222a includes a region overlapping with the conductive layer 222b with the insulating layer 210 therebetween. The insulating layer 210 includes an opening 141 in a region overlapping with the conductive layer 222a. The conductive layer 222a is exposed in the opening 141. The conductive layer 222b includes an opening 143 in a region overlapping with the conductive layer 222a. The opening 143 is provided in a region overlapping with the opening 141.

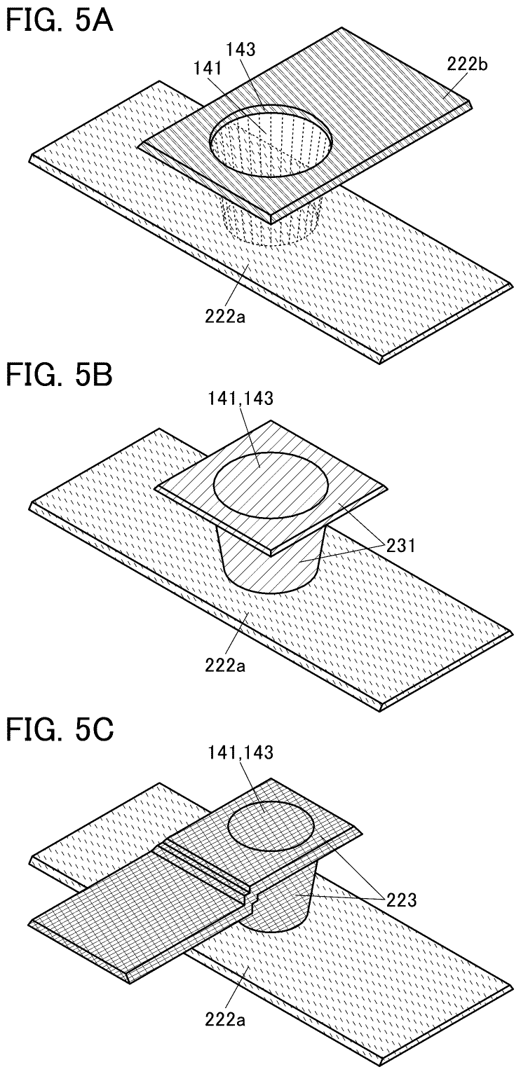

FIG. 5A is a perspective view selectively illustrating the conductive layer 222a, the conductive layer 222b, the opening 141, and the opening 143. Note that the opening 141 provided in the insulating layer 210 is indicated by dashed lines. As illustrated in FIG. 5A, the conductive layer 222b includes the opening 143 in a region overlapping with the conductive layer 222a. It is preferable that the conductive layer 222b not be provided inside the opening 141. That is, it is preferable that the conductive layer 222b not include a region in contact with the side surface of the insulating layer 210 on the opening 141 side.

The top surface shapes of the opening 141 and the opening 143 can each be a circle or an ellipse, for example. The top surface shapes of the opening 141 and the opening 143 may each be a polygon such as a triangle, a tetragon (including a rectangle, a rhombus, and a square), or a pentagon, or a polygon with rounded corners. As illustrated in FIG. 3A and the like, the top surface shapes of the opening 141 and the opening 143 are each preferably a circle. When the top surface shapes of the opening 141 and the opening 143 are each a circle, processing accuracy at the time of forming the opening 141 and the opening 143 can be improved, so that the opening 141 and the opening 143 with a minute size can be formed. Note that in this specification and the like, a circle is not necessarily a perfect circle.

An end portion of the conductive layer 222b on the opening 143 side is preferably the same or substantially the same as an end portion of the insulating layer 210 on the opening 141 side. In other words, the top surface shape of the opening 143 is the same or substantially the same as the top surface shape of the opening 141. Note that in this specification and the like, the end portion of the conductive layer 222b on the opening 143 side refers to an end portion of the bottom surface of the conductive layer 222b on the opening 143 side. The bottom surface of the conductive layer 222b refers to a surface thereof on the insulating layer 210 side. The end portion of the insulating layer 210 on the opening 141 side refers to an end portion of the top surface of the insulating layer 210 on the opening 141 side. The top surface of the insulating layer 210 refers to a surface thereof on the conductive layer 222b side. The top surface shape of the opening 143 refers to the shape of the end portion of the bottom surface of the conductive layer 222b on the opening 143 side. The top surface shape of the opening 141 refers to the shape of the end portion of the top surface of the insulating layer 210 on the opening 141 side.

Note that in the case where end portions are the same or substantially the same, the end portions can also be said to be aligned or substantially aligned with each other. In the case where end portions are aligned or substantially aligned with each other and the case where top surface shapes are the same or substantially the same, it can be said that outlines of stacked layers at least partly overlap with each other in the top view. For example, the case of processing the upper layer and the lower layer with the use of the same mask pattern or mask patterns that are partly the same is included. Note that, in some cases, the outlines do not completely overlap with each other and the upper layer is positioned inward from the lower layer or the upper layer is positioned outward from the lower layer; such cases are also represented by the expression “end portions are substantially aligned with each other” or the expression “top surface shapes are substantially the same”.

The opening 141 can be formed using a resist mask used for forming the opening 143, for example. Specifically, an insulating film to be the insulating layer 210, a conductive film to be the conductive layer 222b over the insulating film, and a resist mask over the conductive film are formed. Then, the opening 143 is formed in the conductive film with the use of the resist mask, and then the opening 141 is formed in the insulating film with the use of the resist mask, whereby an end portion of the opening 141 and an end portion of the opening 143 can be the same or substantially the same. With such a structure, processes can be simplified.

After the opening 143 is formed, the opening 141 may be formed in a step different from that of the opening 143. There is no particular limitation on the formation order of the opening 141 and the opening 143. For example, after the opening 141 is formed in the insulating film to be the insulating layer 210, the conductive film to be the conductive layer 222b may be formed, and the opening 143 may be formed in the conductive film. The end portion of the conductive layer 222b on the opening 143 side is not necessarily the same as the end portion of the insulating layer 210 on the opening 141 side.

The semiconductor layer 231 is provided to cover the opening 141 and the opening 143. The semiconductor layer 231 includes a region in contact with the top surface and the side surface of the conductive layer 222b, the side surface of the insulating layer 210, and the top surface of the conductive layer 222a. The semiconductor layer 231 is electrically connected to the conductive layer 222a through the opening 141 and the opening 143. The semiconductor layer 231 has a shape along the shapes of the top surface and the side surface of the conductive layer 222b, the side surface of the insulating layer 210, and the top surface of the conductive layer 222a.

The semiconductor layer 231 preferably covers the end portion of the conductive layer 222b on the opening 143 side. FIG. 3B and the like illustrate a structure in which an end portion of the semiconductor layer 231 is positioned over the conductive layer 222b. It can be said that the end portion of the semiconductor layer 231 is in contact with the top surface of the conductive layer 222b. Note that the semiconductor layer 231 may extend and cover an end portion of the conductive layer 222b on the side not facing the opening 143. The end portion of the semiconductor layer 231 may be in contact with the top surface of the insulating layer 210.

FIG. 5B is a perspective view selectively illustrating the conductive layer 222a and the semiconductor layer 231. As illustrated in FIG. 5B, the semiconductor layer 231 is provided to cover the opening 141 and the opening 143. In the opening 141, the semiconductor layer 231 includes a region in contact with the top surface of the conductive layer 222a.

Although the semiconductor layer 231 has a single-layer structure in FIG. 3B and the like, one embodiment of the present invention is not limited thereto. The semiconductor layer 231 may have a stacked-layer structure of two or more layers.

The insulating layer 225 functioning as the gate insulating layer is provided to cover the opening 141 and the opening 143. The insulating layer 225 is provided over the semiconductor layer 231, the conductive layer 222b, and the insulating layer 210. The insulating layer 225 includes a region in contact with the top surface and the side surface of the semiconductor layer 231, the top surface and the side surface of the conductive layer 222b, and the top surface of the insulating layer 210. The insulating layer 225 has a shape along the shapes of the top surface of the insulating layer 210, the top surface and the side surface of the conductive layer 222b, the top surface and the side surface of the semiconductor layer 231, and the top surface of the conductive layer 222a.

The conductive layer 223 functioning as the gate electrode is provided over the insulating layer 225 and includes a region in contact with the top surface of the insulating layer 225. The conductive layer 223 includes a region overlapping with the semiconductor layer 231 with the insulating layer 225 therebetween. The conductive layer 223 has a shape along the shape of the top surface of the insulating layer 225.

FIG. 5C is a perspective view selectively illustrating the conductive layer 222a and the conductive layer 223. As illustrated in FIG. 5C, the conductive layer 223 is provided to cover the opening 141 and the opening 143.

As illustrated in FIG. 3B and the like, in the opening 141 and the opening 143, the conductive layer 223 includes a region overlapping with the semiconductor layer 231 with the insulating layer 225 therebetween. The conductive layer 223 includes a region overlapping with the conductive layer 222a and a region overlapping with the conductive layer 222b with the insulating layer 225 and the semiconductor layer 231 therebetween. The conductive layer 223 preferably covers the end portion of the conductive layer 222b on the opening 143 side. With such a structure, in the semiconductor layer 231, the whole region that is between the source electrode and the drain electrode and overlaps with the gate electrode with the gate insulating layer therebetween can function as the channel formation region.

The transistor 200 is what is called a top-gate transistor including a gate electrode above the semiconductor layer 231. Furthermore, since the bottom surface of the semiconductor layer 231 is in contact with the source electrode and the drain electrode, the transistor can be referred to as a TGBC (Top Gate Bottom Contact) transistor.

The conductive layer 222a, the conductive layer 222b, and the conductive layer 223 can each function as a wiring. The transistor 200 can be provided in a region where these wirings overlap with each other. That is, the area occupied by the transistor 200 and the wirings can be reduced in the circuit including the transistor 200 and the wirings. Furthermore, the area occupied by the circuit can be reduced. For example, in the case where the transistor 200 is used in a pixel circuit of a display apparatus, the area occupied by the pixel circuit can be reduced, so that the display apparatus can have high definition. In the case where the transistor 200 is used in a driver circuit (e.g., a gate line driver circuit and a source line driver circuit) of a display apparatus, the area occupied by the driver circuit can be reduced, so that a display apparatus with a narrow bezel can be obtained. In addition, a small display apparatus can be obtained.

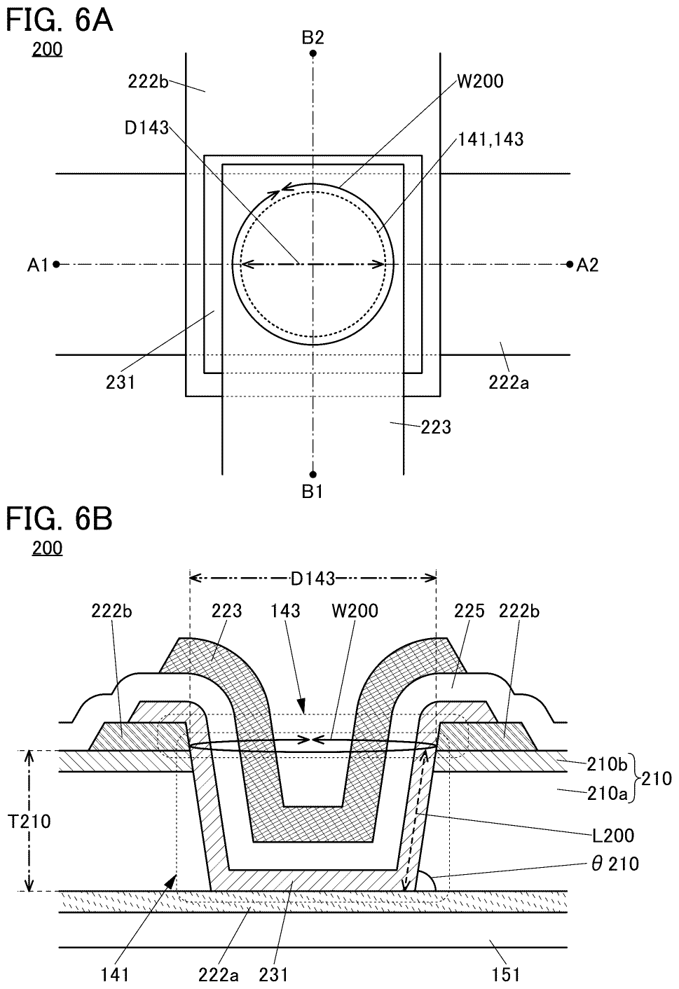

Here, the channel length and the channel width of the transistor 200 are described with reference to FIG. 6A and FIG. 6B. FIG. 6A is a top view of the transistor 200. FIG. 6B is an enlarged view of FIG. 3B.

In the semiconductor layer 231, a region in contact with the conductive layer 222a functions as one of the source region and the drain region, a region in contact with the conductive layer 222b functions as the other of the source region and the drain region, and a region between the source region and the drain region functions as the channel formation region.

The channel length of the transistor 200 is a distance between the source region and the drain region. In FIG. 6B, a channel length L200 of the transistor 200 is indicated by a dashed double-headed arrow. In the cross-sectional view, the channel length L200 is a distance between an end portion of a region where the semiconductor layer 231 and the conductive layer 222a are in contact with each other and an end portion of a region where the semiconductor layer 231 and the conductive layer 222b are in contact with each other.

The channel length L200 of the transistor 200 corresponds to the length of the side surface of the insulating layer 210 on the opening 141 side in the cross-sectional view. In other words, the channel length L200 is determined by a thickness T210 of the insulating layer 210 and an angle θ210 formed by the side surface of the insulating layer 210 on the opening 141 side and the formation surface of the insulating layer 210 (here, the top surface of the conductive layer 222a), and is not affected by the performance of the light-exposure apparatus used for manufacturing the transistor. Thus, the channel length L200 can be a value smaller than the resolution limit of the light-exposure apparatus, so that a miniaturized transistor can be achieved. For example, the channel length L200 is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet still further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm. In FIG. 6B, the thickness T210 of the insulating layer 210 is indicated by a dashed-dotted double-headed arrow.

The reduction in the channel length L200 can increase the on-state current of the transistor 200. With the use of the transistor 200, a circuit capable of high-speed operation can be manufactured. Furthermore, the area occupied by the circuit can be reduced. For example, when the transistor 200 is used in a large display apparatus or a high-definition display apparatus, signal delay in wirings can be reduced and display unevenness can be inhibited even when the number of wirings is increased. Furthermore, since the area occupied by the circuit can be reduced, the bezel of the display apparatus can be narrowed.

By adjusting the thickness T210 and the angle θ210 of the insulating layer 210, the channel length L200 can be controlled.

The thickness T210 of the insulating layer 210 is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet still further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

The side surface of the insulating layer 210 on the opening 141 side preferably has a tapered shape. The angle θ210 formed by the side surface of the insulating layer 210 on the opening 141 side and the formation surface of the insulating layer 210 (here, the top surface of the conductive layer 222a) is preferably less than 90°. By reducing the angle θ210, coverage with a layer provided over the insulating layer 210 (e.g., the semiconductor layer 231) can be improved. However, when the angle θ210 is reduced, the contact area between the semiconductor layer 231 and the conductive layer 222a is reduced, so that the contact resistance between the semiconductor layer 231 and the conductive layer 222a is increased in some cases. The angle θ210 is preferably greater than or equal to 450 and less than 90°, further preferably greater than or equal to 500 and less than 90°, still further preferably greater than or equal to 550 and less than 90°, yet still further preferably greater than or equal to 600 and less than 90°, yet still further preferably greater than or equal to 600 and less than or equal to 85°, yet still further preferably greater than or equal to 650 and less than or equal to 85°, yet still further preferably greater than or equal to 650 and less than or equal to 80°, yet still further preferably greater than or equal to 700 and less than or equal to 80°. When the angle θ210 is in the above range, coverage with a layer formed over the conductive layer 222a and the insulating layer 210 (e.g., the semiconductor layer 231) can be improved, so that a defect such as disconnection or a void can be inhibited from occurring in the layer. Furthermore, the contact resistance between the semiconductor layer 231 and the conductive layer 222a can be reduced.

Although FIG. 6B and the like illustrate a structure in which the side surface of the insulating layer 210 on the opening 141 side has a linear shape in the cross-sectional view, one embodiment of the present invention is not limited thereto. In the cross-sectional view, the side surface of the insulating layer 210 on the opening 141 side may be curved or include both a region where the side surface is curved and a region where the side surface is linear.

The channel width of the transistor 200 is the width of the source region or the width of the drain region in a direction orthogonal to the channel length direction. That is, the channel width is the width of the region where the semiconductor layer 231 and the conductive layer 222a are in contact with each other or the width of the region where the semiconductor layer 231 and the conductive layer 222b are in contact with each other in the direction orthogonal to the channel length direction. Here, the channel width of the transistor 200 is described as the width of the region where the semiconductor layer 231 and the conductive layer 222b are in contact with each other in the direction orthogonal to the channel length direction. In FIG. 6A and FIG. 6B, a channel width W200 of the transistor 200 is indicated by a solid double-headed arrow. The channel width W200 is the length of the end portion of the bottom surface of the conductive layer 222b on the opening 143 side in the top view.

The channel width W200 is determined by the top surface shape of the opening 143. In FIG. 6A and FIG. 6B, a width D143 of the opening 143 is indicated by a dashed double-dotted double-headed arrow. In the top view, the width D143 of the opening 143 refers to the short side of the smallest rectangle circumscribing the opening 143. In the case where the opening 143 is formed by a photolithography method, the width D143 of the opening 143 is larger than or equal to the resolution limit of the light-exposure apparatus. For example, the width D143 is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet still further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm. Note that in the case where the top surface shape of the opening 143 is a circle, the width D143 corresponds to the diameter of the opening 143, and the channel width W200 can be calculated to be “D143×π”.

Components included in a transistor that can be used in the display apparatus of one embodiment of the present invention are described below.

### [Semiconductor Layer 231]

The semiconductor material that can be used for the semiconductor layer 231 is not particularly limited. For example, a single-element semiconductor or a compound semiconductor can be used. As the single-element semiconductor, silicon or germanium can be used, for example. Examples of the compound semiconductor include gallium arsenide and silicon germanium. As the compound semiconductor, an organic substance having semiconductor characteristics or a metal oxide having semiconductor characteristics (also referred to as an oxide semiconductor) can be used. Note that these semiconductor materials may contain an impurity as a dopant.

There is no particular limitation on the crystallinity of a semiconductor material used in the semiconductor layer 231 of the transistor, and any of an amorphous semiconductor or a semiconductor having crystallinity (a single crystal semiconductor, a polycrystalline semiconductor, a microcrystalline semiconductor, or a semiconductor partly including crystal regions) may be used. A semiconductor having crystallinity is preferably used because deterioration of the transistor characteristics can be inhibited.

Silicon can be used for the semiconductor layer 231. Examples of silicon include single crystal silicon, polycrystalline silicon, microcrystalline silicon, and amorphous silicon. As the polycrystalline silicon, for example, low-temperature polysilicon (LTPS) is given.

A transistor using amorphous silicon for the semiconductor layer 231 can be formed over a large-sized glass substrate, thereby reducing the manufacturing cost. A transistor using polycrystalline silicon for the semiconductor layer 231 has high field-effect mobility and can operate at high speed. A transistor using microcrystalline silicon for the semiconductor layer 231 has higher field-effect mobility and enables higher-speed operation than the transistor using amorphous silicon.

The semiconductor layer 231 preferably includes a metal oxide film having semiconductor characteristics (an oxide semiconductor). Examples of the metal oxide that can be used for the semiconductor layer 231 include indium oxide, gallium oxide, and zinc oxide. The metal oxide preferably contains at least indium (In) or zinc (Zn). The metal oxide preferably contains two or three selected from indium, an element M, and zinc. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin.

For the semiconductor layer 231, it is possible to use, for example, indium oxide, indium zinc oxide (In—Zn oxide), indium tin oxide (In—Sn oxide), indium titanium oxide (In—Ti oxide), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide), and indium gallium aluminum zinc oxide (In—Ga—Al—Zn oxide, also referred to as IGAZO or IAGZO). Alternatively, indium tin oxide containing silicon, or the like can also be used.

In particular, the element M is preferably one or more kinds selected from gallium, aluminum, yttrium, and tin. In particular, gallium is preferable as the element M.

Here, the composition of a metal oxide included in the semiconductor layer 231 greatly affects the electrical characteristics and reliability of the transistor 200.

For example, higher content of indium in the metal oxide enables the transistor to have high on-state current.

In the case where an In—Zn oxide is used for the semiconductor layer 231, a metal oxide in which the atomic ratio of indium is higher than or equal to that of zinc is preferably used. For example, a metal oxide in which the atomic ratio of metal elements is In:Zn=1:1, In:Zn=2:1, In:Zn=3:1, In:Zn=4:1, In:Zn=5:1, In:Zn=7:1, or In:Zn=10:1, or in the neighborhood thereof.

In the case where an In—Sn oxide is used for the semiconductor layer 231, a metal oxide in which the atomic ratio of indium is higher than or equal to that of tin is preferably used. For example, it is possible to use a metal oxide in which the atomic ratio of metal elements is In:Sn=1:1, In:Sn=2:1, In:Sn=3:1, In:Sn=4:1, In:Sn=5:1, In:Sn=7:1, or In:Sn=10:1, or in the neighborhood thereof.

In the case where an In—Sn—Zn oxide is used for the semiconductor layer 231, it is possible to use a metal oxide in which the atomic ratio of indium is higher than that of tin. It is further preferable to use a metal oxide in which the atomic ratio of zinc higher than that of tin. For example, it is possible to use a metal oxide in which the atomic ratio of metal elements is In:Sn:Zn=2:1:3, In:Sn:Zn=3:1:2, In:Sn:Zn=4:2:3, In:Sn:Zn=4:2:4.1, In:Sn:Zn=5:1:3, In:Sn:Zn=5:1:6, In:Sn:Zn=5:1:7, In:Sn:Zn=5:1:8, In:Sn:Zn=6:1:6, In:Sn:Zn=10:1:3, In:Sn:Zn=10:1:6, In:Sn:Zn=10:1:7, In:Sn:Zn=10:1:8, In:Sn:Zn=5:2:5, In:Sn:Zn=10:1:10, In:Sn:Zn=20:1:10, or In:Sn:Zn=40:1:10, or in the neighborhood thereof.

In the case where an In—Al—Zn oxide is used for the semiconductor layer 231, it is possible to use a metal oxide in which the atomic ratio of indium is higher than that of aluminum. It is further preferable to use a metal oxide in which the atomic ratio of zinc is higher than that of aluminum. For example, it is possible to use a metal oxide in which the atomic ratio of metal elements is In:Al:Zn=2:1:3, In:Al:Zn=3:1:2, In:Al:Zn=4:2:3, In:Al:Zn=4:2:4.1, In:Al:Zn=5:1:3, In:Al:Zn=5:1:6, In:Al:Zn=5:1:7, In:Al:Zn=5:1:8, In:Al:Zn=6:1:6, In:Al:Zn=10:1:3, In:Al:Zn=10:1:6, In:Al:Zn=10:1:7, In:Al:Zn=10:1:8, In:Al:Zn=5:2:5, In:Al:Zn=10:1:10, In:Al:Zn=20:1:10, or In:Al:Zn=40:1:10, or in the neighborhood thereof.

In the case where an In—Ga—Zn oxide is used for the semiconductor layer 231, it is possible to use a metal oxide in which the atomic ratio of indium is higher than that of gallium. It is further preferable to use a metal oxide in which the atomic ratio of zinc is higher than gallium. For example, a metal oxide having any of the following atomic ratios of metal elements can be used as the semiconductor layer 231: In:Ga:Zn=2:1:3, In:Ga:Zn=3:1:2, In:Ga:Zn=4:2:3, In:Ga:Zn=4:2:4.1, In:Ga:Zn=5:1:3, In:Ga:Zn=5:1:6, In:Ga:Zn=5:1:7, In:Ga:Zn=5:1:8, In:Ga:Zn=6:1:6, In:Ga:Zn=10:1:3, In:Ga:Zn=10:1:6, In:Ga:Zn=10:1:7, In:Ga:Zn=10:1:8, In:Ga:Zn=5:2:5, In:Ga:Zn=10:1:10, In:Ga:Zn=20:1:10, In:Ga:Zn=40:1:10, and a neighborhood thereof.

In the case where an In-M-Zn oxide is used for the semiconductor layer 231, it is possible to use a metal oxide in which the atomic ratio of indium is higher than that of the element M. It is further preferable to use a metal oxide in which the atomic ratio of zinc is higher than the element M. For example, a metal oxide having any of the following atomic ratios of metal elements can be used as the semiconductor layer 231: In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, In:M:Zn=10:1:3, In:M:Zn=10:1:6, In:M:Zn=10:1:7, In:M:Zn=10:1:8, 5 In:M:Zn=5:2:5, In:M:Zn=10:1:10, In:M:Zn=20:1:10, In:M:Zn=40:1:10, or a neighborhood thereof.

Note that in the case where a plurality of metal elements are contained as the element M, the atomic ratio of the sum of the metal elements can be the atomic ratio of the element M. In an In—Ga—Al—Zn oxide where gallium and aluminum are contained as the element M, for example, the atomic ratio of the sum of gallium and aluminum can be the atomic ratio of the element M. The atomic ratio of indium to the element M to zinc is preferably within the ranges given above.

It is preferable to use a metal oxide in which the atomic ratio of indium to the metal elements contained in the metal oxide is higher than or equal to 30 atomic % and lower than or equal to 100 atomic %, preferably higher than or equal to 30 atomic % and lower than or equal to 95 atomic %, further preferably higher than or equal to 35 atomic % and lower than or equal to 95 atomic %, still further preferably higher than or equal to 35 atomic % and lower than or equal to 90 atomic %, yet still further preferably higher than or equal to 40 atomic % and lower than or equal to 90 atomic %, yet still further preferably higher than or equal to 45 atomic % and lower than or equal to 90 atomic %, yet still further preferably higher than or equal to 50 atomic % and lower than or equal to 80 atomic %, yet still further preferably higher than or equal to 60 atomic % and lower than or equal to 80 atomic %, yet still further preferably higher than or equal to 70 atomic % and lower than or equal to 80 atomic %. For example, when an In—Ga—Zn oxide is used for the semiconductor layer 231, the atomic ratio of indium to the total number of the atoms of indium, the element M, and zinc is preferably within the ranges given above.

In this specification and the like, the atomic ratio of indium to the metal elements contained is sometimes referred to as indium content. The same applies to other metal elements.

Higher indium content in the metal oxide enables the transistor to have high on-state current. With the use of the transistor, a circuit capable of high-speed operation can be manufactured. Furthermore, the area occupied by a circuit can be reduced. For example, when the transistor is used in a large display apparatus or a high-definition display apparatus, signal delay in wirings can be reduced and display unevenness can be inhibited even when the number of wirings is increased. In addition, since the area occupied by the circuit can be reduced, the bezel of the display apparatus can be narrowed.

As an analysis method of the composition of a metal oxide, for example, energy dispersive X-ray spectroscopy (EDX), X-ray photoelectron spectroscopy (XPS), inductively coupled plasma-mass spectroscopy (ICP-MS), or inductively coupled plasma-atomic emission spectrometry (ICP-AES), can be used. Alternatively, such kinds of analysis methods may be performed in combination. Note that as for an element whose content is low, the actual content may be different from the content obtained by analysis because of the influence of the analysis accuracy. In the case where the content of the element M is low, for example, the content of the element M obtained by analysis may be lower than the actual content.

Note that a composition in the neighborhood in this specification and the like includes the range of ±30% of an intended atomic ratio. For example, when the atomic ratio is described as In:M:Zn=4:2:3 or a composition in the neighborhood thereof, the case is included where the atomic ratio of the element M is greater than or equal to 1 and less than or equal to 3 and the atomic ratio of zinc is greater than or equal to 2 and less than or equal to 4 with the atomic ratio of indium being 4. When the atomic ratio is described as In:M:Zn=5:1:6 or a composition in the neighborhood thereof, the case is included where the atomic ratio of the element M is greater than 0.1 and less than or equal to 2 and the atomic ratio of zinc is greater than or equal to 5 and less than or equal to 7 with the atomic ratio of indium being 5. When the atomic ratio is described as In:M:Zn=1:1:1 or a composition in the neighborhood thereof, the case is included where the atomic ratio of the element M is greater than 0.1 and less than or equal to 2 and the atomic ratio of zinc is greater than 0.1 and less than or equal to 2 with the atomic ratio of indium being 1.

For formation of the metal oxide, a sputtering method or an atomic layer deposition (ALD) method can be suitably used. Note that in the case where the metal oxide is formed by a sputtering method, the atomic ratio of a target may be different from the atomic ratio of the metal oxide. In particular, the atomic ratio of zinc in the metal oxide is lower than the atomic ratio of zinc in the target in some cases. Specifically, the atomic ratio of zinc contained in the metal oxide may be approximately 40% to 90% of the atomic ratio of zinc contained in the target.

Here, the reliability of a transistor is described. One of indicators of evaluating the reliability of a transistor is a GBT (Gate Bias Temperature) stress test in which a state of applying an electric field to a gate is maintained. Among GBTs, a test in which a state where a positive potential (positive bias) relative to a source potential and a drain potential is supplied to a gate is maintained at high temperatures is referred to as a PBTS (Positive Bias Temperature Stress) test, and a test in which a state where a negative potential (negative bias) is supplied to a gate is maintained at high temperatures is referred to as an NBTS (Negative Bias Temperature Stress) test. The PBTS test and the NBTS test conducted in a state where irradiation is performed are respectively referred to as a PBTIS (Positive Bias Temperature Illumination Stress) test and an NBTIS (Negative Bias Temperature Illumination Stress) test.

In particular, in an n-channel transistor, a positive potential is applied to a gate in putting the transistor in an on state (a state where current flows); thus, the amount of change in threshold voltage in the PBTS test is one important item to be focused on as an indicator of the reliability of the transistor.

With use of a metal oxide that does not contain gallium or has low gallium content in the semiconductor layer 231, the transistor can be highly reliable against positive bias application. In other words, the amount of change in the threshold voltage of the transistor in the PBTS test can be small. Meanwhile, with use of a metal oxide that contains gallium, the gallium content is preferably lower than the indium content so that the transistor can be highly reliable. Thus, a highly reliable transistor can be achieved.

One of the factors in change in the threshold voltage in the PBTS test is a defect state at the interface between a semiconductor layer and a gate insulating layer or in the vicinity of the interface. As the density of defect states increases, degradation in the PBTS test becomes significant. Generation of the defect states can be inhibited by reducing the gallium content in a region of the semiconductor layer in contact with the gate insulating layer.

The following can be given as the reason why the amount of change in the threshold voltage in the PBTS test can be reduced when a metal oxide that does not contain gallium or has low gallium content is used for the semiconductor layer. Gallium contained in a metal oxide has a property of attracting oxygen more easily than another metal element (e.g., indium or zinc) does. Thus, when, at the interface between a metal oxide containing a large amount of gallium and the gate insulating layer, gallium is bonded to excess oxygen in the gate insulating layer, trap sites of carriers (here, electrons) are probably generated easily. This might cause the change in the threshold voltage when a positive potential is applied to a gate and carriers are trapped at the interface between the semiconductor layer and the gate insulating layer.

Specifically, in the case where an In—Ga—Zn oxide is used for the semiconductor layer 231, a metal oxide film in which the atomic ratio of indium is higher than that of gallium can be used as the semiconductor layer 231. It is further preferable to use a metal oxide in which the atomic ratio of zinc is higher than that of gallium. In other words, a metal oxide in which the atomic ratios of metal elements satisfy In >Ga and Zn>Ga is preferably used as the semiconductor layer 231.

The semiconductor layer 231 is preferably formed using a metal oxide having the following compositions; the atomic ratio of gallium to the metal elements contained in the metal oxide is higher than 0 atomic % and lower than or equal to 50 atomic %, preferably higher than or equal to 0.1 atomic % and lower than or equal to 40 atomic %, further preferably higher than or equal to 0.1 atomic % and lower than or equal to 35 atomic %, still further preferably higher than or equal to 0.1 atomic % and lower than or equal to 30 atomic %, yet still further preferably higher than or equal to 0.1 atomic % and lower than or equal to 25 atomic %, yet still further preferably higher than or equal to 0.1 atomic % and lower than or equal to 20 atomic %, yet still further preferably higher than or equal to 0.1 atomic % and lower than or equal to 15 atomic %, yet still further preferably higher than or equal to 0.1 atomic % and lower than or equal to 10 atomic %. The reduction in the gallium content in the semiconductor layer enables the transistor to be highly resistant to the PBTS test. Note that oxygen vacancies (Vo) are less likely to be generated in the metal oxide when the metal oxide contains gallium.

A metal oxide not containing gallium may be used for the semiconductor layer 231. For example, an In—Zn oxide can be used for the semiconductor layer 231. In this case, when the atomic ratio of indium to metal elements contained in the metal oxide is increased, the field-effect mobility of the transistor can be increased. By contrast, when the atomic ratio of zinc to metal elements contained in the metal oxide is increased, the metal oxide has high crystallinity; thus, a change in the electrical characteristics of the transistor can be inhibited and the reliability can be increased. Alternatively, a metal oxide that contains neither gallium nor zinc, such as indium oxide, can be used for the semiconductor layer 231. The use of a metal oxide not containing gallium at all can make a change in the threshold voltage particularly in the PBTS test extremely small.

For example, an oxide containing indium and zinc can be used for the semiconductor layer 231. In that case, for example, a metal oxide where the atomic ratio of metal elements of In:Zn=2:3, In:Zn=4:1, or a neighborhood thereof can be used.

Although the case of using gallium is described as an example, the same applies to the case where the element M is used instead of gallium. In particular, a metal oxide in which the atomic ratio of indium is higher than the atomic ratio of the element M is preferably used as the semiconductor layer 231. Furthermore, a metal oxide in which the atomic ratio of zinc is higher than the atomic ratio of the element M is preferably used.

With the use of a metal oxide with a low content of the element M for the semiconductor layer 231, a transistor that is highly reliable against positive bias application can be provided. With the use of the transistor as a transistor that is required to have high reliability against positive bias application, a highly reliable display apparatus can be provided.

Next, the reliability of a transistor against light is described.

Light irradiation on a transistor may change electrical characteristics of the transistor. In particular, a transistor provided in a region on which light can be incident preferably exhibits a small variation in electrical characteristics under light irradiation and has high reliability against light. The reliability against light can be evaluated with the amount of change in threshold voltage in a NBTIS test, for example.

The high content of the element Min the metal oxide enables the transistor to be highly reliable against light. In other words, the amount of change in the threshold voltage of the transistor in the NBTIS test can be small. Specifically, in a metal oxide in which the atomic ratio of the element M is higher than or equal to that of indium, the band gap is increased and accordingly the amount of change in the threshold voltage of the transistor in the NBTIS test can be reduced. The band gap of the metal oxide in the semiconductor layer 231 is preferably greater than or equal to 2.0 eV, further preferably greater than or equal to 2.5 eV, still further preferably greater than or equal to 3.0 eV, yet still further preferably greater than or equal to 3.2 eV, yet still further preferably greater than or equal to 3.3 eV, yet still further preferably greater than or equal to 3.4 eV, yet still further preferably greater than or equal to 3.5 eV.

For example, the semiconductor layer 231 can include a metal oxide film having any of the following atomic ratios: In:M:Zn=1:1:1, In:M:Zn=1:1:1.2, In:M:Zn=1:3:2, In:M:Zn=1:3:3, In:M:Zn=1:3:4, and a neighborhood thereof.

For the semiconductor layer 231, in particular, it is preferable to use a metal oxide in which the atomic ratio of the element M to the metal elements contained in the metal oxide is higher than or equal to 20 atomic % and lower than or equal to 70 atomic %, preferably higher than or equal to 30 atomic % and lower than or equal to 70 atomic %, further preferably higher than or equal to 30 atomic % and lower than or equal to 60 atomic %, still further preferably higher than or equal to 40 atomic % and lower than or equal to 60 atomic %, yet still further preferably higher than or equal to 50 atomic % and lower than or equal to 60 atomic %.

In the case where an In—Ga—Zn oxide is used for the semiconductor layer 231, a metal oxide in which the atomic ratio of indium to the number of atoms of the metal elements is lower than or equal to the number of atoms of gallium can be used. For example, it is possible to use a metal oxide having any of the following atomic ratios: In:Ga:Zn=1:1:1, In:Ga:Zn=1:1:1.2, In:Ga:Zn=1:3:2, In:Ga:Zn=1:3:3, In:Ga:Zn=1:3:4, and a neighborhood thereof.

For the semiconductor layer 231, in particular, it is preferable to use a metal oxide in which the atomic ratio of gallium to the metal elements contained in the semiconductor layer is higher than or equal to 20 atomic % and lower than or equal to 60 atomic %, preferably higher than or equal to 20% atomic % and lower than or equal to 50 atomic %, further preferably higher than or equal to 30 atomic % and lower than or equal to 50 atomic %, still further preferably higher than or equal to 40% atomic % and lower than or equal to 60 atomic %, yet still further preferably higher than or equal to 50% atomic % and lower than or equal to 60 atomic %.

With use of a metal oxide with high content of the element M for the semiconductor layer 231, a transistor that is highly reliable against light can be provided. With use of the transistor as a transistor that is required to have high reliability against light, a highly reliable display apparatus can be provided.

As described above, electrical characteristics and reliability of a transistor vary depending on the composition of the metal oxide used for the semiconductor layer 231. Thus, by determining the composition of the metal oxide in accordance with the electrical characteristics and reliability required for the transistor, the display apparatus can have both excellent electrical characteristics and high reliability.

The semiconductor layer 231 may have a stacked-layer structure of two or more metal oxide layers. The two or more metal oxide layers included in the semiconductor layer 231 may have the same composition or substantially the same compositions. With the stacked-layer structure of metal oxide layers having the same composition, the manufacturing cost can be reduced because the metal oxide layers can be formed with the same sputtering target.

The two or more metal oxide layers included in the semiconductor layer 231 may have different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed. In particular, gallium or aluminum is preferably used as the element M. For another example, a stacked-layer structure of one selected from indium oxide, indium gallium oxide, and IGZO, and one selected from IAZO, IAGZO, and ITZO (registered trademark) may be employed.

It is preferable to use a metal oxide layer having crystallinity as the semiconductor layer 231. For example, a metal oxide layer having a CAAC (c-axis aligned crystal) structure, which is described later, a polycrystalline structure, a nano-crystal (nc) structure, or the like can be used. With the use of a metal oxide layer having crystallinity as the semiconductor layer 231, the density of defect states in the semiconductor layer 231 can be reduced, which enables the display apparatus to have high reliability.

The higher the crystallinity of the metal oxide layer used for the semiconductor layer 231 is, the lower the density of defect states in the semiconductor layer 231 can be. By contrast, the use of a metal oxide layer with low crystallinity enables a transistor to flow a large amount of current.

In the case where the metal oxide layer is formed by a sputtering method, the crystallinity of the formed metal oxide layer can be increased as the substrate temperature at the time of formation is higher. For example, the substrate temperature at the time of formation can be adjusted by the temperature of the stage where the substrate is placed. The crystallinity of the metal oxide layer can be increased as the proportion of a flow rate of an oxygen gas to the whole deposition gas (hereinafter also referred to as oxygen flow rate ratio) used at the time of formation or the oxygen partial pressure in a treatment chamber of a deposition apparatus is higher.

The semiconductor layer 231 may have a stacked-layer structure of two or more metal oxide layers having different crystallinities. For example, a stacked-layer structure of a first metal oxide layer and a second metal oxide layer provided over the first metal oxide layer can be employed, and the second metal oxide layer can include a region having higher crystallinity than the first metal oxide layer. Alternatively, the second metal oxide layer can include a region having lower crystallinity than the first metal oxide layer. The two or more metal oxide layers included in the semiconductor layer 231 may have the same composition or substantially the same compositions. With the stacked-layer structure of metal oxide layers having the same composition, for example, the metal oxide layers can be formed using the same sputtering target, which leads to a reduction in manufacturing cost. For example, the oxygen flow rate ratio or the oxygen partial pressure is made different using the same sputtering target, whereby a stacked-layer structure of two or more metal oxide layers having different crystallinities can be formed. Note that the two or more metal oxide layers included in the semiconductor layer 231 may have different compositions.

The thickness of the semiconductor layer 231 is preferably larger than or equal to 3 nm and smaller than or equal to 100 nm, further preferably larger than or equal to 5 nm and smaller than or equal to 100 nm, still further preferably larger than or equal to 10 nm and smaller than or equal to 100 nm, yet still further preferably larger than or equal to 10 nm and smaller than or equal to 70 nm, yet still further preferably larger than or equal to 15 nm and smaller than or equal to 70 nm, yet still further preferably larger than or equal to 15 nm and smaller than or equal to 50 nm, yet still further preferably larger than or equal to 20 nm and smaller than or equal to 50 nm, yet still further preferably larger than or equal to 20 nm and smaller than or equal to 40 nm, yet still further preferably larger than or equal to 25 nm and smaller than or equal to 40 nm.

The substrate temperature at the time of forming the semiconductor layer 231 is preferably higher than or equal to room temperature (25° C.) and lower than or equal to 200° C., further preferably higher than or equal to room temperature and lower than or equal to 130° C. With the substrate temperature in the above range, the bending or warpage of the substrate can be inhibited in the case where a large-area glass substrate is used.

Here, oxygen vacancies that might be formed in the semiconductor layer 231 is described.

In the case where an oxide semiconductor is used for the semiconductor layer 231, hydrogen contained in the oxide semiconductor reacts with oxygen bonded to a metal atom to be water, and thus sometimes forms an oxygen vacancy (Vo) in the oxide semiconductor. In some cases, a defect where hydrogen enters an oxygen vacancy (hereinafter, referred to as VoH) functions as a donor and generates an electron serving as a carrier. In other cases, bonding of part of hydrogen to oxygen bonded to a metal atom generates electrons serving as carriers. Thus, a transistor using an oxide semiconductor that contains a large amount of hydrogen is likely to be normally-on. Moreover, hydrogen in an oxide semiconductor is easily transferred by a stress such as heat or an electric field; thus, a large amount of hydrogen in an oxide semiconductor might reduce the reliability of a transistor.

VoH can serve as a donor of the oxide semiconductor. However, it is difficult to evaluate the defect quantitatively. Thus, the oxide semiconductor is sometimes evaluated by not its donor concentration but its carrier concentration. Therefore, in this specification and the like, the carrier concentration assuming the state where an electric field is not applied is sometimes used, instead of the donor concentration, as the parameter of the oxide semiconductor. That is, “carrier concentration” described in this specification and the like can be replaced with “donor concentration” in some cases.

Accordingly, in the case where an oxide semiconductor is used as the semiconductor layer 231, the amount of VoH in the semiconductor layer 231 is preferably reduced as much as possible so that the semiconductor layer 231 becomes a highly purified intrinsic or substantially highly purified intrinsic semiconductor layer. In order to obtain such an oxide semiconductor with sufficiently reduced VoH, it is important to remove impurities such as water and hydrogen in the oxide semiconductor (this treatment is sometimes referred to as dehydration or dehydrogenation treatment) and repair oxygen vacancies (Vo) by supply of oxygen to the oxide semiconductor. When an oxide semiconductor with sufficiently reduced impurities such as VoH is used for a channel formation region of a transistor, stable electrical characteristics can be given. Note that repairing oxygen vacancies (Vo) by supply of oxygen to the oxide semiconductor is sometimes referred to as oxygen adding treatment.

When an oxide semiconductor is used for the semiconductor layer 231, the carrier concentration of the oxide semiconductor in a region functioning as a channel formation region is preferably lower than or equal to 1×10¹⁸ cm⁻³ further preferably lower than 1×10¹⁷ cm⁻³, still further preferably lower than 1×10¹⁶ cm⁻³, yet still further preferably lower than 1×10¹³ cm⁻³, yet still further preferably lower than 1×10¹² cm⁻³. Note that the lower limit of the carrier concentration of the oxide semiconductor in the region functioning as the channel formation region is not particularly limited and can be, for example, 1×10⁻⁹ cm³.

A transistor containing a metal oxide semiconductor (hereinafter also referred to as an OS transistor) has much higher field-effect mobility than a transistor using amorphous silicon. In addition, the OS transistor has extremely low leakage current between a source and a drain in an off state (hereinafter also referred to as off-state current), and charge accumulated in a capacitor that is connected in series to the transistor can be retained for a long period. Furthermore, the power consumption of the display apparatus can be reduced with the OS transistor.

To increase the emission luminance of the light-emitting device included in a pixel circuit of a display apparatus, it is necessary to increase the amount of current flowing through the light-emitting device. For that purpose, the source-drain voltage of the driving transistor included in the pixel circuit needs to be increased. Since an OS transistor has a higher withstand voltage between the source and the drain than a transistor including silicon (hereinafter referred to as a Si transistor), a high voltage can be applied between the source and the drain of the OS transistor. Thus, by using an OS transistor as a driving transistor included in the pixel circuit, the amount of current flowing through the light-emitting device can be increased, resulting in an increase in emission luminance of the light-emitting device.

When a transistor operates in a saturation region, a change in source-drain current relative to a change in gate-source voltage can be smaller in an OS transistor than in a Si transistor. Accordingly, when an OS transistor is employed as the driving transistor included in the pixel circuit, the amount of current flowing between the source and the drain can be finely set by a change in gate-source voltage; thus, the amount of current flowing through the light-emitting device can be controlled. Thus, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be fed through the OS transistor than through a Si transistor. Thus, with use of an OS transistor as a driving transistor, current can be made flow stably to the light-emitting device, for example, even when a variation in current-voltage characteristics of the light-emitting device occurs. In other words, when the OS transistor operates in the saturation region, the source-drain current hardly changes even with an increase in the source-drain voltage; thus, the emission luminance of the light-emitting device can be stable.

As described above, with the use of an OS transistor as the driving transistor included in the pixel circuit, it is possible to achieve “inhibition of black floating,” “increase in emission luminance,” “increase in the number of gray levels,” “inhibition of variation in light-emitting devices,” and the like.

A change in electrical characteristics of an OS transistor due to irradiation with radiation is small, i.e., an OS transistor has high tolerance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a display apparatus used in space. Examples of radiation include electromagnetic radiation (e.g., X-rays and gamma rays) and particle radiation (e.g., alpha rays, beta rays, a proton beam, and a neutron beam).

### [Insulating Layer 210]

For the insulating layer 210, an inorganic insulating material or an organic insulating material can be used. The insulating layer 210 may have a stacked-layer structure of an inorganic insulating material and an organic insulating material.

For the insulating layer 210, an organic material can be suitably used. As the inorganic insulating material, one or more of an oxide, an oxynitride, a nitride oxide, and a nitride can be used. For the insulating layer 210, for example, one or more of silicon oxide, silicon oxynitride, aluminum oxide, hafnium oxide, yttrium oxide, zirconium oxide, gallium oxide, tantalum oxide, magnesium oxide, lanthanum oxide, cerium oxide, neodymium oxide, silicon nitride, silicon nitride oxide, and aluminum nitride can be used.

Note that in this specification and the like, an oxynitride refers to a material that contains more oxygen than nitrogen. A nitride oxide refers to a material that contains more nitrogen than oxygen in its composition. For example, a silicon oxynitride refers to a material that contains more oxygen than nitrogen in its composition, and a silicon nitride oxide refers to a material that contains more nitrogen than oxygen in its composition.

The oxygen and nitrogen contents can be analyzed using secondary ion mass spectrometry (SIMS) or X-ray photoelectron spectroscopy (XPS). XPS is suitable when the content percentage of a target element is high (e.g., higher than or equal to 0.5 atomic %, or higher than or equal to 1 atomic %). By contrast, SIMS is suitable when the content percentage of a target element is low (e.g., lower than 0.5 atomic % or lower than 1 atomic %). To compare contents of elements, analysis with a combination of SIMS and XPS is further preferably used.

The insulating layer 210 may have a stacked structure of two or more layers. FIG. 3B and the like illustrate a structure in which the insulating layer 210 has a stacked-layer structure of an insulating layer 210a and an insulating layer 210b over the insulating layer 210a. For each of the insulating layer 210a and the insulating layer 210b, the material that can be used for the insulating layer 210 can be used. Note that for the insulating layer 210a and the insulating layer 210b, the same material or different materials may be used. Note that the insulating layer 210a may have a stacked structure of two or more layers. Note that the insulating layer 210b may have a stacked structure of two or more layers.

The thickness of the insulating layer 210a can be larger than that of the insulating layer 210b. The deposition rate of the insulating layer 210a is preferably high. In particular, in the case where the insulating layer 210a has a large thickness, the deposition rate of the insulating layer 210a is preferably high. By increasing the deposition rate of the insulating layer 210a, the productivity can be increased. For example, when power at the time of forming the insulating layer 210a is increased, the deposition rate can be increased.

The stress of the insulating layer 210a is preferably low. When the thickness of the insulating layer 210a is increased, the stress of the insulating layer 210a is increased, so that warpage of the substrate is generated in some cases. When the stress of the insulating layer 210a is reduced, occurrence of problems due to stress during the process, such as warpage of the substrate, can be inhibited.

The insulating layer 210b functions as a blocking film that inhibits release of gas from the insulating layer 210a. For the insulating layer 210b, a material that does not easily allow diffusion of gas is preferably used. The insulating layer 210b preferably includes a region having a higher film density than the insulating layer 210a. With a higher film density, the insulating layer 210b can have a higher blocking property. For the insulating layer 210b, a material having a higher nitrogen content than the insulating layer 210a can be used, for example. With a higher nitrogen content, the insulating layer 210b can have a higher blocking property.

The insulating layer 210b can be thinner than the insulating layer 210a as long as the insulating layer 210b has a thickness with which the insulating layer can function as a blocking film that inhibits release of gas from the insulating layer 210a. The deposition rate of the insulating layer 210b is preferably lower than the deposition rate of the insulating layer 210a. Note that when the deposition rate of the insulating layer 210b is made low, the insulating layer 210b has a high film density, and thus can have a high blocking property. Similarly, when the substrate temperature at the time of forming the insulating layer 210b is increased, the insulating layer 210b has a high film density, and thus can have a high blocking property.

Even when containing the same material, the insulating layer 210a and the insulating layer 210b have different film densities; thus, the boundary therebetween can sometimes be observed as a difference in contrast in a transmission electron microscopy (TEM) image or the like of the cross section of the insulating layer 210. In the TEM observation, the transmission electron (TE) image is dark-colored (dark) when the film density is high, and the transmission electron (TE) image is pale (bright) when the film density is low. Thus, in the transmission electron (TE) image, the insulating layer 210b is sometimes illustrated as a dark-colored (dark) image compared to the insulating layer 210a.

The insulating layer 210b sometimes includes a region having a lower hydrogen concentration than the insulating layer 210a. The difference in hydrogen concentration between the insulating layer 210a and the insulating layer 210b can be examined by secondary ion mass spectrometry (SIMS), for example.

Here, the insulating layer 210 is specifically described with use of a structure in which a metal oxide is used for the semiconductor layer 231 as an example.

In the case where an oxide semiconductor is used for the semiconductor layer 231, an inorganic insulating material can be suitably used for each of the insulating layer 210a and the insulating layer 210b.

An oxide or an oxynitride is preferably used for the insulating layer 210a. A film from which oxygen is released by heating is preferably used as the insulating layer 210a. Silicon oxide or silicon oxynitride can be suitably used as the insulating layer 210a, for example.

When the insulating layer 210a releases oxygen, oxygen can be supplied from the insulating layer 210a to the semiconductor layer 231. Supply of oxygen from the insulating layer 210a to the semiconductor layer 231, particularly to the channel formation region of the semiconductor layer 231, can reduce oxygen vacancies (Vo) and VoH in the semiconductor layer 231, so that the transistor can have favorable electrical characteristics and high reliability. The insulating layer 210a preferably has a high oxygen diffusion coefficient. When the diffusion coefficient of oxygen in the insulating layer 210a is increased, oxygen can be easily diffused into the insulating layer 210a, and oxygen can be efficiently supplied from the insulating layer 210a to the semiconductor layer 231. Note that examples of treatment for supplying oxygen to the semiconductor layer 231 include heat treatment in an oxygen-containing atmosphere and plasma treatment in an oxygen-containing atmosphere.

The amount of impurities (e.g., water and hydrogen) released from the insulating layer 210a itself is preferably small. When the amount of impurities released from the insulating layer 210a is reduced, diffusion of impurities into the semiconductor layer 231 is inhibited, and the transistor can have favorable electrical characteristics and high reliability.

Silicon oxide or silicon oxynitride deposited by a PECVD method can be suitably used as the insulating layer 210a, for example. In that case, a mixed gas including a gas containing silicon and a gas containing oxygen is preferably used as a source gas. As the gas containing silicon, for example, one or more of silane, disilane, trisilane, and silane fluoride can be used. As the gas containing oxygen, for example, one or more of oxygen (O₂), ozone (O₃), dinitrogen monoxide (N₂O), nitrogen monoxide (NO), and nitrogen dioxide (NO₂) can be used. Note that increasing the power at the time of forming the insulating layer 210a can reduce the amount of impurities (e.g., water and hydrogen) released from the insulating layer 210a.

The insulating layer 210b is preferably less likely to transmit oxygen. The insulating layer 210b functions as a blocking film that inhibits release of oxygen from the insulating layer 210a. Furthermore, the insulating layer 210b is preferably less likely to transmit hydrogen. The insulating layer 210b functions as a blocking film that inhibits diffusion of hydrogen from the outside of the transistor into the semiconductor layer 231 through the insulating layer 210. The film density of the insulating layer 210b is preferably high. The blocking property against oxygen and hydrogen of the insulating layer 210b can be enhanced by increasing the film density of the insulating layer 210b. The film density of the insulating layer 210b is preferably higher than that of the insulating layer 210a. The insulating layer 210b preferably includes a region having a higher nitrogen content than the insulating layer 210a, for example. For the insulating layer 210b, a material having a higher nitrogen content than the insulating layer 210a can be used, for example. A nitride or a nitride oxide is preferably used for the insulating layer 210b. A silicon nitride or a silicon oxynitride can be suitably used as the insulating layer 210b, for example.

When oxygen contained in the insulating layer 210a is diffused upward from a region of the insulating layer 210a that is not in contact with the semiconductor layer 231 (e.g., the top surface of the insulating layer 210a), the amount of oxygen supplied from the insulating layer 210a to the semiconductor layer 231 is reduced in some cases. Provision of the insulating layer 210b over the insulating layer 210a can inhibit diffusion of oxygen contained in the insulating layer 210a from a region of the insulating layer 210a that is not in contact with the semiconductor layer 231. Thus, the amount of oxygen supplied from the insulating layer 210a to the semiconductor layer 231 is increased, so that oxygen vacancies (Vo) and VoH in the semiconductor layer 231 can be reduced. Consequently, the transistor can have favorable electrical characteristics and high reliability.

The conductive layer 222b is oxidized by oxygen contained in the insulating layer 210a and has high resistance in some cases. When the conductive layer 222b is oxidized by oxygen contained in the insulating layer 210a, the amount of oxygen supplied from the insulating layer 210a to the semiconductor layer 231 is reduced in some cases. Provision of the insulating layer 210b over the insulating layer 210a can inhibit the conductive layer 222b from being oxidized and having high resistance. In addition, the amount of oxygen supplied from the insulating layer 210a to the semiconductor layer 231 is increased, and oxygen vacancies (Vo) and VoH in the semiconductor layer 231 can be reduced, so that the transistor can have favorable electrical characteristics and high reliability.

When hydrogen is diffused into the semiconductor layer 231, hydrogen reacts with an oxygen atom contained in the oxide semiconductor to be water, so that an oxygen vacancy (Vo) is formed in some cases. Furthermore, VoH is formed and the carrier concentration is increased in some cases. Provision of the insulating layer 210b over the insulating layer 210a can reduce oxygen vacancies (Vo) and VoH in the semiconductor layer 231, so that the transistor can have favorable electrical characteristics and high reliability.

The insulating layer 210b preferably has a thickness with which the insulating layer can function as a blocking film against oxygen and hydrogen. When the thickness of the insulating layer 210b is small, the function of a blocking film might deteriorate. Meanwhile, when the thickness of the insulating layer 210b is large, a region of the semiconductor layer 231 in contact with the insulating layer 210a is narrowed and the amount of oxygen supplied from the insulating layer 210a to the semiconductor layer 231 is reduced in some cases. The thickness of the insulating layer 210b may be smaller than that of the insulating layer 210a. The thickness of the insulating layer 210b is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, yet still further preferably larger than or equal to 20 nm and smaller than or equal to 50 nm, yet still further preferably larger than or equal to 20 nm and smaller than or equal to 40 nm. When the thickness of the insulating layer 210b is in the above range, oxygen vacancies (Vo) and VoH in the semiconductor layer 231, in particular, in the channel formation region can be reduced, so that the transistor can have favorable electrical characteristics and high reliability.

The amount of impurities (e.g., water and hydrogen) released from the insulating layer 210b itself is preferably small. When the amount of impurities released from the insulating layer 210b is reduced, diffusion of impurities into the semiconductor layer 231 is inhibited, and the transistor can have favorable electrical characteristics and high reliability.

In the transistor 200, a region of the semiconductor layer 231 in contact with the insulating layer 210 can function as the channel formation region. That is, oxygen is selectively supplied to the channel formation region, so that oxygen vacancies (Vo) and VoH can be reduced. Consequently, the transistor can have favorable electrical characteristics and high reliability.

### [Conductive Layer 222a, Conductive Layer 222b, and Conductive Layer 223]

The conductive layer 222a and the conductive layer 222b functioning as the source electrode and the drain electrode and the conductive layer 223 functioning as the gate electrode can each be formed using one or more of chromium, copper, aluminum, gold, silver, zinc, molybdenum, tantalum, titanium, tungsten, manganese, nickel, iron, cobalt, and niobium or an alloy containing one or more of the above metals as its component. For the conductive layer 223, the conductive layer 222a, and the conductive layer 222b, a low-resistance conductive material containing one or more of copper, silver, gold, and aluminum can be suitably used. Copper or aluminum is particularly preferable because of its high mass-productivity.

For the conductive layer 223, the conductive layer 222a, and the conductive layer 222b, a conductive metal oxide (also referred to as an oxide conductor) can be used. Examples of an oxide conductor (OC) include In—Sn oxide (ITO), In—W oxide, In—W—Zn oxide, In—Ti oxide, In—Ti—Sn oxide, In—Zn oxide, In—Sn—Si oxide (ITSO), and In—Ga—Zn oxide.

Here, an oxide conductor (OC) is described. For example, when oxygen vacancies are formed in a metal oxide having semiconductor characteristics and hydrogen is added to the oxygen vacancies, a donor level is formed in the vicinity of the conduction band. As a result, the conductivity of the metal oxide is increased, so that the metal oxide becomes a conductor. The metal oxide having become a conductor can be referred to as an oxide conductor.

In addition, each of the conductive layer 223, the conductive layer 222a, and the conductive layer 222b may have a stacked-layer structure of a conductive film containing the above-described oxide conductor (the metal oxide) and a conductive film containing a metal or an alloy. The use of the conductive film containing a metal or an alloy can reduce the wiring resistance.

A Cu—X alloy film (X is Mn, Ni, Cr, Fe, Co, Mo, Ta, or Ti) may be used for the conductive layer 223, the conductive layer 222a, and the conductive layer 222b. The use of a Cu—X alloy film enables the manufacturing cost to be reduced because processing can be performed by a wet etching method.

Note that the conductive layer 223, the conductive layer 222a, and the conductive layer 222b may be formed using the same material or different materials.

Here, the conductive layer 222a and the conductive layer 222b are described in detail with use of a structure in which a metal oxide is used for the semiconductor layer 231 as an example.

In the case where an oxide semiconductor is used for the semiconductor layer 231, the conductive layer 222a and the conductive layer 222b are oxidized by oxygen contained in the semiconductor layer 231 and have high resistance in some cases. The conductive layer 222a and the conductive layer 222b are oxidized by oxygen contained in the insulating layer 210a and have high resistance in some cases. When the conductive layer 222a and the conductive layer 222b are oxidized by oxygen contained in the semiconductor layer 231, oxygen vacancies (Vo) in the semiconductor layer 231 are increased in some cases. When the conductive layer 222a and the conductive layer 222b are oxidized by oxygen contained in the insulating layer 210a, the amount of oxygen supplied from the insulating layer 210a to the semiconductor layer 231 is reduced in some cases.

A material that is less likely to be oxidized is preferably used for each of the conductive layer 222a and the conductive layer 222b. An oxide conductor is preferably used for each of the conductive layer 222a and the conductive layer 222b. For example, an In—Sn oxide (ITO) or an In—Sn—Si oxide (ITSO) can be suitably used for each of the conductive layer 222a and the conductive layer 222b. The conductive layer 222a and the conductive layer 222b may each be formed using a nitride conductor. Examples of the nitride conductor include tantalum nitride and titanium nitride. The conductive layer 222a and the conductive layer 222b may each have a stacked-layer structure of the above materials.

The use of a material that is less likely to be oxidized for the conductive layer 222a and the conductive layer 222b can inhibit an increase in resistance due to oxidation caused by oxygen contained in the semiconductor layer 231 or oxygen contained in the insulating layer 210a. Furthermore, an increase in oxygen vacancies (Vo) in the semiconductor layer 231 can be inhibited, and the amount of oxygen supplied from the insulating layer 210a to the semiconductor layer 231 can be increased. Accordingly, oxygen vacancies (Vo) and VoH in the semiconductor layer 231 can be reduced, and the transistor can have favorable electrical characteristics and high reliability. Note that the conductive layer 222a and the conductive layer 222b may be formed using the same material or different materials.

### [Insulating Layer 225]

The insulating layer 225 functioning as the gate insulating layer preferably has low defect density. With the insulating layer 225 having low defect density, the transistor can have favorable electrical characteristics. Furthermore, the insulating layer 225 preferably has high withstand voltage. The high withstand voltage of the insulating layer 225 results in a transistor with high reliability.

For the insulating layer 225, one or more of an insulating oxide, an insulating oxynitride, an insulating nitride oxide, and an insulating nitride can be used, for example. For the insulating layer 225, one or more of silicon oxide, silicon oxynitride, silicon nitride oxide, silicon nitride, aluminum oxide, aluminum oxynitride, aluminum nitride oxide, aluminum nitride, hafnium oxide, hafnium oxynitride, gallium oxide, gallium oxynitride, yttrium oxide, yttrium oxynitride, and a Ga—Zn oxide can be used. The insulating layer 225 may have either a single-layer structure or a stacked-layer structure. The insulating layer 225 may have a stacked-layer structure of an oxide and a nitride, for example.

Note that in a miniaturized transistor, the small thickness of the gate insulating layer causes large leakage current in some cases. When a material with a high relative permittivity (also referred to as a high-k material) is used for the gate insulating layer, the voltage at the time of operation of the transistor can be reduced while the physical thickness is maintained. Examples of the high-k material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

The amount of impurities (e.g., water and hydrogen) released from the insulating layer 225 itself is preferably small. When the amount of impurities released from the insulating layer 225 is reduced, diffusion of impurities into the semiconductor layer 231 is inhibited, and the transistor can have favorable electrical characteristics and high reliability.

The insulating layer 225 is formed over the semiconductor layer 231, and thus is preferably a film formed under conditions where damage to the semiconductor layer 231 is small. For example, the insulating layer 225 can be formed at a sufficiently low deposition rate. For example, when the insulating layer 225 is formed by a plasma CVD method under a low-power condition, damage to the semiconductor layer 231 can be extremely small.

Here, the insulating layer 225 is specifically described with use of a structure in which a metal oxide is used for the semiconductor layer 231 as an example.

In order to improve the properties of the interface with the semiconductor layer 231, an oxide or an oxynitride is preferably used as at least the side of the insulating layer 225 in contact with the semiconductor layer 231. One or more of a silicon oxide or a silicon oxynitride can be suitably used for the insulating layer 225, for example. Moreover, a film from which oxygen is released by heating is preferably used as the insulating layer 225.

Note that the insulating layer 225 may have a stacked-layer structure. For the insulating layer 225, an oxide or an oxynitride can be used on the side in contact with the semiconductor layer 231, and a nitride or a nitride oxide can be used on the side in contact with the conductive layer 223. As the oxide or the oxynitride, for example, one or more of a silicon oxide and a silicon oxynitride can be suitably used. As the nitride or the nitride oxide, a silicon nitride can be suitably used, for example.

The above is the description of the components.

Note that in the case where a metal oxide is used for the semiconductor layer 231 and the insulating layer 210b contains hydrogen, it is possible that hydrogen is diffused into the semiconductor layer 231 in a region in contact with the insulating layer 210b and that oxygen vacancies (Vo) and VoH are increased in the semiconductor layer 231. Accordingly, in some cases, a region of the semiconductor layer 231 in contact with the insulating layer 210b functions as a source region or a drain region, and a region of the semiconductor layer 231 in contact with the insulating layer 210a functions as a channel formation region. That is, a region of the semiconductor layer 231 in contact with the conductive layer 222b and the region of the semiconductor layer 231 in contact with the insulating layer 210b function as a source region or a drain region in some cases.

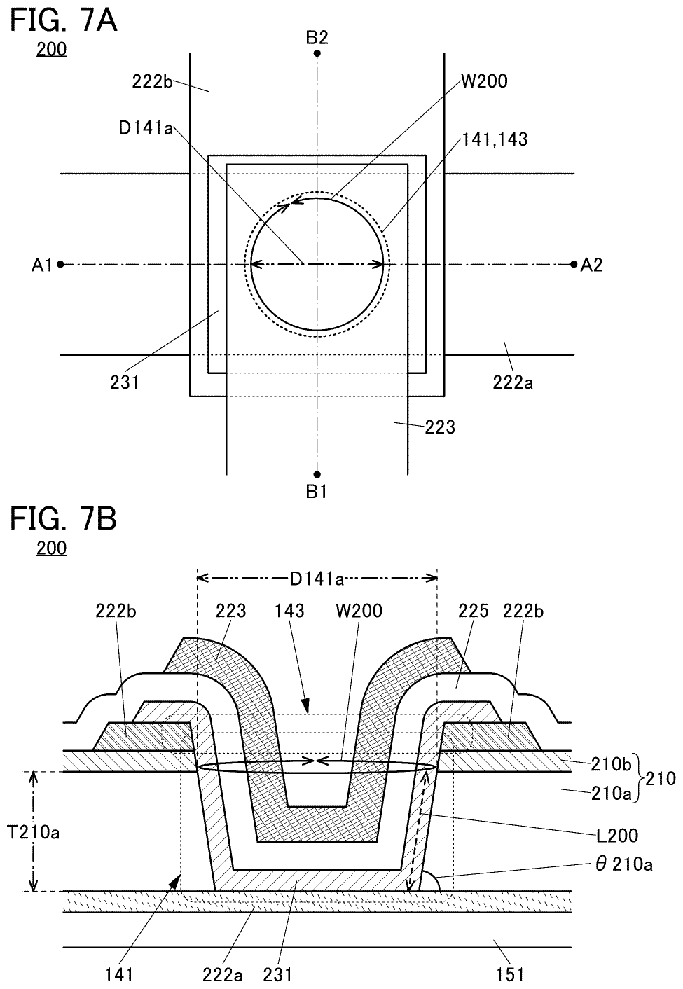

A channel length and a channel width in the case where a region of the semiconductor layer 231 in contact with the insulating layer 210b functions as a source region or a drain region are described with reference to FIG. 7A and FIG. 7B. FIG. 7A is a top view of the transistor 200. FIG. 7B is an enlarged view of FIG. 3B.

The channel length L200 of the transistor 200 corresponds to the length of the side surface of the insulating layer 210a on the opening 141 side in the cross-sectional view. That is, the channel length L200 is determined by a thickness T210a of the insulating layer 210a and an angle θ210a formed by the side surface of the insulating layer 210a on the opening 141 side and the formation surface of the insulating layer 210a (here, the top surface of the conductive layer 222a), and is not affected by the performance of the light-exposure apparatus used for manufacturing the transistor. Thus, the channel length L200 can be a value smaller than the resolution limit of the light-exposure apparatus, so that a miniaturized transistor can be achieved. For example, the channel length L200 can be within the above-described range. In FIG. 7B, the thickness T210a of the insulating layer 210a is indicated by a dashed-dotted double-headed arrow.

By adjusting the thickness T210a and the angle θ210a of the insulating layer 210a, the channel length L200 can be controlled.

The thickness T210a of the insulating layer 210a is preferably larger than or equal to 0.01 μm and smaller than 3 μm, further preferably larger than or equal to 0.05 μm and smaller than 3 μm, still further preferably larger than or equal to 0.1 μm and smaller than 3 μm, yet further preferably larger than or equal to 0.15 μm and smaller than 3 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

The angle θ210a formed by the side surface of the insulating layer 210a on the opening 141 side and the formation surface of the insulating layer 210a (here, the top surface of the conductive layer 222a) is preferably greater than or equal to 450 and less than 90°, further preferably greater than or equal to 500 and less than 90°, still further preferably greater than or equal to 550 and less than 90°, yet still further preferably greater than or equal to 600 and less than 90°, yet still further preferably greater than or equal to 600 and less than or equal to 85°, yet still further preferably greater than or equal to 650 and less than or equal to 85°, yet still further preferably greater than or equal to 650 and less than or equal to 80°, yet still further preferably greater than or equal to 700 and less than or equal to 80°.

The channel width W200 is the length of the end portion of the bottom surface of the insulating layer 210b on the opening 141 side in the top view. In FIG. 7A and FIG. 7B, the channel width W200 of the transistor 200 is indicated by a solid double-headed arrow.

The channel width W200 is determined by the shape of the end portion of the bottom surface of the insulating layer 210b. In FIG. 7A and FIG. 7B, a width D141a between the facing end portions of the bottom surface of the insulating layer 210b in the opening 141 is indicated by a double-dotted double-headed arrow. In the top view, the width D141a refers to the short side of the smallest rectangle circumscribing the outline of the end portion of the bottom surface of the insulating layer 210b. For example, the width D141a is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

Note that hydrogen may also diffuse from the insulating layer 210b into a region of the semiconductor layer 231 in contact with the insulating layer 210a. However, supply of oxygen from the insulating layer 210a to the semiconductor layer 231 inhibits an increase in oxygen vacancies (Vo) and VoH in the region of the semiconductor layer 231 in contact with the insulating layer 210a. Thus, at least the region of the semiconductor layer 231 in contact with the insulating layer 210a can function as a channel formation region, so that the transistor can have favorable electrical characteristics and high reliability.

A structure example of a transistor whose structure is partly different from that of Structure example 1 of transistor is described below. Note that description of the same portions as those in Structure example 1 of transistor is omitted below in some cases. Furthermore, in drawings to be used later, the same hatching pattern is applied to portions having functions similar to those in Structure example 1 of transistor, and the portions are not indicated by reference numerals in some cases.

### [Structure Example 2 of Transistor]

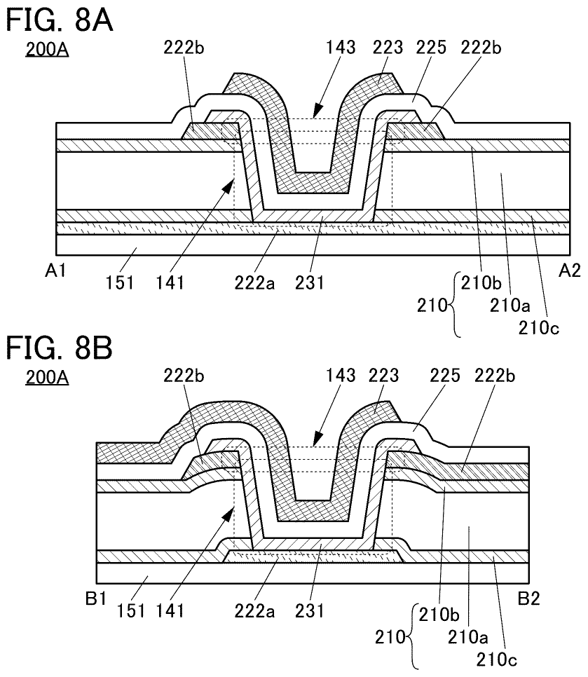

FIG. 3A can be referred to for a top view of a transistor 200A that can be used in the display apparatus of one embodiment of the present invention. FIG. 8A is a cross-sectional view of a cut plane along the dashed-dotted line A1-A2 in FIG. 3A, and FIG. 8B is a cross-sectional view of a cut plane along the dashed-dotted line B1-B2 in FIG. 3A. FIG. 4 can be referred to for a perspective view of the transistor 200A.

The transistor 200A is different from the above-described transistor 200 mainly in that the insulating layer 210 includes the insulating layer 210c.

The insulating layer 210 has a stacked-layer structure of the insulating layer 210c, the insulating layer 210a over the insulating layer 210c, and the insulating layer 210b over the insulating layer 210a. The insulating layer 210c includes a region in contact with the top surface of the substrate 151 and the top surface and the side surface of the conductive layer 222a.

The insulating layer 210c functions as a blocking film that inhibits release of gas from the insulating layer 210a. For the insulating layer 210c, a material that does not easily allow diffusion of gas is preferably used. The insulating layer 210c preferably includes a region having a higher film density than the insulating layer 210a. With a higher film density, the insulating layer 210c can have a higher blocking property. The insulating layer 210c preferably includes a region having a higher nitrogen content than the insulating layer 210a, for example. For the insulating layer 210c, a material having a higher nitrogen content than the insulating layer 210a can be used, for example. With a higher nitrogen content, the insulating layer 210c can have a higher blocking property.

The insulating layer 210c can be thinner than the insulating layer 210c as long as the insulating layer 210c has a thickness with which the insulating layer functions as a blocking film that inhibits release of gas from the insulating layer 210a. The deposition rate of the insulating layer 210c is preferably lower than the deposition rate of the insulating layer 210a. Note that when the deposition rate of the insulating layer 210c is made low, the insulating layer 210c has a high film density, and thus can have a high blocking property. Similarly, when the substrate temperature at the time of forming the insulating layer 210c is increased, the insulating layer 210c has a high film density, and thus can have a high blocking property.

Even when containing the same material, the insulating layer 210a and the insulating layer 210c have different film densities; thus, the boundary therebetween can sometimes be observed as a difference in contrast in a transmission electron microscopy (TEM) image or the like of the cross section of the insulating layer 210. In the TEM observation, the transmission electron (TE) image is dark-colored (dark) when the film density is high, and the transmission electron (TE) image is pale (bright) when the film density is low. Thus, in the transmission electron (TE) image, the insulating layer 210c is sometimes illustrated as a dark-colored (dark) image compared to the insulating layer 210a.

The insulating layer 210a sometimes includes a region where the hydrogen concentration in the film is higher than that of the insulating layer 210c. The difference in hydrogen concentration between the insulating layer 210a and the insulating layer 210c can be examined by secondary ion mass spectrometry (SIMS), for example.

For the insulating layer 210c, a material that can be used for the insulating layer 210b can be used. For the insulating layer 210c and the insulating layer 210b, the same organic material or different organic materials may be used.

The insulating layer 210c is described in detail with an example in which an oxide semiconductor is used for the semiconductor layer 231.

The insulating layer 210c is preferably less likely to transmit oxygen. The insulating layer 210c functions as a blocking film that inhibits release of oxygen from the insulating layer 210a.

The conductive layer 222a is oxidized by oxygen contained in the insulating layer 210a and has high resistance in some cases. Moreover, when the conductive layer 222a is oxidized by oxygen contained in the insulating layer 210a, the amount of oxygen supplied from the insulating layer 210a to the semiconductor layer 231 is reduced in some cases. Provision of the insulating layer 210c between the insulating layer 210a and the conductive layer 222a can inhibit the conductive layer 222a from being oxidized and having high resistance. In addition, the amount of oxygen supplied from the insulating layer 210a to the semiconductor layer 231 is increased, and oxygen vacancies (Vo) and VoH in the semiconductor layer 231 can be reduced, so that the transistor can have favorable electrical characteristics and high reliability.

The insulating layer 210c is preferably less likely to transmit impurities. The insulating layer 210c functions as a blocking film that inhibits diffusion of impurities from the substrate 151 side into the semiconductor layer 231 through the insulating layer 210. Examples of the impurities include water, hydrogen, and sodium.

The insulating layer 210c preferably has a thickness with which the insulating layer can function as a blocking film against oxygen and hydrogen. When the thickness of the insulating layer 210c is small, the function of a blocking film might deteriorate. Meanwhile, when the thickness of the insulating layer 210c is large, a region where the semiconductor layer 231 is in contact with the insulating layer 210a is narrowed and the amount of oxygen supplied from the insulating layer 210a to the semiconductor layer 231 is reduced in some cases. The thickness of the insulating layer 210c may be smaller than the thickness of the insulating layer 210a. The thickness of the insulating layer 210c is preferably larger than or equal to 5 nm and smaller than or equal to 100 nm, further preferably larger than or equal to 5 nm and smaller than or equal to 70 nm, still further preferably larger than or equal to 10 nm and smaller than or equal to 70 nm, yet still further preferably larger than or equal to 10 nm and smaller than or equal to 50 nm, yet still further preferably larger than or equal to 20 nm and smaller than or equal to 50 nm, yet still further preferably larger than or equal to 20 nm and smaller than or equal to 40 nm. When the thickness of the insulating layer 210c is within the above range, oxygen vacancies (Vo) and VoH in the semiconductor layer 231, particularly in the channel formation region can be reduced, so that the transistor can have favorable electric characteristics and high reliability.

The amount of impurities (e.g., water and hydrogen) released from the insulating layer 210c itself is preferably small. When the amount of impurities released from the insulating layer 210c is reduced, diffusion of impurities into the semiconductor layer 231 is inhibited, and the transistor can have favorable electrical characteristics and high reliability.

Note that in the case where a metal oxide is used for the semiconductor layer 231 and the insulating layer 210c contains hydrogen, it is possible that hydrogen diffuses into the semiconductor layer 231 in a region in contact with the insulating layer 210c and that oxygen vacancies (Vo) and VoH are increased in the semiconductor layer 231. Accordingly, a region of the semiconductor layer 231 in contact with the insulating layer 210c functions as the source region or the drain region in some cases. Similarly, a region of the semiconductor layer 231 in contact with the insulating layer 210b functions as a source region or a drain region in some cases. A region in contact with the insulating layer 210a functions as a channel formation region in some cases.

In the case where a region of the semiconductor layer 231 in contact with the insulating layer 210b and a region of the semiconductor layer 231 in contact with the insulating layer 210c function as a source region and a drain region, the channel length L200 of the transistor 200 corresponds to the length of the side surface of the insulating layer 210a on the opening 141 side in the cross-sectional view (see FIG. 7B).

Note that hydrogen may also diffuse from the insulating layer 210c into a region of the semiconductor layer 231 in contact with the insulating layer 210a. However, supply of oxygen from the insulating layer 210a to the semiconductor layer 231 inhibits an increase in oxygen vacancies (Vo) and VoH in the region of the semiconductor layer 231 in contact with the insulating layer 210a. Thus, at least the region of the semiconductor layer 231 in contact with the insulating layer 210a can function as a channel formation region, so that the transistor can have favorable electrical characteristics and high reliability.

Note that the structure of the insulating layer 210 described here can also be applied to other structure examples.

### [Structure Example 3 of Transistor]

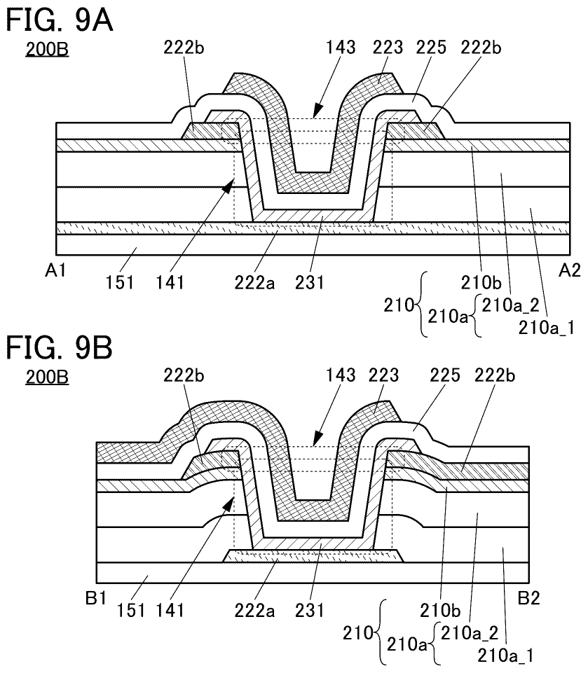

FIG. 3A can be referred to for a top view of a transistor 200B that can be used in the display apparatus of one embodiment of the present invention. FIG. 9A is a cross-sectional view of a cut plane along the dashed-dotted line A1-A2 in FIG. 3A and FIG. 9B is a cross-sectional view of a cut plane along the dashed-dotted line B1-B2 in FIG. 3A. FIG. 4 can be referred to for a perspective view of the transistor 200B.

The transistor 200B is different from the above-described transistor 200 mainly in that the insulating layer 210a has a stacked-layer structure.

The insulating layer 210a has a stacked-layer structure of an insulating layer 210a_1 and an insulating layer 210a_2 over the insulating layer 210a_1. For each of the insulating layer 210a_1 and the insulating layer 210a_2, the material that can be used for the insulating layer 210a can be used. For the insulating layer 210a_1 and the insulating layer 210a_2, the same material or different materials may be used. The thicknesses of the insulating layer 210a_1 and the insulating layer 210a_2 may be different from each other.

When the thickness of the insulating layer 210a is increased, stress of the insulating layer 210a is increased, so that warpage of the substrate is generated in some cases. Occurrence of problems due to the stress in the process can be inhibited in some cases by forming the insulating layer 210a in a plurality of steps.

Although FIG. 9A and FIG. 9B illustrate the structure in which the insulating layer 210a has a stacked-layer structure of two layers, one embodiment of the present invention is not limited thereto. The insulating layer 210a may have a stacked-layer structure of three or more layers.

Note that in a transmission electron microscope (TEM) image or the like of a cross section, a boundary between layers (e.g., the insulating layer 210a_1 and the insulating layer 210a_2) included in the insulating layer 210a is unclear in some cases.

Note that the structure of the insulating layer 210 described here can also be applied to other structure examples.

### [Structure Example 4 of Transistor]

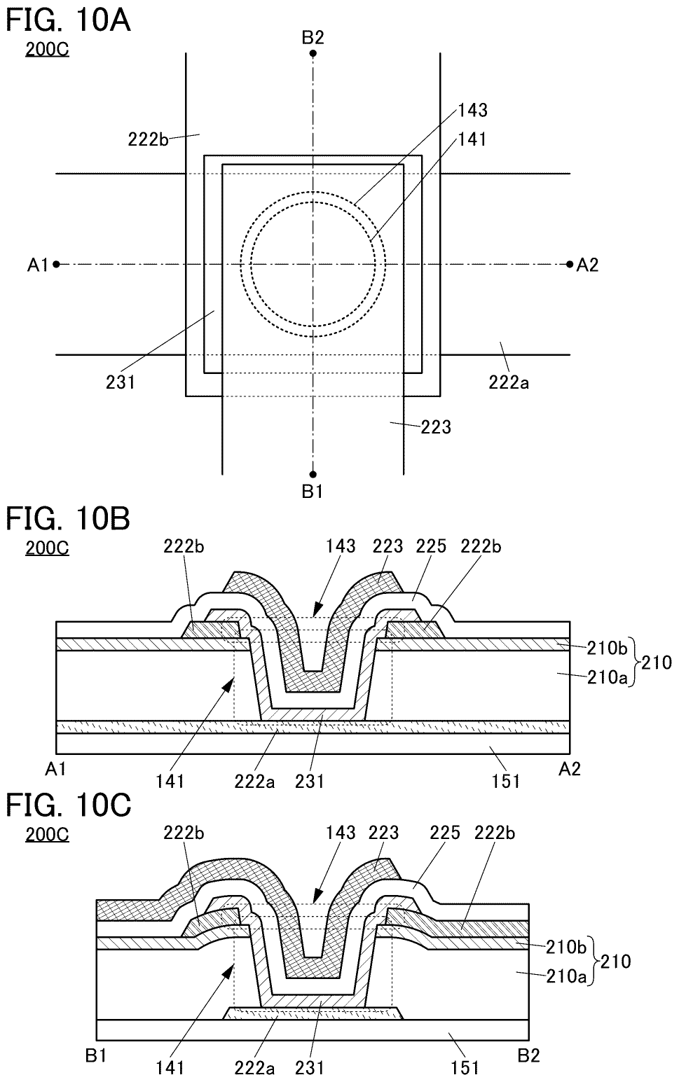

FIG. 10A is a top view of a transistor 200C that can be used in the display apparatus of one embodiment of the present invention. FIG. 10B is a cross-sectional view of a cut plane along the dashed-dotted line A1-A2 in FIG. 10A, and FIG. 10C is a cross-sectional view of a cut plane along the dashed-dotted line B1-B2 in FIG. 10A. FIG. 4 can be referred to for a perspective view of the transistor 200C.

The transistor 200C is different from the above-described transistor 200 mainly in that the end portion of the conductive layer 222b on the opening 143 side is positioned outward from the end portion of the insulating layer 210 on the opening 141 side.

The end portion of the conductive layer 222b on the opening 143 side is positioned over the insulating layer 210. In the top view, it can be said that the opening 143 covers the opening 141.

The semiconductor layer 231 includes a region in contact with the top surface and the side surface of the conductive layer 222b, the top surface and the side surface of the insulating layer 210, and the top surface of the conductive layer 222a. The semiconductor layer 231 has a shape along the shapes of the top surface and the side surface of the conductive layer 222b, the top surface and the side surface of the insulating layer 210, and the top surface of the conductive layer 222a.

When the end portion of the conductive layer 222b on the opening 143 side is positioned outward from the end portion of the insulating layer 210 on the opening 141 side, a step in the formation surface of a layer (e.g., the semiconductor layer 231) formed over the conductive layer 222a, the conductive layer 222b, and the insulating layer 210 becomes small. Thus, coverage with layers formed over the conductive layer 222a, the conductive layer 222b, and the insulating layer 210 can be improved, so that defects such as step disconnection or voids can be inhibited from occurring in the layers.

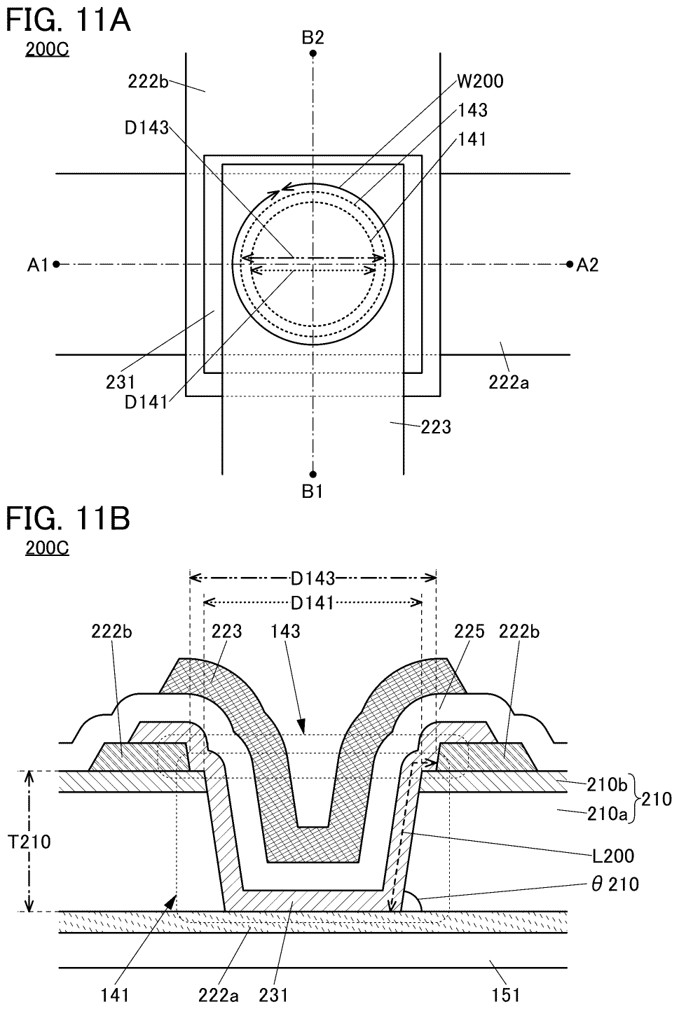

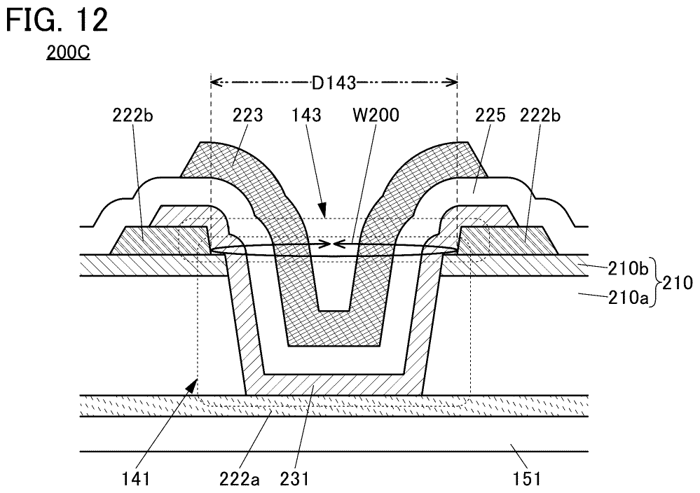

Here, the channel length and the channel width of the transistor 200C are described with reference to FIG. 11A, FIG. 11B, and FIG. 12. FIG. 11A is a top view of the transistor 200C. FIG. 11B and FIG. 12 are enlarged views of FIG. 10B.

In FIG. 11B, the channel length L200 of the transistor 200C is indicated by a dashed double-headed arrow. In FIG. 11A and FIG. 111B, the width D141 of the opening 141 is indicated by a dashed double-headed arrow and the width D143 of the opening 143 is indicated by a dashed double-dotted double-headed arrow. In the top view, the width D141 refers to the short side of the smallest rectangle circumscribing the opening 141.

Here, the channel length L200 of the transistor 200C corresponds to the sum of the distance between the end portion of the conductive layer 222b on the opening 143 side and the end portion of the insulating layer 210 on the opening 141 side and the length of the side surface of the insulating layer 210 on the opening 141 side. That is, the channel length L200 can be adjusted by the width D141 of the opening 141, the width D143 of the opening 143, the thickness T210 and the angle θ210 of the insulating layer 210.

The channel length L200 is preferably within the above range. The width D143 is preferably within the above range. The width D141 is preferably smaller than the width D143. Furthermore, for example, the width D141 is preferably larger than or equal to 0.2 μm and smaller than 5 μm, further preferably larger than or equal to 0.2 μm and smaller than 4.5 μm, still further preferably larger than or equal to 0.2 μm and smaller than 4 μm, yet still further preferably larger than or equal to 0.2 μm and smaller than 3.5 μm, yet still further preferably larger than or equal to 0.2 μm and smaller than 3 μm, yet still further preferably larger than or equal to 0.2 μm and smaller than 2.5 μm, yet still further preferably larger than or equal to 0.2 μm and smaller than 2 μm, yet still further preferably larger than or equal to 0.2 μm and smaller than 1.5 μm, yet still further preferably larger than or equal to 0.3 μm and smaller than or equal to 1.5 μm, yet still further preferably larger than or equal to 0.3 μm and smaller than or equal to 1.2 μm, yet still further preferably larger than or equal to 0.4 μm and smaller than or equal to 1.2 μm, yet still further preferably larger than or equal to 0.4 μm and smaller than or equal to 1 μm, yet still further preferably larger than or equal to 0.5 μm and smaller than or equal to 1 μm.

In FIG. 11A and FIG. 12, the channel width W200 of the transistor 200C is indicated by a solid double-headed arrow. The channel width W200 is the length of the end portion of the conductive layer 222b on the opening 143 side in the top view. For example, in the case where the top surface shape of the opening 143 is a circle, the width D143 corresponds to the diameter of the opening 143, and the channel width W200 can be calculated to be “D143×π”.

Note that in the case where a metal oxide is used for the semiconductor layer 231 and the insulating layer 210b contains hydrogen, a region in contact with the insulating layer 210b functions as one of a source region and a drain region, and a region in contact with the insulating layer 210a functions as a channel formation region in the semiconductor layer 231 in some cases. That is, in the semiconductor layer 231, a region of in contact with the conductive layer 222b and a region in contact with the insulating layer 210b function as one of a source region and a drain region in some cases.

The description of FIG. 7A and FIG. 7B can be referred to for the channel length and the channel width in the case where the region of the semiconductor layer 231 in contact with the insulating layer 210b functions as the source region or the drain region; thus, the detailed description thereof is omitted.

Note that the structures of the opening 141 and the opening 143 described here can also be applied to other structure examples.

### [Structure Example of Transistor 5]

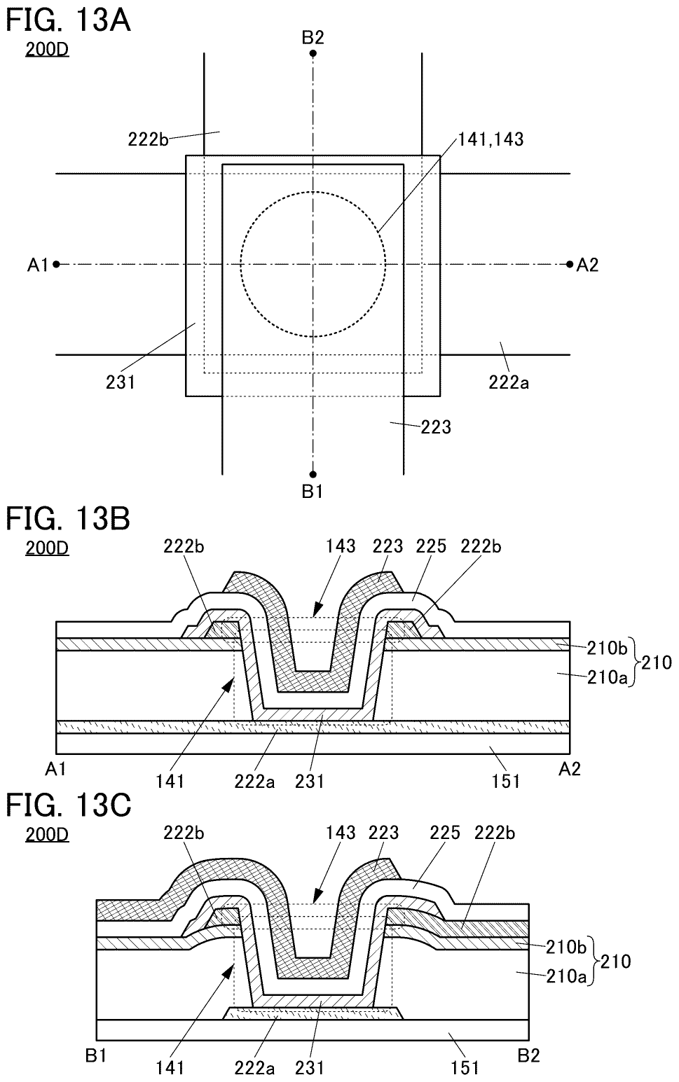

FIG. 13A is a top view of a transistor 200D that can be used in the display apparatus of one embodiment of the present invention. FIG. 13B is a cross-sectional view of a cut plane along the dashed-dotted line A1-A2 in FIG. 13A, and FIG. 13C is a cross-sectional view of a cut plane along the dashed-dotted line B1-B2 in FIG. 13A. FIG. 4 can be referred to for a perspective view of the transistor 200D.

The transistor 200D is different from the above-described transistor 200 mainly in that the semiconductor layer 231 includes a region in contact with the side surface of the conductive layer 222b on the side not facing the opening 143.

Part of the end portion of the semiconductor layer 231 is positioned over the insulating layer 210. It can be said that part of the end portion of the semiconductor layer 231 is in contact with the top surface of the insulating layer 210.

Note that the structure of the semiconductor layer 231 described here can also be applied to other structure examples.

The above is the description of the transistors that can be used in the display apparatus of one embodiment of the present invention.

As illustrated in FIG. 2, the insulating layer 218 provided over the transistor 205R, the transistor 205G, and the transistor 205B functions as a protective layer for the transistor 205R, the transistor 205G, and the transistor 205B. It is preferable to use a material that does not easily allow diffusion of impurities for the insulating layer 218. The insulating layer 218 functions as a blocking film that inhibits the diffusion of impurities from the outside into the transistors. Examples of the impurities include water and hydrogen. When the insulating layer 218 is provided, the reliability of the display apparatus can be increased.

The insulating layer 218 can be an insulating layer containing an inorganic material or an insulating layer containing an organic material. For example, an inorganic material such as an oxide, an oxynitride, a nitride oxide, or a nitride can be suitably used for the insulating layer 218. More specifically, one or more of silicon nitride, silicon nitride oxide, silicon oxynitride, aluminum oxide, aluminum oxynitride, aluminum nitride, hafnium oxide, and hafnium aluminate can be used. For example, a silicon nitride oxide can be suitably used for the insulating layer 218 because the amount of impurities (such as water and hydrogen) released from a silicon nitride oxide itself is small and a silicon nitride oxide film can function as a blocking film that inhibits the diffusion of impurities into the transistors from above the transistors. As the organic material, for example, one or both of an acrylic resin and a polyimide resin can be used. As the organic material, a photosensitive material may be used. A stack including two or more of the above insulating films may also be used. The insulating layer 218 may have a stacked-layer structure of an insulating layer containing an inorganic material and an insulating layer containing an organic material.

The insulating layer 235 has a function of reducing unevenness due to the transistor 205R, the transistor 205G, and the transistor 205B and planarizing the top surface of the layer 101. Note that in this specification and the like, the insulating layer 235 is referred to as a planarization layer in some cases.

An insulating layer containing an organic material can be suitably used as the insulating layer 235. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

For the insulating layer 235, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the insulating layer 235, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

The insulating layer 235 may have a stacked-layer structure of an organic insulating layer and an inorganic insulating layer. For example, the insulating layer 235 can have a stacked-layer structure of an organic insulating layer and an inorganic insulating layer over the organic insulating layer. An inorganic insulating layer provided on the outermost surface of the insulating layer 235 can function as an etching protective layer. This can inhibit a decrease in the flatness of the insulating layer 235, which is caused by etching of part of the insulating layer 235 in the formation of the pixel electrode 111 and the layer 113.

The low flatness of the top surface of the insulating layer 235, which is the formation surface of the light-emitting device 130, might cause a defect such as a connection defect due to step disconnection of the common electrode 115 or an increase in electric resistance due to the locally thinned regions of the common electrode 115. In addition, the low flatness of the top surface of the insulating layer 235 might lower the processing accuracy of the layer to be formed over the insulating layer 235. Making the top surface of the insulating layer 235 flat increases the processing accuracy of the light-emitting device 130 and the like to be provided over the insulating layer 235, whereby the display apparatus can have high definition. Furthermore, since a connection defect due to step disconnection of the common electrode 115 and an increase in electric resistance due to the locally thinned regions of the common electrode 115 can be prevented, the display apparatus can have high display quality.

In some cases, the insulating layer 235 is partly removed when the pixel electrode 111R, the pixel electrode 111G, and the pixel electrode 111B are formed. FIG. 2 illustrates an example of the insulating layer 235 having a concave portion in a region overlapping with none of the pixel electrode 111R, the pixel electrode 111G, and the pixel electrode 111B.

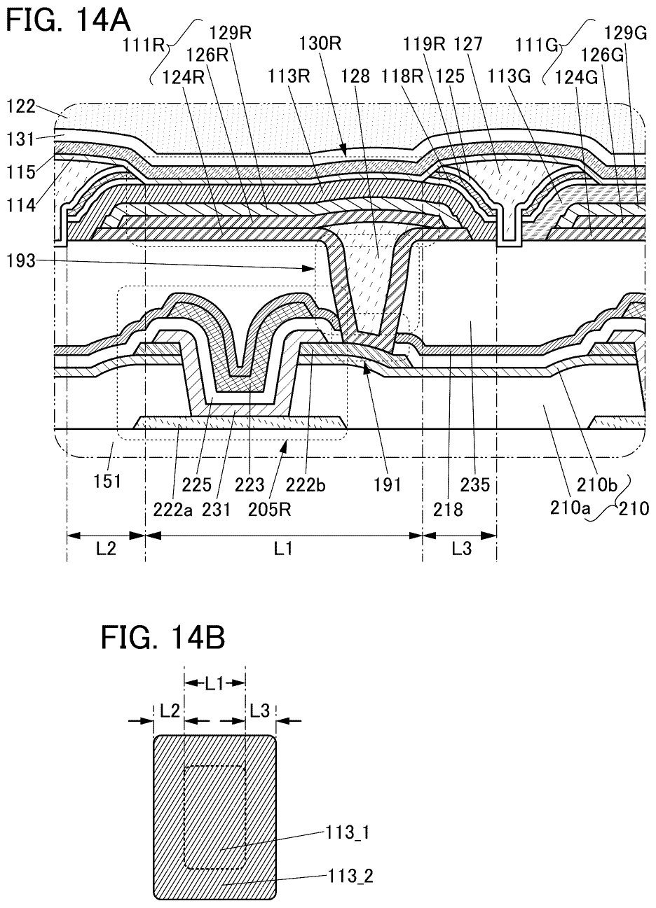

FIG. 14A illustrates an enlarged view of the light-emitting device 130R, the transistor 205R, and the vicinity thereof illustrated in FIG. 2. The insulating layer 225 and the insulating layer 218 include an opening 191 in a region overlapping with the conductive layer 222b included in the transistor 205R. The conductive layer 222b is exposed in the opening 191. The insulating layer 235 includes the opening 193 in a region overlapping with the opening 191. The pixel electrode 111R included in the light-emitting device 130R is provided to cover the opening 191 and the opening 193. The pixel electrode 111R includes a region in contact with the top surface and the side surface of the insulating layer 235, the side surface of the insulating layer 218, the side surface of the insulating layer 225, and the top surface of the conductive layer 222b. That is, the light-emitting device 130R is electrically connected to the transistor 205R through the opening 191 and the opening 193. Similarly, the light-emitting device 130G is electrically connected to the transistor 205G through openings provided in the insulating layer 225, the insulating layer 218, and the insulating layer 235. The light-emitting device 130B is electrically connected to the transistor 205B through openings provided in the insulating layer 225, the insulating layer 218, and the insulating layer 235.

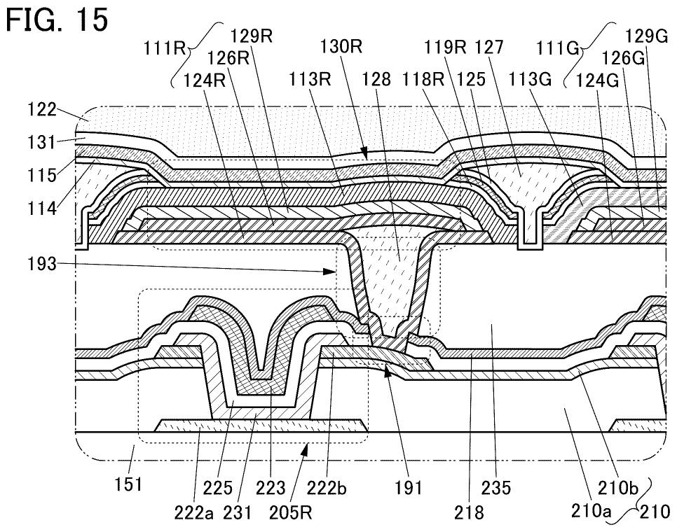

Although FIG. 14A illustrates an example in which the position of an end portion of the insulating layer 225 on the opening 191 side and the position of the end portion of the insulating layer 218 are the same or substantially the same and the position of the end portion of the insulating layer 235 on the opening 193 side and the position of the end portion of the insulating layer 218 on the opening 191 side are the same or substantially the same, one embodiment of the present invention is not limited thereto. The position of the end portion of the insulating layer 225 on the opening 191 side is not necessarily the same as the position of the end portion of the insulating layer 218. The position of the end portion of the insulating layer 235 on the opening 193 side is not necessarily the same as the position of the end portion of the insulating layer 218 on the opening 191 side. For example, as illustrated in FIG. 15, the end portion of the insulating layer 235 on the opening 193 side is preferably positioned inward from the end portion of the insulating layer 218 on the opening 191 side. That is, the end portion of the insulating layer 235 on the opening 193 side is preferably in contact with the top surface of the insulating layer 218. It can be said that the opening 193 includes the opening 191. Such a structure can improve the coverage with the pixel electrode 111. Furthermore, the end portion of the insulating layer 225 on the opening 191 side may be positioned outward from the end portion of the insulating layer 218.

Note that although the pixel electrode 111R, the pixel electrode 111G, and the pixel electrode 111B are electrically connected to the conductive layer 222b here, one embodiment of the present invention is not limited thereto. The pixel electrode 111R, the pixel electrode 111G, and the pixel electrode 111B may be electrically connected to the conductive layer 222a. In that case, the pixel electrode 111R, the pixel electrode 111G, and the pixel electrode 111B can be electrically connected to the conductive layer 222a through openings provided in the insulating layer 210, the insulating layer 225, the insulating layer 218, and the insulating layer 235.

The pixel electrode 111R has a stacked-layer structure including a conductive layer 124R, a conductive layer 126R over the conductive layer 124R, and a conductive layer 129R over the conductive layer 126R. Similarly, the pixel electrode 111G included in the light-emitting device 130G has a stacked-layer structure including a conductive layer 124G, a conductive layer 126G over the conductive layer 124G, and a conductive layer 129G over the conductive layer 126G. The pixel electrode 111B included in the light-emitting device 130B has a stacked-layer structure including a conductive layer 124B, a conductive layer 126B over the conductive layer 124B, and a conductive layer 129B over the conductive layer 126B.

The conductive layer 124R is electrically connected to the conductive layer 222b included in the transistor 205R through the opening 191 and the opening 193. An end portion of the conductive layer 124R is positioned outward from an end portion of the conductive layer 126R. The end portion of the conductive layer 126R is positioned inward from an end portion of the conductive layer 129R. The end portion of the conductive layer 124R is positioned outward from the end portion of the conductive layer 129R. In other words, the end portion of the conductive layer 126R is positioned over the conductive layer 124R. The end portion of the conductive layer 129R is positioned over the conductive layer 124R. The top surface and the side surface of the conductive layer 126R are covered with the conductive layer 129R.

For the conductive layer 124R, no particular limitations are imposed on the properties of transmitting and reflecting visible light. As the conductive layer 124R, a conductive layer having a property of transmitting visible light or a conductive layer having a property of reflecting visible light can be used. As the conductive layer having a property of transmitting visible light, an oxide conductive layer can be used, for example. Specifically, an In—Si—Sn oxide (also referred to as ITSO) can be suitably used for the conductive layer 124R. Examples of the conductive layer having a property of reflecting visible light include metal such as aluminum, titanium, chromium, nickel, copper, yttrium, zirconium, silver, tin, zinc, platinum, gold, molybdenum, tantalum, and tungsten, and an alloy containing the metal as its main component (e.g., an alloy of silver, palladium, and copper (APC: Ag—Pd—Cu)). The conductive layer 124R may have a stacked-layer structure of a conductive layer having a property of transmitting visible light and a conductive layer having a property of reflecting visible light over the conductive layer. For the conductive layer 124R, a material with high adhesion to the formation surface of the conductive layer 124R (here, the insulating layer 235) is preferably used. Accordingly, film separation of the conductive layer 124R can be inhibited.

As the conductive layer 126R, a conductive layer having a property of transmitting visible light can be used. The conductive layer 126R may have a stacked-layer structure of a conductive layer having a property of transmitting visible light and a conductive layer having a property of reflecting visible light over the conductive layer. The conductive layer 126R can be formed using a material that can be used for the conductive layer 124R. Specifically, a stacked-layer structure of In—Si—Sn oxide (ITSO) and an alloy of silver, palladium, and copper (APC) over the In—Si—Sn oxide (ITSO) can be suitably used as the conductive layer 126R.

For the conductive layer 129R, a material that can be used for the conductive layer 124R can be used. As the conductive layer 129R, a conductive layer having a property of transmitting visible light can be used. Specifically, In—Si—Sn oxide (ITSO) can be used for the conductive layer 129R.

In the case where a material that is likely to be oxidized is used for the conductive layer 126R, a material that is less likely to be oxidized is used for the conductive layer 129R and the conductive layer 126R is covered with the conductive layer 129R, whereby oxidation of the conductive layer 126R can be inhibited. In addition, precipitation of a metal component included in the conductive layer 126R can be inhibited. For example, in the case where a material containing silver is used for the conductive layer 126R, In—Si—Sn oxide (ITSO) can be suitably used for the conductive layer 129R. Thus, oxidation of the conductive layer 126R can be inhibited, and precipitation of silver can be inhibited.

Detailed description of the conductive layer 124G, the conductive layer 126G, and the conductive layer 129G of the pixel electrode 111G and the conductive layer 124B, the conductive layer 126B, and the conductive layer 129B of the pixel electrode 111B is omitted because these conductive layers are similar to the conductive layer 124R, the conductive layer 126R, and the conductive layer 129R of the pixel electrode 111R.

The structure of the pixel electrode 111 that can be applied to the display apparatus of one embodiment of the present invention is not limited to the structure of the pixel electrode 111 illustrated in FIG. 2 and the like.

Concave portions are formed in the conductive layer 124R, the conductive layer 124G, and the conductive layer 124B so as to cover the opening 193 provided in the insulating layer 235. A layer 128 is embedded in each of the concave portions.

The layer 128 has a planarization function for the concave portions of the conductive layer 124R, the conductive layer 124G, and the conductive layer 124B. The conductive layer 126R, the conductive layer 126G, and the conductive layer 126B electrically connected to the conductive layer 124R, the conductive layer 124G, and the conductive layer 124B, respectively, are provided over the conductive layer 124R, the conductive layer 124G, the conductive layer 124B, and the layer 128. Thus, regions overlapping with the concave portions of the conductive layer 124R, the conductive layer 124G, and the conductive layer 124B can also function as the light-emitting regions, increasing the aperture ratio of the pixels.

The layer 128 has a planarization function for the concave portions formed in the conductive layer 124R, the conductive layer 124G, and the conductive layer 124B. Provision of the layer 128 can improve the planarity of the top surfaces of the pixel electrode 111R, the pixel electrode 111G, and the pixel electrode 111B that are formation surfaces of the layer 113R, the layer 113G, and the layer 113B.

The layer 128 may be an insulating layer or a conductive layer. Any of a variety of inorganic insulating materials, organic insulating materials, and conductive materials can be used for the layer 128 as appropriate.

As the layer 128, an insulating layer containing an organic material can be suitably used. The insulating layer 128 can be formed using a material that can be used for the insulating layer 235. As the organic material, a photosensitive organic resin is preferably used, and for example, a photosensitive resin composite containing an acrylic resin is preferably used.

Note that when the layer 128 is a conductive layer, the layer 128 can function as part of a pixel electrode. For the layer 128, for example, an organic resin in which metal particles are dispersed can be used.

The side surface of the conductive layer 124R and the top surface and the side surface of the conductive layer 129R are covered with the layer 113R. Similarly, the side surface of the conductive layer 124G and the top surface and the side surface of the conductive layer 129G are covered with the layer 113G, and the side surface of the conductive layer 124B and the top surface and the side surface of the conductive layer 129B are covered with the layer 113B. Accordingly, regions provided with the conductive layer 126R, the conductive layer 126G, and the conductive layer 126B can be entirely used as the light-emitting regions of the light-emitting device 130R, the light-emitting device 130G, and the light-emitting device 130B, increasing the aperture ratio of the pixels.

Each of end portions of the pixel electrode 111R, the pixel electrode 111G, and the pixel electrode 111B preferably has a tapered shape. Specifically, each of the end portions of the pixel electrode 111R, the pixel electrode 111G, and the pixel electrode 111B preferably has a tapered shape with a taper angle less than 90°. When the pixel electrode 111R, the pixel electrode 111G, and the pixel electrode 111B have tapered side surfaces, the coverage with the EL layer provided along the top surfaces and the side surfaces of the pixel electrode 111R, the pixel electrode 111G, and the pixel electrode 111B can be improved.

In some cases, part of the insulating layer 235 is removed when the pixel electrode 111R, the pixel electrode 111G, and the pixel electrode 111B are formed. The insulating layer 235 may have a concave portion in a region overlapping with none of the pixel electrode 111R, the pixel electrode 111G, and the pixel electrode 111B.

In some cases, part of the insulating layer 235 is removed at the time of forming the layer 113R, the layer 113G, and the layer 113B. FIG. 2 and FIG. 14A illustrate an example in which the insulating layer 235 has a concave portion in a region overlapping with none of the layer 113R, the layer 113G, and the layer 113B.

An insulating layer (also referred to as an embankment, a bank, or a spacer) covering an end portion of the top surface of the pixel electrode 111R is not provided between the pixel electrode 111R and the layer 113R. Similarly, an insulating layer covering an end portion of the top surface of the pixel electrode 111G is not provided between the pixel electrode 111G and the layer 113G. An insulating layer covering an end portion of the top surface of the pixel electrode 111B is not provided between the pixel electrode 111B and the layer 113B. Thus, the distance between adjacent light-emitting devices can be short. Accordingly, the display apparatus can have high definition or high resolution. In addition, a mask for forming the insulating layer is not needed, which leads to a reduction in manufacturing cost of the display apparatus.

Light emitted from the EL layer can be extracted efficiently with a structure in which an insulating layer covering the end portion of the pixel electrode is not provided between the pixel electrode and the EL layer, i.e., a structure in which an insulating layer is not provided between the pixel electrode and the EL layer. Thus, the display apparatus of one embodiment of the present invention can significantly reduce the viewing angle dependence. A reduction in the viewing angle dependence leads to an increase in visibility of an image on the display apparatus.

The light-emitting device of this embodiment may have either a single structure (a structure including only one light-emitting unit) or a tandem structure (a structure including a plurality of light-emitting units). The light-emitting unit includes at least one light-emitting layer.

The light-emitting device 130R emits red (R) light, the light-emitting device 130G emits green (G) light, and the light-emitting device 130B emits blue (B) light. The layer 113R, the layer 113G, and the layer 113B each include at least a light-emitting layer. The EL layer 113R includes a light-emitting layer emitting red light, the layer 113G includes a light-emitting layer emitting green light, and the layer 113B includes a light-emitting layer emitting blue light. In other words, the layer 113R contains a light-emitting material emitting red light, the layer 113G contains a light-emitting material emitting green light, and the layer 113B contains a light-emitting material emitting blue light.

In the case of using a light-emitting device having a tandem structure, the layer 113R is preferably configured to include a plurality of light-emitting units emitting red light, the layer 113G is preferably configured to include a plurality of light-emitting units emitting green light, and the layer 113B is preferably configured to include a plurality of light-emitting units emitting blue light. A charge-generation layer is preferably provided between the light-emitting units.

The layer 113R, the layer 113G, and the layer 113B may each include one or more of a hole-injection layer, a hole-transport layer, a hole-blocking layer, a charge-generation layer, an electron-blocking layer, an electron-transport layer, and an electron-injection layer.

For example, the layer 113R, the layer 113G, and the layer 113B may each include a hole-injection layer, a hole-transport layer, a light-emitting layer, and an electron-transport layer in this order. In addition, an electron-blocking layer may be provided between the hole-transport layer and the light-emitting layer. In addition, a hole-blocking layer may be provided between the electron-transport layer and the light-emitting layer. Furthermore, an electron-injection layer may be provided over the electron-transport layer.

For another example, the layer 113R, the layer 113G, and the layer 113B may each include an electron-injection layer, an electron-transport layer, a light-emitting layer, and a hole-transport layer in this order. In addition, a hole-blocking layer may be provided between the electron-transport layer and the light-emitting layer. In addition, an electron-blocking layer may be provided between the hole-transport layer and the light-emitting layer. Furthermore, a hole-injection layer may be provided over the hole-transport layer.

Thus, the layer 113R, the layer 113G, and the layer 113B each preferably include a light-emitting layer and a carrier-transport layer (an electron-transport layer or a hole-transport layer) over the light-emitting layer. Alternatively, the layer 113R, the layer 113G, and the layer 113B each preferably include a light-emitting layer and a carrier-blocking layer (a hole-blocking layer or an electron-blocking layer) over the light-emitting layer. Alternatively, the layer 113R, the layer 113G, and the layer 113B each preferably include a light-emitting layer, a carrier-blocking layer over the light-emitting layer, and a carrier-transport layer over the carrier-blocking layer. Since the surfaces of the layer 113R, the layer 113G, and the layer 113B are exposed in the manufacturing process of the display apparatus, provision of one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved.

The upper temperature limits of the compounds contained in the layer 113R, the layer 113G, and the layer 113B are each preferably higher than or equal to 100° C. and lower than or equal to 180° C., further preferably higher than or equal to 120° C. and lower than or equal to 180° C., still further preferably higher than or equal to 140° C. and lower than or equal to 180° C. For example, the glass transition points (Tg) of these compounds are each preferably higher than or equal to 100° C. and lower than or equal to 180° C., further preferably higher than or equal to 120° C. and lower than or equal to 180° C., still further preferably higher than or equal to 140° C. and lower than or equal to 180° C.

In particular, the upper temperature limits of the functional layers provided over the light-emitting layer are preferably high. It is further preferable that the upper temperature limit of the functional layer provided over and in contact with the light-emitting layer be high. When the functional layer has high heat resistance, the light-emitting layer can be effectively protected and damage to the light-emitting layer can be reduced.

The upper temperature limit of the light-emitting layer is preferably high. In this case, the light-emitting layer can be inhibited from being damaged by heating and being decreased in emission efficiency and lifetime.

The light-emitting layer contains a light-emitting substance (also referred to as a light-emitting material, a light-emitting organic compound, or a guest material) and a host material. Since the light-emitting layer is configured to contain more host material than light-emitting substance, Tg of the host material can be used as an indicator of the upper temperature limit of the light-emitting layer.

The layer 113R, the layer 113G, and the layer 113B may each include a first light-emitting unit, a charge-generation layer over the first light-emitting unit, and a second light-emitting unit over the charge-generation layer, for example.

The second light-emitting unit preferably includes a light-emitting layer and a carrier-transport layer (an electron-transport layer or a hole-transport layer) over the light-emitting layer. Alternatively, the second light-emitting unit preferably includes a light-emitting layer and a carrier-blocking layer (a hole-blocking layer or an electron-blocking layer) over the light-emitting layer. Alternatively, the second light-emitting unit preferably includes a light-emitting layer, a carrier-blocking layer over the light-emitting layer, and a carrier-transport layer over the carrier-blocking layer. Since the surface of the second light-emitting unit is exposed in the manufacturing process of the display apparatus, provision of one or both of the carrier-transport layer and the carrier-blocking layer over the light-emitting layer inhibits the light-emitting layer from being exposed on the outermost surface, so that damage to the light-emitting layer can be reduced. Accordingly, the reliability of the light-emitting device can be improved. Note that in the case where three or more light-emitting units are provided, the uppermost light-emitting unit preferably includes a light-emitting layer and one or both of a carrier-transport layer and a carrier-blocking layer over the light-emitting layer.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting device 130R, the light-emitting device 130G, and the light-emitting device 130B.

In a region between the adjacent light-emitting devices 130, an insulating layer 125 and an insulating layer 127 over the insulating layer 125 are provided. Although FIG. 2 illustrates a plurality of cross sections of the insulating layer 125 and the insulating layer 127, the insulating layer 125 and the insulating layer 127 are each one continuous layer when the display apparatus 100 is seen from above. In other words, the display apparatus 100 can have a structure including one insulating layer 125 and one insulating layer 127, for example. Note that the display apparatus 100 may include a plurality of insulating layers 125 that are separated from each other, and may include a plurality of insulating layers 127 that are separated from each other.

FIG. 2 and the like illustrate an example in which an end portion of the layer 113R is positioned outward from the end portion of the pixel electrode 111R. The layer 113R is formed to cover the end portion of the pixel electrode 111R. Such a structure enables the entire top surface of the pixel electrode to be a light-emitting region, and the aperture ratio can be higher than that in the structure in which the end portion of the island-shaped EL layer is positioned inward from the end portion of the pixel electrode. Note that although description is made using the pixel electrode 111R and the layer 113R as an example, the same applies to the pixel electrode 111G and the layer 113G, and the pixel electrode 111B and the layer 113B.

Covering the side surface of the pixel electrode 111 with the EL layer inhibits contact between the pixel electrode 111 and the common electrode 115, thereby inhibiting a short circuit of the light-emitting device 130. Furthermore, the distance between the light-emitting region (i.e., the region overlapping with the pixel electrode 111) in the EL layer and the end portion of the EL layer can be increased. Since the end portion of the EL layer might be damaged by processing, the use of a region away from the end portion of the EL layer as a light-emitting region can improve the reliability of the light-emitting device 130 in some cases.

The layer 113R, the layer 113G, and the layer 113B each preferably include a first region that is a light-emitting region and a second region on the outer side of the first region. The first region is positioned between the pixel electrode and the common electrode. In the layer 113R, the first region is a portion being in contact with the pixel electrode 111R and overlapping with the common electrode 115 with the common layer 114 therebetween. The first region is covered with the mask layer during the manufacturing process of the display apparatus and thus subjected to reduced damage. Accordingly, a light-emitting device with high emission efficiency and a long lifetime can be achieved. Meanwhile, the second region includes an end portion of the EL layer and the vicinity thereof, which might be damaged due to exposure to plasma in the manufacturing process of the display apparatus. By not using the second region as a light-emitting region, variation in characteristics of the light-emitting devices can be reduced. The second region can be referred to as a dummy region.

FIG. 14B illustrates a top view of the layer 113R. In FIG. 14A and FIG. 14B, a width 35 L1 of the first region 113_1 which is a light-emitting region in the layer 113R is indicated by a double-headed arrow. A width L2 and a width L3 of the second region 113_2 which is a dummy region in the layer 113R are indicated by arrows. As illustrated in FIG. 14B, the second region 113_2 is provided to surround the first region 113_1; thus, in the cross-sectional view of the display apparatus, the second region 113_2 can be observed in two portions between which the first region 113_1 is interposed. For example, the width L1 to the width L3 can be observed in a cross-sectional transmission electron microscope (TEM) image.

The second region 113_2 is a portion where the layer 113R overlaps with at least one of a mask layer 118R, a mask layer 119R, the insulating layer 125, and the insulating layer 127.

Each of the width L2 and the width L3 of the second region 1132 is preferably larger than or equal to 1 nm, further preferably larger than or equal to 5 nm, still further preferably larger than or equal to 50 nm, yet still further preferably larger than or equal to 100 nm. The width of the second region 113_2 that is a dummy region is preferably wider, in which case the quality of the light-emitting region can be more uniform and the light-emitting devices can have less variation in characteristics.

By contrast, a narrower width of the second region 113_2 can widen the light-emitting region and increase the aperture ratio of the pixel. Thus, each of the width L2 and the width L3 of the second region 1132 is preferably less than or equal to 50%, further preferably less than or equal to 40%, still further preferably less than or equal to 30%, yet still further preferably less than or equal to 20%, yet still further preferably less than or equal to 10% of the width L1 of the first region 113_1. For example, each of the width L2 and the width L3 of the second region 113_2 in a small and high-definition display apparatus, such as a display apparatus for a wearable device, is preferably less than or equal to 500 nm, further preferably less than or equal to 300 nm, still further preferably less than or equal to 200 nm, yet still further preferably less than or equal to 150 nm.

Note that in the island-shaped EL layer, the first region (light-emitting region) is a region from which EL (Electroluminescence) emission is obtained. Furthermore, in the island-shaped EL layer, the first region (light-emitting region) and the second region (dummy region) are each a region from which PL (Photoluminescence) emission is obtained. Thus, the first region and the second region can be distinguished from each other by observing EL emission and PL emission.

As illustrated in FIG. 2, the mask layer 118R and the mask layer 119R are positioned over the layer 113R included in the light-emitting device 130R, the mask layer 118G and the mask layer 119G are positioned over the layer 113G included in the light-emitting device 130G, and the mask layer 118B and the mask layer 119B are positioned over the layer 113B included in the light-emitting device 130B. The mask layer 118 and the mask layer 119 are provided to surround the first region 1131 (light-emitting region). In other words, the mask layers include an opening in a portion overlapping with the light-emitting region. The top surface shape of the mask layer is the same or substantially the same as, or similar to that of the second region 113_2 illustrated in FIG. 14B. The mask layer 118R and the mask layer 119R are remaining parts of the mask layers provided over the layer 113R at the time of forming the layer 113R. In a similar manner, the mask layer 118G and the mask layer 119G are remaining parts of the mask layers provided at the time of forming the layer 113G, and the mask layer 118B and the mask layer 119B are remaining parts of the mask layers provided at the time of forming the layer 113B. Thus, the mask layer used to protect the EL layer in manufacture of the display apparatus may partly remain in the display apparatus of one embodiment of the present invention.

For any two or all of the mask layer 118R, the mask layer 118G, and the mask layer 118B, the same material may be used or different materials may be used. Similarly, for any two or all of the mask layer 119R, the mask layer 119G, and the mask layer 119B, the same material may be used or different materials may be used. Note that the mask layer 118R, the mask layer 118G, and the mask layer 118B are sometimes collectively referred to as a mask layer 118. The mask layer 119R, the mask layer 119G, and the mask layer 119B may be collectively referred to as a mask layer 119.

As illustrated in FIG. 2, one end portion of the mask layer 118R and one end portion of the mask layer 119R (outer end portions which are opposite to the light-emitting region side) are aligned or substantially aligned with the end portion of the layer 113R, and the other end portion of the mask layer 118R and the other end portion of the mask layer 119R (inner end portions which are on the light-emitting region side) are positioned over the layer 113R. Here, the other end portion of the mask layer 118R and the other end portion of the mask layer 119R preferably overlap with the layer 113R and the pixel electrode 11 IR. In this case, the other end portion of the mask layer 118R and the other end portion of the mask layer 119R are easily formed over a substantially flat surface of the layer 113R. Note that the same applies to the mask layer 118G, the mask layer 119G, the mask layer 118B, and the mask layer 119B. The mask layer 118 and the mask layer 119 remain between the top surface of the EL layer processed into an island shape (the layer 113R, the layer 113G, or the layer 113B) and the insulating layer 125.

The side surfaces of the layer 113R, the layer 113G, and the layer 113B are each covered with the insulating layer 125. The insulating layer 127 overlaps with the side surfaces of the layer 113R, the layer 113G, and the layer 113B with the insulating layer 125 therebetween.

The top surfaces of the layer 113R, the layer 113G, and the layer 113B are each partly covered with the mask layer 118. The mask layer 119 is provided over the mask layer 118. The insulating layer 125 and the insulating layer 127 overlap with parts of the top surfaces of the layer 113R, the layer 113G, and the layer 113B with the mask layer 118 and the mask layer 119 therebetween.

The side surface and part of the top surface of each of the layer 113R, the layer 113G, and the layer 113B are covered with at least one of the insulating layer 125, the insulating layer 127, the mask layer 118, and the mask layer 119, so that the common layer 114 (or the common electrode 115) can be inhibited from being in contact with the side surfaces of the pixel electrode 111R, the pixel electrode 111G, the pixel electrode 111B, the layer 113R, the layer 113G, and the layer 113B, leading to inhibition of a short circuit of the light-emitting device. Accordingly, the reliability of the light-emitting device can be improved.

Although FIG. 2 illustrates the layer 113R, the layer 113G, and the layer 113B that have the same thickness, the present invention is not limited thereto. The layer 113R, the layer 113G, and the layer 113B may have different thicknesses. For example, the thickness is preferably set to match an optical path length that intensifies light emitted from the layer 113R, the layer 113G, and the layer 113B. A microcavity structure can be achieved in this manner, and the color purity of light emitted from each light-emitting device 130 can be increased.

The insulating layer 125 is preferably in contact with the side surfaces of the layer 113R, the layer 113G, and the layer 113B. The insulating layer 125 is configured to be in contact with the layer 113R, the layer 113G, and the layer 113B, whereby film separation of the layer 113R, the layer 113G, and the layer 113B can be prevented. When the insulating layer 125 is in close contact with the layer 113B, the layer 113G, or the layer 113R, the layer 113B and the like that are adjacent each other can be fixed or bonded to each other by the insulating layer 125. Accordingly, the reliability of the light-emitting device can be improved. The manufacturing yield of the light-emitting device can also be improved.

As illustrated in FIG. 2, the insulating layer 125 and the insulating layer 127 cover the side surface and part of the top surface of each of the layer 113R, the layer 113G, and the layer 113B, whereby film separation of the EL layers can further be prevented and the reliability of the light-emitting device can be improved. The manufacturing yield of the light-emitting device can also be improved.

In the example illustrated in FIG. 2, a stacked-layer structure of the layer 113R, the mask layer 118R, the mask layer 119R, the insulating layer 125, and the insulating layer 127 is provided over the end portion of the pixel electrode 111R. Similarly, a stacked-layer structure of the layer 113G, the mask layer 118G, the mask layer 119G, the insulating layer 125, and the insulating layer 127 is provided over the end portion of the pixel electrode 111G; and a stacked-layer structure of the layer 113B, the mask layer 118B, the mask layer 119B, the insulating layer 125, and the insulating layer 127 is provided over the end portion of the pixel electrode 111B.

In FIG. 2, the end portion of the pixel electrode 111R is covered with the layer 113R and the insulating layer 125 is in contact with the side surface of the layer 113R. Similarly, the end portion of the pixel electrode 111G is covered with the layer 113G, the end portion of the pixel electrode 111B is covered with the layer 113B, and the insulating layer 125 is in contact with the side surface of the layer 113G and the side surface of the layer 113B.

The insulating layer 127 is provided over the insulating layer 125 to fill a concave portion formed in the insulating layer 125. The insulating layer 127 can be configured to overlap with the side surface and part of the top surface of each of the layer 113R, the layer 113G, and the layer 113B with the insulating layer 125 therebetween. The insulating layer 127 preferably covers at least part of the side surface of the insulating layer 125.

The insulating layer 125 and the insulating layer 127 can fill a space between adjacent island-shaped layers, whereby the formation surface of the layers (e.g., the carrier-injection layer and the common electrode) provided over the island-shaped layers can have higher flatness with small unevenness. Consequently, coverage with the carrier-injection layer, the common electrode, and the like can be improved.

The common layer 114 and the common electrode 115 are provided over the layer 113R, the layer 113G, the layer 113B, the mask layer 118, the mask layer 119, the insulating layer 125, and the insulating layer 127. Before the insulating layer 125 and the insulating layer 127 are provided, a step is generated due to a difference between a region where the pixel electrode and the island-shaped EL layer are provided and a region where neither the pixel electrode nor the island-shaped EL layer is provided (region between the light-emitting devices). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection of the common layer 114 and the common electrode 115 can be inhibited. In addition, an increase in electric resistance, which is caused by local thinning of the common electrode 115 due to the step, can be inhibited.

The top surface of the insulating layer 127 preferably has a shape with higher flatness, but may include a convex portion, a convex surface, a concave surface, or a concave portion. For example, the top surface of the insulating layer 127 preferably has a smooth convex shape with high flatness.

Next, an example of materials that can be used for the insulating layer 125 and the insulating layer 127 is described.

The insulating layer 125 can be an insulating layer containing an inorganic material. For example, one or more of an oxide, a nitride, an oxynitride, and a nitride oxide can be used for the insulating layer 125. The insulating layer 125 may have either a single-layer structure or a stacked-layer structure. Examples of the oxide include a silicon oxide, an aluminum oxide, a magnesium oxide, an indium gallium zinc oxide, a gallium oxide, a germanium oxide, an yttrium oxide, a zirconium oxide, a lanthanum oxide, a neodymium oxide, a hafnium oxide, and a tantalum oxide. Examples of the nitride include a silicon nitride and an aluminum nitride. Examples of the oxynitride include a silicon oxynitride and an aluminum oxynitride. Examples of the nitride oxide include a silicon nitride oxide and an aluminum nitride oxide. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an atomic layer deposition (ALD) method is used as the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide formed by an ALD method and a silicon nitride formed by a sputtering method, for example.

The insulating layer 125 preferably has a function of a barrier insulating layer against at least one of water and oxygen. Alternatively, the insulating layer 125 preferably has a function of inhibiting diffusion of at least one of water and oxygen. Alternatively, the insulating layer 125 preferably has a function of capturing or fixing (also referred to as gettering) at least one of water and oxygen.

Note that in this specification and the like, a barrier insulating layer refers to an insulating layer having a barrier property. A barrier property in this specification and the like means a function of inhibiting diffusion of a particular substance (also referred to as having low permeability). Alternatively, a barrier property refers to a function of capturing or fixing (also referred to as gettering) a particular substance.

When the insulating layer 125 has a function of a barrier insulating layer or a gettering function, entry of impurities (typically, at least one of water and oxygen) that would diffuse into the light-emitting devices from the outside can be inhibited. With this structure, a highly reliable light-emitting device and a highly reliable display apparatus can be provided.

The insulating layer 125 preferably has a low impurity concentration. Accordingly, degradation of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, it is desirable that one or both of the hydrogen concentration and the carbon concentration in the insulating layer 125 be sufficiently low.

Note that for the insulating layer 125 and the mask layer 118B, the mask layer 118G, and the mask layer 118R, the same material can be used. In this case, the boundary between the insulating layer 125 and any of the mask layer 118B, the mask layer 118G, and the mask layer 118R is unclear and thus the layers cannot be distinguished from each other in some cases.

The insulating layer 127 provided over the insulating layer 125 has a function of filling large unevenness of the insulating layer 125, which is formed between the adjacent light-emitting devices. In other words, the insulating layer 127 has an effect of improving the flatness of the formation surface of the common electrode 115.

As the insulating layer 127, an insulating layer containing an organic material can be favorably used. As the organic material, a photosensitive organic resin is preferably used, and for example, a photosensitive resin composite containing an acrylic resin is preferably used. Note that in this specification and the like, an acrylic resin refers to not only a polymethacrylic acid ester or a methacrylic resin, but also all the acrylic-based polymers in a broad sense in some cases.

Alternatively, for the insulating layer 127, it is possible to use an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like. Alternatively, for the insulating layer 127, it is possible to use an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin. A photoresist may be used for the photosensitive resin. As the photosensitive organic resin, either a positive material or a negative material may be used.

For the insulating layer 127, a material absorbing visible light may be used. When the insulating layer 127 absorbs light from the light-emitting device, leakage of light (stray light) from the light-emitting device to the adjacent light-emitting device through the insulating layer 127 can be inhibited. Thus, the display quality of the display apparatus can be improved. Since no polarizing plate is required to improve the display quality, the weight and thickness of the display apparatus can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two colors or three or more colors is particularly preferred, in which case the effect of blocking visible light can be enhanced. In particular, mixing color filter materials of three or more colors enables the formation of a black or nearly black resin layer.

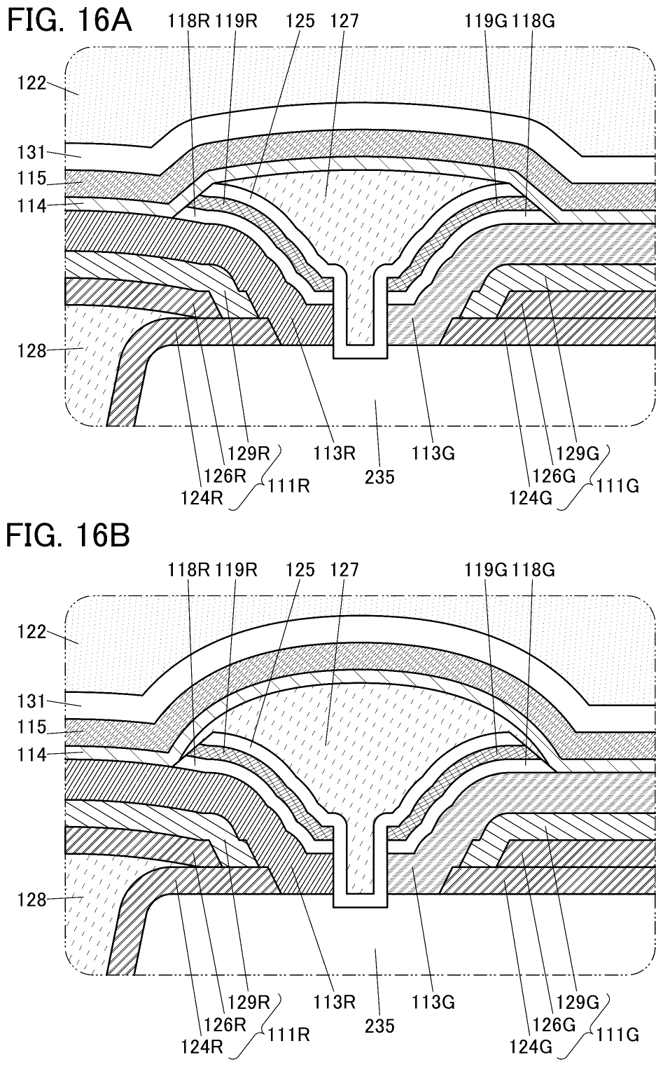

Next, structures of the insulating layer 127 and the vicinity thereof are described. FIG. 16A is an enlarged cross-sectional view of a region including the insulating layer 127 between the light-emitting device 130R and the light-emitting device 130G, and the vicinity of the insulating layer 127. Although the insulating layer 127 between the light-emitting device 130R and the light-emitting device 130G is described below as an example, the same applies to the insulating layer 127 between the light-emitting device 130G and the light-emitting device 130B, the insulating layer 127 between the light-emitting device 130B and the light-emitting device 130R, and the like.

As illustrated in FIG. 16A, the layer 113R is provided to cover the pixel electrode 111R and the layer 113G is provided to cover the pixel electrode 111G. The mask layer 118R is provided in contact with part of the top surface of the layer 113R, and the mask layer 118G is provided in contact with part of the top surface of the layer 113G. The insulating layer 125 is provided in contact with the side surface of the mask layer 118R, the side surface and the side surface of the mask layer 119R, the side surface of the layer 113R, the top surface of the insulating layer 235, the side surface of the mask layer 118G, the top surface and the side surface of the mask layer 119G, and the side surface of the layer 113G. The insulating layer 125 covers part of the top surface of the layer 113R and part of the top surface of the layer 113G. The insulating layer 127 is provided in contact with the top surface of the insulating layer 125. The insulating layer 127 overlaps with the side surface and part of the top surface of the layer 113R and the side surface and part of the top surface of the layer 113G with the insulating layer 125 therebetween, and is in contact with at least part of the side surface of the insulating layer 125. The common layer 114 is provided to cover the layer 113R, the mask layer 118R, the mask layer 119R, the layer 113G, the mask layer 118G, the mask layer 119G, the insulating layer 125, and the insulating layer 127, and the common electrode 115 is provided over the common layer 114.

The insulating layer 127 is formed in a region between two island-shaped EL layers (e.g., a region between the layer 113R and the layer 113G in FIG. 16A). At this time, at least part of the insulating layer 127 is placed at a position interposed between an end portion of the side surface of one of the EL layers (e.g., the layer 113R in FIG. 16A) and an end portion of the side surface of the other of the EL layers (e.g., the layer 113G in FIG. 16A). Provision of the insulating layer 127 in such a manner can prevent formation of a disconnected portion and a locally thinned portion in the common layer 114 and the common electrode 115 that are formed over the island-shaped EL layers and the insulating layer 127.

The end portion of the insulating layer 127 preferably has a tapered shape in the cross-sectional view of the display apparatus. The angle formed by the side surface of the insulating layer 127 and the formation surface of the insulating layer 127 is preferably less than 90°, further preferably less than or equal to 60°, still further preferably less than or equal to 45°, yet still further preferably less than or equal to 20°. When the end portion of the insulating layer 127 has such a tapered shape, the coverage of the common layer 114 and the common electrode 115 that are provided over the insulating layer 127 can be improved, thereby inhibiting disconnection or local thinning of the thickness of the common layer 114 and the common electrode 115. Accordingly, the in-place uniformity of the thicknesses of the common layer 114 and the common electrode 115 can be improved, leading to higher display quality of the display apparatus.

As illustrated in FIG. 16A, in the cross-sectional view of the display apparatus, the top surface of the insulating layer 127 preferably has a convex shape. The convex shape of the top surface of the insulating layer 127 is preferably a shape gently bulged toward the center. It is also preferable that the convex portion in the center portion of the top surface of the insulating layer 127 have a shape gently connected to a tapered portion in the end portion. When the insulating layer 127 has such a shape, the common layer 114 and the common electrode 115 can be formed with good coverage over the entire insulating layer 127.

The end portion of the insulating layer 125 preferably has a tapered shape in the cross-sectional view of the display apparatus. The angle formed by the side surface of the insulating layer 125 and the formation surface of the insulating layer 125 is preferably less than 90°, further preferably less than or equal to 60°, still further preferably less than or equal to 45°, yet still further preferably less than or equal to 20°.

The end portion of the mask layer 118R preferably has a tapered shape in the cross-sectional view of the display apparatus. The angle formed by the side surface of the mask layer 118R and the formation surface of the mask layer 118R is preferably less than 90°, further preferably less than or equal to 60°, still further preferably less than or equal to 45°, yet still further preferably less than or equal to 20°. Similarly, the end portions of the mask layer 118G and the mask layer 118B preferably have tapered shapes, and the angles formed between these side surfaces and the formation surface are preferably within the above range.

The end portion of the mask layer 119R preferably has a tapered shape in the cross-sectional view of the display apparatus. The angle formed by the side surface of the mask layer 119R and the formation surface of the mask layer 119R is preferably less than 90°, further preferably less than or equal to 60°, still further preferably less than or equal to 45°, yet still further preferably less than or equal to 20°. Similarly, the end portions of the mask layer 119G and the mask layer 119B preferably have tapered shapes, and the angles formed between these side surfaces and the formation surface are preferably within the above range.

Such tapered shapes of the end portions of the mask layer 118R and the mask layer 119R can improve the coverage with the common layer 114 and the common electrode 115 provided over the mask layer 118R and the mask layer 119R.

The end portion of the mask layer 118R and the end portion of the mask layer 119R are each preferably positioned outward from the end portion of the insulating layer 125. In this case, unevenness of the formation surface of the common layer 114 and the common electrode 115 can be reduced and coverage with the common layer 114 and the common electrode 115 can be improved.

The insulating layer 127 covers at least part of the side surface of the insulating layer 125, the side surface of the mask layer 118R, the side surface of the mask layer 119R, the side surface of the mask layer 118G, and the side surface of the mask layer 119G in some cases. FIG. 16B illustrates a structure in which the insulating layer 127 covers the side surface of the insulating layer 125, part of the side surface of the mask layer 118R, the side surface of the mask layer 119R, part of the side surface of the mask layer 118G, and the side surface of the mask layer 119G.

The end portion of the insulating layer 127 is preferably positioned outward from the end portion of the insulating layer 125. In this case, unevenness of the formation surface of the common layer 114 and the common electrode 115 can be reduced and coverage with the common layer 114 and the common electrode 115 can be improved.

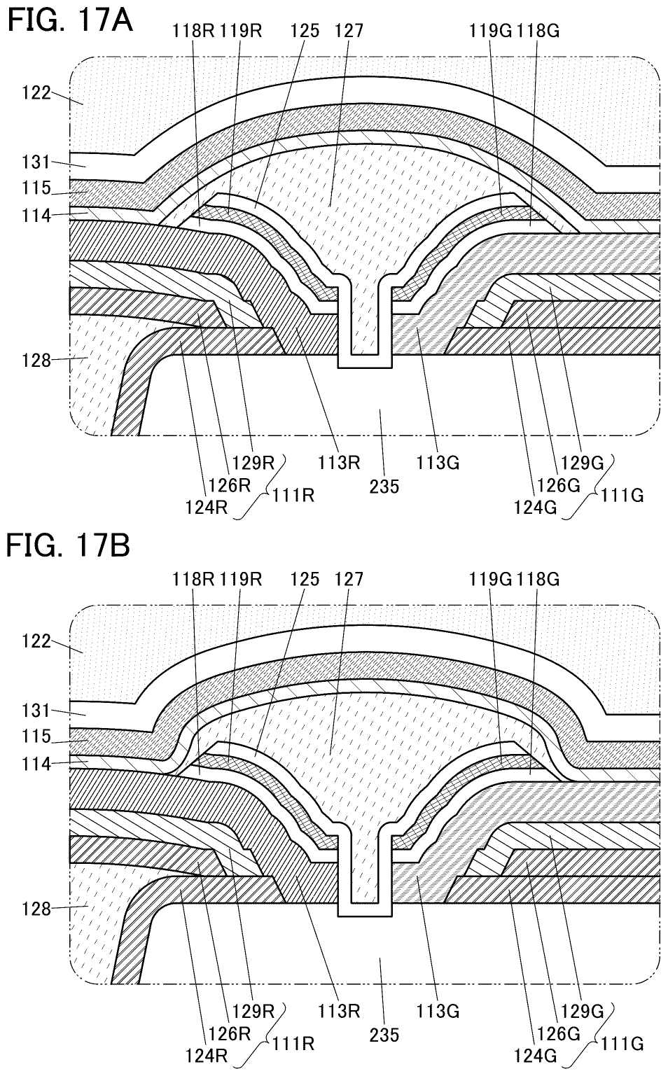

FIG. 17A illustrates an example in which the insulating layer 127 covers the entire side surface of the insulating layer 125, the entire side surface of the mask layer 118R, the entire side surface of the mask layer 119R, the entire side surface of the mask layer 118G, and the entire surface of the mask layer 119G. This is preferable because unevenness on the formation surface of the common layer 114 and the common electrode 115 can be further reduced. As illustrated in FIG. 17A, the insulating layer 127 may be in contact with the layer 113R and the layer 113G.

FIG. 17B illustrates examples in which the side surface of the insulating layer 127 has a concave shape (also referred to as a narrowed portion, a concave portion, a dent, or a hollow). Depending on the materials and the formation conditions (e.g., heating temperature, heating time, and heating atmosphere) of the insulating layer 127, the side surface of the insulating layer 127 has a concave shape in some cases.

One end portion of the insulating layer 127 preferably overlaps with the top surface of the pixel electrode 111R and the other end portion of the insulating layer 127 preferably overlaps with the top surface of the pixel electrode 111G. Such a structure enables the end portion of the insulating layer 127 to be formed over substantially flat regions of the layer 113R and the layer 113G.

Note that the insulating layer 127 does not necessarily overlap with the top surface of the pixel electrode 111. Meanwhile, a portion where the top surface of the pixel electrode 111 and the insulating layer 127 overlap with each other is preferably smaller because the light-emitting region of the light-emitting device can be wider and the aperture ratio can be higher.

As described above, provision of the insulating layer 127, the insulating layer 125, the mask layer 118R, the mask layer 118G, the mask layer 119R, and the mask layer 119G enables the common layer 114 and the common electrode 115 to be formed with favorable coverage from the substantially flat region of the layer 113R to the substantially flat region of the layer 113G. It is also possible to prevent formation of a disconnected portion and a locally thinned portion in the common layer 114 and the common electrode 115. This can inhibit the common layer 114 and the common electrode 115 between light-emitting devices from having connection defects due to the disconnected portion and an increased electric resistance due to the locally thinned portion. Thus, the display quality of the display apparatus of one embodiment of the present invention can be improved.

The common electrode 115 is shared by the light-emitting device 130R, the light-emitting device 130G, and the light-emitting device 130B. The common electrode 115 shared by the plurality of light-emitting devices is electrically connected to a conductive layer 123 provided in the connection portion 140 (see FIG. 2). The conductive layer 123 is preferably formed using a conductive layer formed using the same material and in the same step as the pixel electrode 111R, the pixel electrode 111G, and the pixel electrode 111B. For example, the conductive layer 123 can have a stacked-layer structure of a conductive layer 124p, a conductive layer 126p over the conductive layer 124p, and a conductive layer 129p over the conductive layer 126p. The conductive layer 124p can be formed in the same step as the conductive layer 124R, the conductive layer 124G, and the conductive layer 124B. The conductive layer 126p can be formed in the same step as the conductive layer 126R, the conductive layer 126G, and the conductive layer 126B. The conductive layer 129p can be formed in the same step as the conductive layer 129R, the conductive layer 129G, and the conductive layer 129B.

Note that FIG. 2 illustrates a structure in which the thickness of the conductive layer 129p is different from the thicknesses of the conductive layer 129R, the conductive layer 129G, and the conductive layer 129B. These thicknesses of the conductive layer 129p, the conductive layer 129R, the conductive layer 129G, and the conductive layer 129B may be different depending on the resistivities of materials used for these layers. In the case of making the thicknesses different, the conductive layer 129p may be formed in a step different from a step of forming the conductive layer 129R, the conductive layer 129G, and the conductive layer 129B. Alternatively, some formation steps may be common between the conductive layer 129p and the conductive layer 129R, the conductive layer 129G, and the conductive layer 129B.

The common layer 114 is not necessarily provided in the connection portion 140. FIG. 2 illustrates a structure in which the common electrode 115 is provided over the conductive layer 123. Note that an example in which the common layer 114 is provided over the conductive layer 123 and the conductive layer 123 and the common electrode 115 are electrically connected to each other through the common layer 114 may be employed. For example, by using a mask for specifying a film formation area (also referred to as an area mask or a rough metal mask to be distinguished from a fine metal mask), the common layer 114 and the common electrode 115 can be formed in different regions.

The protective layer 131 is preferably provided over the light-emitting device 130R, the light-emitting device 130G, and the light-emitting device 130B. Provision of the protective layer 131 can improve the reliability of the light-emitting device 130. The protective layer 131 may have a single-layer structure or a stacked-layer structure, and may have a stacked-layer structure including two or more layers.

There is no limitation on the conductivity of the protective layer 131. As the protective layer 131, at least one type of insulating films, semiconductor films, and conductive films can be used.

The protective layer 131 including an inorganic film can inhibit oxidation of the common electrode 115 and entry of impurities (e.g., moisture and oxygen) into the light-emitting device; thus, the deterioration of the light-emitting device can be inhibited and the reliability of the display apparatus can be improved.

For the protective layer 131, any of inorganic insulating films containing one or more of an oxide, a nitride, an oxynitride, and a nitride oxide can be used, for example. Specific examples of materials that can be used for these inorganic insulating films are as described above. In particular, the protective layer 131 preferably includes a nitride or a nitride oxide, and further preferably includes a nitride.

As the protective layer 131, an inorganic film containing In—Sn oxide (also referred to as ITO), In—Zn oxide, Ga—Zn oxide, Al—Zn oxide, indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can employ, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (e.g., water and oxygen) into the EL layer.

Furthermore, the protective layer 131 may include an organic film. For example, the protective layer 131 may include both an organic film and an inorganic film. Examples of an organic material that can be used for the protective layer 131 include organic insulating materials that can be used for the insulating layer 127.

The protective layer 131 may have a stacked structure of two layers which are formed by different film formation methods. Specifically, the first layer of the protective layer 131 may be formed by an ALD method, and the second layer of the protective layer 131 may be formed by a sputtering method.

A light-blocking layer 117 may be provided on the surface of the substrate 120 on the resin layer 122 side. The light-blocking layer 117 can be provided between adjacent light-emitting devices 130 and in the connection portion 140. The light-blocking layer 117 can prevent color mixture by blocking light emitted from adjacent subpixels. Furthermore, external light can be inhibited from reaching the transistor 205, and deterioration of the transistor 205 can be inhibited. Note that a structure in which the light-blocking layer 117 is not provided may be employed.

A variety of optical members can be provided on the outer surface of the substrate 120. Examples of optical members include a polarizing plate, a retardation plate, a light diffusion layer (e.g., a diffusion film), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer surface of the substrate 120. For example, it is preferable to provide, as the surface protective layer, a glass layer or a silica layer (SiOₓ layer) because the surface contamination and generation of damage can be inhibited. For the surface protective layer, DLC (diamond like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For the substrate 120, glass, quartz, ceramic, sapphire, a resin, a metal, an alloy, a semiconductor, or the like can be used. For the substrate through which light from the light-emitting device is extracted, a material that transmits the light is used. When a flexible material is used for the substrate 120, the flexibility of the display apparatus can be increased. Furthermore, a polarizing plate may be used as the substrate 120.

For the substrate 120, it is possible to use polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, and the like. Glass that is thin enough to have flexibility may be used as the substrate 120.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

In the case where a film is used as the substrate and the film absorbs water, the shape of the display apparatus might be changed, e.g., creases might be caused. Thus, as the substrate, a film with a low water absorption rate is preferably used. For example, a film with a water absorption rate lower than or equal to 1% is preferably used, a film with a water absorption rate lower than or equal to 0.1% is further preferably used, and a film with a water absorption rate lower than or equal to 0.01% is still further preferably used.

For the resin layer 122, a variety of curable adhesives such as a photocurable adhesive like an ultraviolet curable adhesive, a reactive curable adhesive, a thermosetting adhesive, and an anaerobic adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

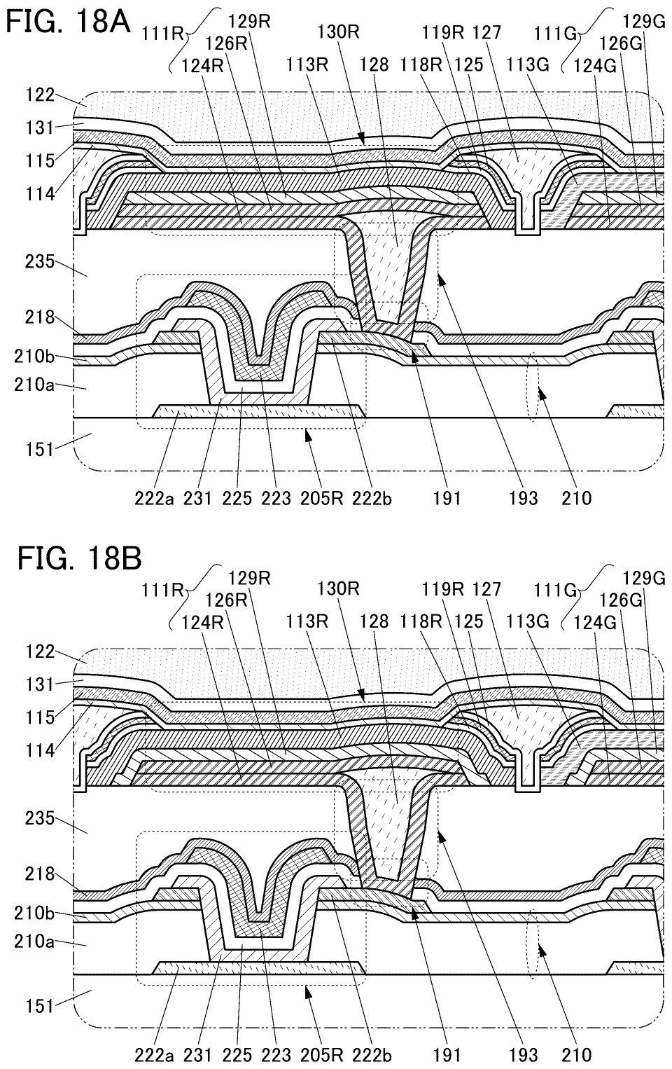

FIG. 18A and FIG. 18B illustrate structure examples of the pixel electrode 111R different from that of the pixel electrode 111R illustrated in FIG. 2 and the like.

In the pixel electrode 111R illustrated in FIG. 18A, the end portions of the conductive layer 129R, the conductive layer 126R, and the conductive layer 124R are aligned or substantially aligned with one another. The layer 113R is in contact with the side surface of the conductive layer 129R, the side surface of the conductive layer 126R, and the side surface of the conductive layer 124R.

For example, a first conductive film to be the conductive layer 124R, the layer 128, a second conductive film to be the conductive layer 126R, and a third conductive film to be the conductive layer 129R are formed; after that, a resist mask is formed over the third conductive film, and the first conductive film, the second conductive film, and the third conductive film are processed using the resist mask, whereby the conductive layer 124R, the conductive layer 126R, and the conductive layer 129R can be formed. The first conductive film, the second conductive film, and the third conductive film are processed in the same step to form the conductive layer 124R, the conductive layer 126R, and the conductive layer 129R, whereby the process can be simplified.

In the pixel electrode 111R illustrated in FIG. 18B, the side surface of the conductive layer 124R and the top surface and the side surface of the conductive layer 126R are covered with the conductive layer 129R. The end portion of the conductive layer 124R and the end portion of the conductive layer 126R are aligned or substantially aligned with each other. The layer 113R is in contact with the top surface and the side surface of the conductive layer 129R.

For example, the first conductive film to be the conductive layer 124R, the layer 128, and the second conductive film to be the conductive layer 126R are formed; after that, a resist mask is formed over the second conductive film, and the first conductive film and the second conductive film are processed using the resist mask, whereby the conductive layer 124R and the conductive layer 126R are formed. After that, the third conductive film to be the conductive layer 129R is formed to cover the conductive layer 124R and the conductive layer 126R, and the third conductive film is processed, whereby the conductive layer 129R can be formed. The first conductive film and the second conductive film are processed in the same step to form the conductive layer 124R and the conductive layer 126R, whereby the process can be simplified. Even when a material that is easily diffused, such as silver, is used for the conductive layer 124R or the conductive layer 126R, diffusion can be inhibited by covering the top surfaces and the side surfaces of the conductive layer 124R and the conductive layer 126R with the conductive layer 129R.

Although FIG. 18A and the like illustrate a structure in which the top surface of the layer 128 has a shape in which the center and the vicinity thereof are bulged, i.e., a shape including a convex surface, in the cross-sectional view, the shape of the layer 128 is not particularly limited. The top surface of the layer 128 can have a shape in which its center and the vicinity thereof are depressed, i.e., a shape including a concave surface, in the cross-sectional view. The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 124R may be equal to or substantially equal to each other, or may be different from each other. For example, the level of the top surface of the layer 128 may be either lower or higher than the level of the top surface of the conductive layer 124R.

A structure example different from that of the above-described display apparatus will be described below. Note that description of the same portions as those in the above-described display apparatus is omitted in some cases. Furthermore, in drawings that are referred to later, the same hatching pattern is applied to portions having functions similar to those in the display apparatus described above, and the portions are not indicated by reference numerals in some cases.

### <Structure Example 2 of Display Apparatus>

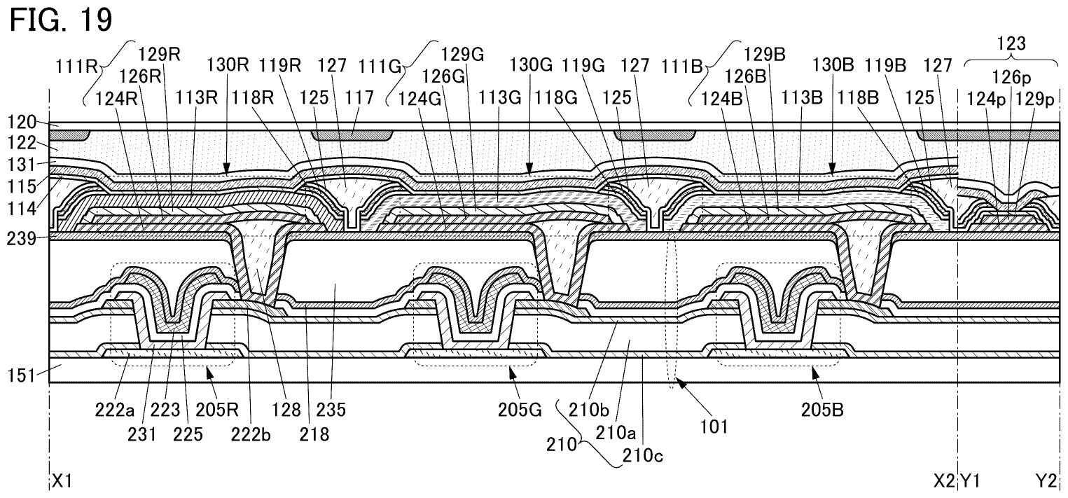

FIG. 19 is cross-sectional view of a display apparatus of one embodiment of the present invention. FIG. 19 is a cross-sectional view taken along the dashed-dotted line X1-X2 and the dashed-dotted line Y1-Y2 in FIG. 1A.

The display apparatus illustrated in FIG. 19 is different from the display apparatus illustrated in FIG. 2 mainly in including an insulating layer 239 between the insulating layer 235 and each of the light-emitting device 130R, the light-emitting device 130G, and the light-emitting device 130B.

The insulating layer 239 is provided over the insulating layer 235 and includes an opening included in a region overlapping with the opening in the insulating layer 235. The pixel electrode 111 is provided to cover an opening provided in the insulating layer 239, the insulating layer 235, the insulating layer 218, and the insulating layer 225.

The insulating layer 239 can function as an etching protective film when the layer 113, the mask layer 118, and the mask layer 119 are formed. Provision of the insulating layer 239 can prevent generation of unevenness in the insulating layer 235 caused by etching of part of the insulating layer 235 at the time when the layer 113, the mask layer 118, and the mask layer 119 are formed. Thus, steps in the formation surface of the insulating layer 125 become small, whereby the coverage with the insulating layer 125 can be improved. Consequently, the side surface of the layer 113 is covered with the insulating layer 125, which inhibits film separation of the layer 113.

The insulating layer 239 can be an insulating layer containing an inorganic material. For example, one or more of an oxide, a nitride, an oxynitride, and a nitride oxide can be used for the insulating layer 239. The insulating layer 239 may have a single-layer structure or a stacked-layer structure. Examples of the oxide include silicon oxide, aluminum oxide, magnesium oxide, indium gallium zinc oxide, gallium oxide, germanium oxide, yttrium oxide, zirconium oxide, lanthanum oxide, neodymium oxide, hafnium oxide, and tantalum oxide. Examples of the nitride include silicon nitride and aluminum nitride. Examples of the oxynitride include silicon oxynitride and aluminum oxynitride. Examples of the nitride oxide include silicon nitride oxide and aluminum nitride oxide. A silicon oxide or a silicon oxynitride can be suitably used for the insulating layer 239, for example.

For the insulating layer 239, it is preferable to select a material having a high etching rate (also referred to as high selectivity) with respect to films to be the layer 113, the mask layer 118, and the mask layer 119 in etching of the films.

Here, the low flatness of the formation surface of the light-emitting device 130 might cause a defect such as a connection defect due to step disconnection of the common electrode 115 or an increase in electric resistance due to local thinning of the common electrode 115. In addition, the processing accuracy of the layer formed on the formation surface is decreased in some cases.

When the insulating layer 239 is provided in the display apparatus of one embodiment of the present invention, the formation surface of the light-emitting device 130 can be flatter. Accordingly, the processing accuracy of the light-emitting devices 130 and the like provided over the insulating layer 239 is increased, whereby the display apparatus can have high definition. Furthermore, since a connection defect due to disconnection of the common electrode 115 and an increase in electric resistance due to the locally thinned regions of the common electrode 115 can be prevented, the display apparatus can have high display quality.

Although the insulating layer 239 has a single-layer structure in FIG. 19 and the like, one embodiment of the present invention is not limited thereto. The insulating layer 239 may have a stacked-layer structure.

In the region that does not overlap with any of the layer 113R, the layer 113G, and the layer 113B, part of the insulating layer 239 may be removed. The thickness of the insulating layer 239 in the region that does not overlap with any of the layer 113R, the layer 113G, and the layer 113B may be smaller than the thickness of the insulating layer 239 in the region that overlaps with the layer 113R, the layer 113G, or the layer 113B.

Note that the insulating layer 239 can be applied to other structure examples.

FIG. 19 illustrates a structure example in which the transistor 200A illustrated in FIG. 8 is used as each of the transistor 205R, the transistor 205G, and the transistor 205B. The insulating layer 210 has a stacked-layer structure of the insulating layer 210c, the insulating layer 210a over the insulating layer 210c, and the insulating layer 210b over the insulating layer 210a. The insulating layer 210c is provided to cover the top surface and the side surface of the conductive layer 222a included in the transistor 205R, the top surface and the side surface of the conductive layer 222a included in the transistor 205G, the top surface and the side surface of the conductive layer 222a included in the transistor 205B, and the top surface of the substrate 151. The above description can be referred to for the insulating layer 210c; thus, the detailed description thereof is omitted.

### <Structure Example 3 of Display Apparatus>

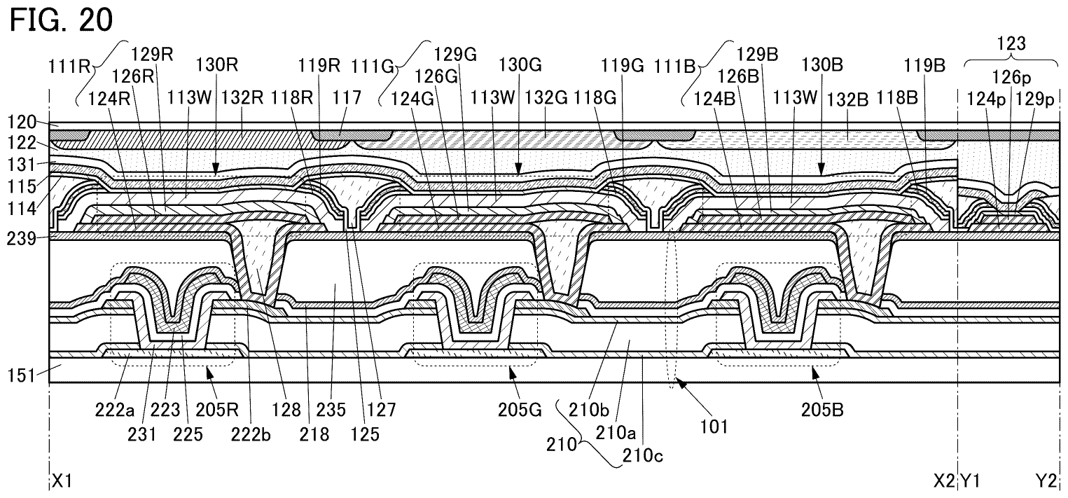

FIG. 20 is a cross-sectional view of a display apparatus of one embodiment of the present invention. FIG. 20 is a cross-sectional view taken along the dashed-dotted line X1-X2 and the dashed-dotted line Y1-Y2 in FIG. 1A.

The display apparatus illustrated in FIG. 20 is different from the display apparatus illustrated in FIG. 19 mainly in the structures of the light-emitting device 130R, the light-emitting device 130G, and the light-emitting device 130B.

The light-emitting device 130R includes a layer 113W instead of the layer 113R. The light-emitting device 130G includes the layer 113W instead of the layer 113G. The light-emitting device 130B includes the layer 113W instead of the layer 113B. The layer 113W can be configured to emit white light, for example.

A conductive layer having a property of transmitting visible light may be used for the conductive layer 129R, the conductive layer 129G, and the conductive layer 129B and their thicknesses may be different from one another. The conductive layer 129R, the conductive layer 129G, and the conductive layer 129B can function as optical adjustment layers. When the thicknesses of the conductive layer 129R, the conductive layer 129G, and the conductive layer 129B are adjusted to obtain optimum path lengths, light with a desired wavelength intensified can be obtained from the light-emitting devices 130 even in the case where the layer 113W emitting white light is used.

A coloring layer 132R transmitting red light, a coloring layer 132G transmitting green light, and a coloring layer 132B transmitting blue light may be provided on the side of the substrate 120 that faces the resin layer 122. The coloring layer 132R is provided in a region overlapping with the light-emitting device 130R. The coloring layer 132G is provided in a region overlapping with the light-emitting device 130G. The coloring layer 132B is provided in a region overlapping with the light-emitting device 130B. For example, light with unnecessary wavelengths emitted from the red-the light-emitting device 130R can be blocked by the coloring layer 132R. Such a structure can increase the color purity of light emitted from each light-emitting device. Note that a similar effect can be obtained in a combination of the light-emitting device 130G and the coloring layer 132G or a combination of the light-emitting device 130B and the coloring layer 132B.

Note that the coloring layer 132R, the coloring layer 132G, and the coloring layer 132B can be applied to other structure examples.

### <Structure Example 4 of Display Apparatus>

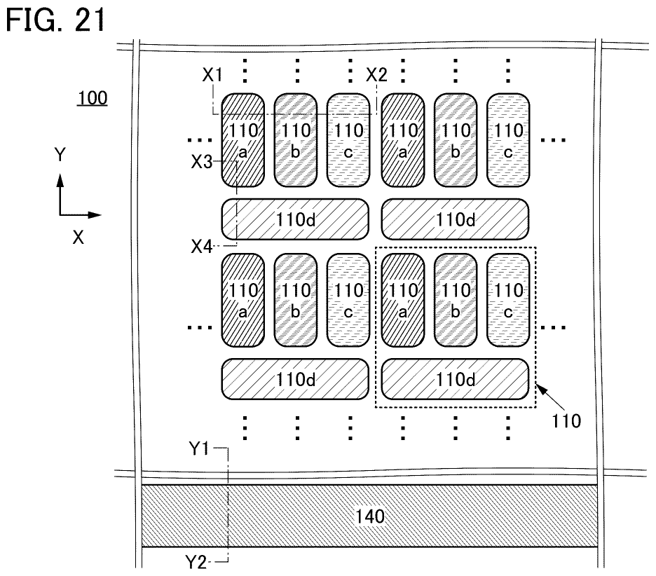

FIG. 21 illustrates a top view of the display apparatus 100 different from that in FIG. 1. The pixel 110 illustrated in FIG. 21 is composed of four kinds of subpixels: the subpixel 110a, the subpixel 110b, the subpixel 110c, and a subpixel 110d.

The subpixel 110a, the subpixel 110b, the subpixel 110c, and the subpixel 110d can be configured to include light-emitting devices whose emission colors are different. The subpixel 110a, the subpixel 110b, the subpixel 110c, and the subpixel 110d are subpixels of four colors of R, G, B, and W, subpixels of four colors of R, G, B, and Y, or subpixels of four types of R, G, B, and IR, for example.

The display apparatus of one embodiment of the present invention may include a light-receiving device in the pixel.

Three of the four subpixels included in the pixel 110 illustrated in FIG. 21 may each be configured to include a light-emitting device and the other one may be configured to include a light-receiving device.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

The light-receiving device can detect one or both of visible light and infrared light. In the case of detecting visible light, for example, one or more of blue light, violet light, bluish violet light, green light, yellowish green light, yellow light, orange light, red light, and the like can be detected. The infrared light is preferably detected because an object can be detected even in a dark environment.

It is particularly preferable to use an organic photodiode including a layer containing an organic compound as the light-receiving device. An organic photodiode, which is easily made thin, lightweight, and large in area and has a high degree of freedom for shape and design, can be used for a variety of display apparatuses.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

The light-receiving device is driven by application of reverse bias between the pixel electrode and the common electrode, whereby light entering the light-receiving device can be detected and electric charge can be generated and extracted as a current.

A manufacturing method similar to that for the light-emitting device can be employed for the light-receiving device. An island-shaped active layer (also referred to as a photoelectric conversion layer) included in the light-receiving device is formed not by using a fine metal mask but by processing a film to be the active layer formed on the entire surface; thus, the island-shaped active layer can be formed to have a uniform thickness. Moreover, provision of the mask layer over the active layer can reduce damage to the active layer in the manufacturing process of the display apparatus, resulting in an improvement in reliability of the light-receiving device.

Embodiment 6 can be referred to for the structure and the materials of the light-receiving device.

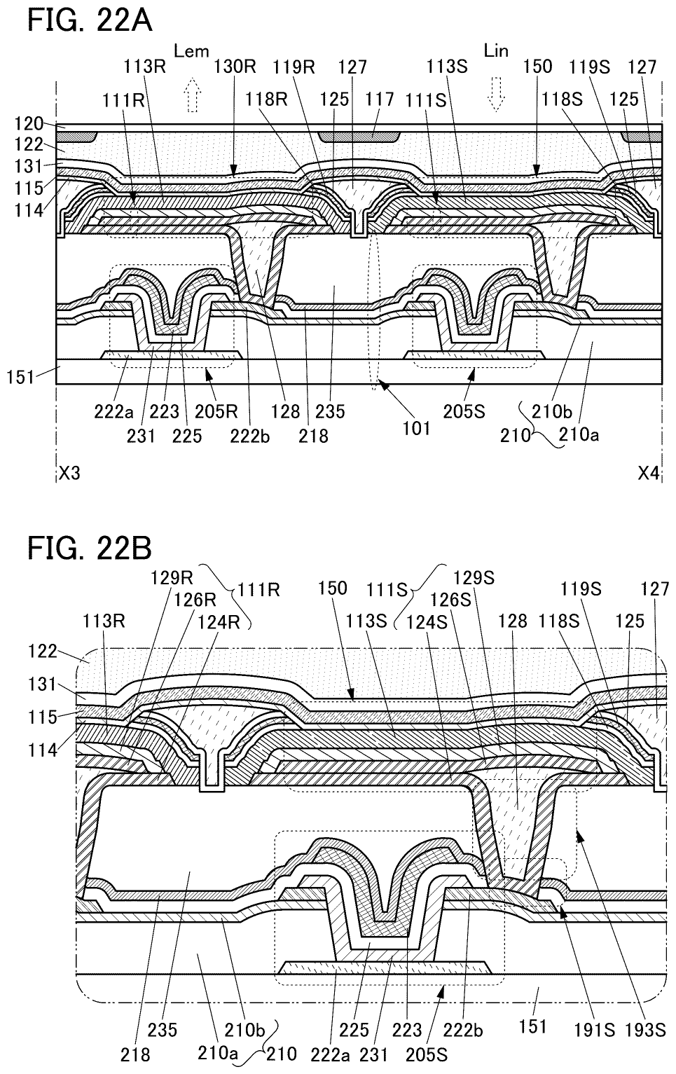

FIG. 22A is a cross-sectional view taken along the dashed-dotted line X3-X4 in FIG. 21. Note that for the cross-sectional view taken along the dashed-dotted line X1-X2 and the cross-sectional view taken along the dashed-dotted line Y1-Y2 in FIG. 21, FIG. 2 can be referred to.

As illustrated in FIG. 22A, in the display apparatus 100, the light-emitting device 130R and a light-receiving device 150 are provided over the layer 101 including transistors, the protective layer 131 is provided to cover the light-emitting device and the light-receiving device, and the substrate 120 is bonded with the resin layer 122. In a region between the light-emitting device and the light-receiving device adjacent to each other, the insulating layer 125 and the insulating layer 127 over the insulating layer 125 are provided.

FIG. 22A illustrates an example in which light is emitted from the light-emitting device 130R to the substrate 120 side and light enters the light-receiving device 150 from the substrate 120 side (see light Lem and light Lin).

The structure of the light-emitting device 130R is as described above.

The light-receiving device 150 includes a pixel electrode 111S over the insulating layer 235, a layer 113S over the pixel electrode 111S, the common layer 114 over the layer 113S, and the common electrode 115 over the common layer 114. The layer 113S includes at least an active layer.

Here, the layer 113S includes at least an active layer, preferably includes a plurality of functional layers. Examples of the functional layer include carrier-transport layers (a hole-transport layer and an electron-transport layer) and carrier-blocking layers (a hole-blocking layer and an electron-blocking layer). In addition, one or more layers are preferably provided over the active layer. A layer between the active layer and the mask layer can inhibit the active layer from being exposed on the outermost surface during the manufacturing process of the display apparatus and can reduce damage to the active layer. Accordingly, the reliability of the light-receiving device 150 can be improved. Thus, the layer 113S preferably includes an active layer and a carrier-blocking layer (a hole-blocking layer or an electron-blocking layer) or a carrier-transport layer (an electron-transport layer or a hole-transport layer) over the active layer.

The layer 113S is a layer that is provided in the light-receiving device 150 and is not in the light-emitting devices. Note that the functional layer other than the active layer included in the layer 113S may include the same material as the functional layer other than the light-emitting layer included in each of the layer 113B to the layer 113R. Meanwhile, the common layer 114 is a continuous layer shared by the light-emitting device and the light-receiving device.

Here, a layer shared by the light-receiving device and the light-emitting device may have different functions in the light-emitting device and the light-receiving device. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. For example, the hole-transport layer functions as a hole-transport layer in both the light-emitting device and the light-receiving device, and the electron-transport layer functions as an electron-transport layer in both the light-emitting device and the light-receiving device.

The mask layer 118R and the mask layer 119R are positioned between the layer 113R and the insulating layer 125, and a mask layer 118S and a mask layer 119S are positioned between the layer 113S and the insulating layer 125. The mask layer 118R and the mask layer 119R are each a remaining part of a mask layer provided over the layer 113R at the time of processing the layer 113R. The mask layer 118S and the mask layer 119S are each a remaining part of a mask layer provided in contact with the top surface of the layer 113S at the time of processing the layer 113S, which is a layer including the active layer. The mask layer 118R and the mask layer 118S may contain the same material or different materials. The mask layer 119R and the mask layer 119S may contain the same material or different materials.

FIG. 22B illustrates an enlarged view of the light-receiving device 150, the transistor 205S, and the vicinity thereof illustrated in FIG. 22A. The light-receiving device 150 is electrically connected to a transistor 205S. The transistor 205S can be formed in the same step as the transistor 205R, the transistor 205G, and the transistor 205B. The conductive layer 222b functioning as the source or the drain of the transistor 205S is electrically connected to the pixel electrode 111S through an opening 191S provided in the insulating layer 225 and the insulating layer 218 and an opening 193S provided in the insulating layer 235.

The opening 191S can be formed in the same step as the opening 191. The opening 193S can be formed in the same step as the opening 193. The description of the opening 191 and the opening 193 can be referred to for the opening 191S and the opening 193S; thus, the detailed description thereof is omitted. The pixel electrode 111S can be formed in the same step as the pixel electrode 111R, the pixel electrode 111G, and the pixel electrode 111B. The pixel electrode 111S can have a stacked-layer structure of a conductive layer 124S, a conductive layer 126S over the conductive layer 124S, and a conductive layer 129S over the conductive layer 126S. The description of the conductive layer 124R, the conductive layer 124G, the conductive layer 124B, the conductive layer 126R, the conductive layer 126G, the conductive layer 126B, the conductive layer 129R, the conductive layer 129G, and the conductive layer 129B can be referred to for the conductive layer 124S, the conductive layer 126S, and the conductive layer 129S; thus, the detailed description thereof is omitted.

Although FIG. 21 illustrates an example where an aperture ratio (also referred to as a size or a size of the light-emitting region or the light-receiving region) of the subpixel 110d is higher than those of the subpixel 110a, the subpixel 110b, and the subpixel 110c, one embodiment of the present invention is not limited thereto. The aperture ratio of each of the subpixel 110a, the subpixel 110b, the subpixel 110c, and the subpixel 110d can be determined as appropriate. The aperture ratios of the subpixel 110a, the subpixel 110b, the subpixel 110c, and the subpixel 110d may be different from each other, or two or more of the aperture ratios may be the same or substantially the same.

The subpixel 110d may have a higher aperture ratio than at least one of the subpixel 110a, the subpixel 110b, and the subpixel 110c. The wide light-receiving area of the subpixel 110d can make it easy to detect an object in some cases. For example, in some cases, the aperture ratio of the subpixel 110d is higher than that of the other subpixels depending on the definition of the display apparatus and the circuit structure or the like of the subpixel.

The subpixel 110d may have a lower aperture ratio than at least one of the subpixel 110a, the subpixel 110b, and the subpixel 110c. A smaller light-receiving area of the subpixel 110d leads to a narrower image-capturing range, so that a blur in a capturing result is inhibited and the resolution is increased. This is preferable because high-definition or high-resolution image capturing can be performed.

As described above, the subpixel 110d can have a detection wavelength, a definition, and an aperture ratio that are suitable for the intended use.

In the display apparatus of one embodiment of the present invention, an island-shaped EL layer is provided in each light-emitting device, which can inhibit generation of a leakage current between the subpixels. This can prevent unintended light emission due to crosstalk, so that a display apparatus with high contrast can be achieved. An end portion of the island-shaped EL layer and the vicinity thereof, which might be damaged in the manufacturing process of the display apparatus, are set as a dummy region not to be used as the light-emitting region, whereby variations in the characteristics of the light-emitting devices can be inhibited. Provision of the insulating layer having a tapered end portion between adjacent island-shaped EL layers can inhibit formation of step disconnection and prevent formation of a locally thinned portion in the common electrode at the time of forming the common electrode. This can inhibit the common layer and the common electrode from having connection defects due to a disconnected portion and an increased electric resistance due to a locally thinned portion. Thus, the display apparatus of one embodiment of the present invention can have both a higher definition and higher display quality.

This embodiment can be combined with the other embodiments as appropriate. In this specification, in the case where a plurality of structure examples are illustrated in one embodiment, the structure examples can be combined as appropriate.

### Embodiment 2

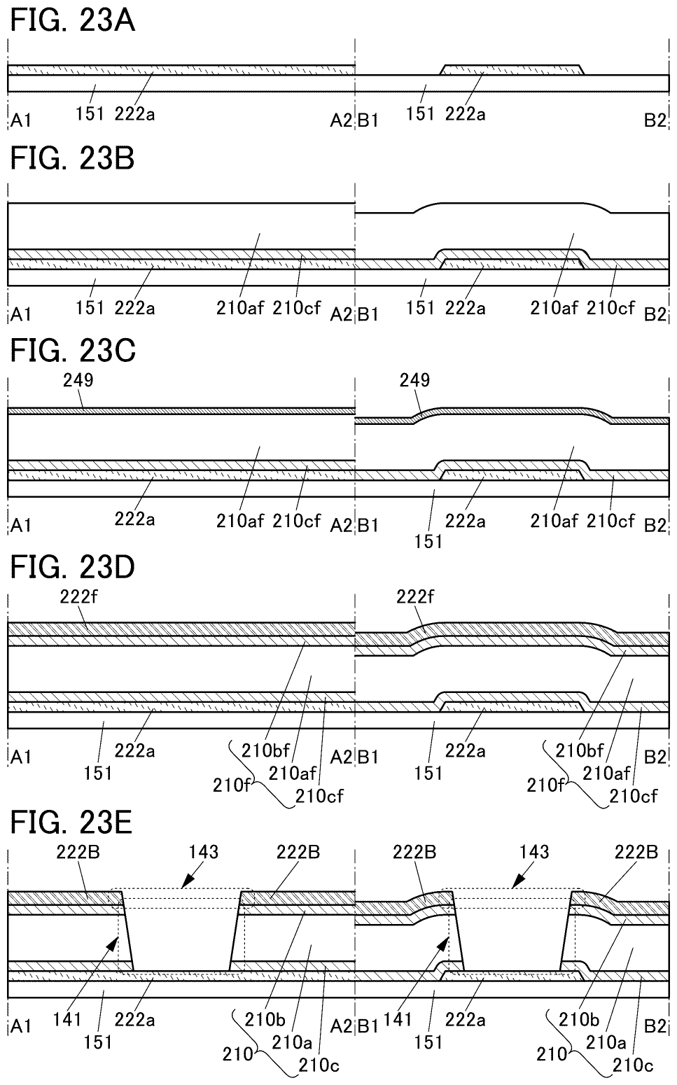

In this embodiment, examples of a manufacturing method of a display apparatus of one embodiment of the present invention will be described with reference to FIG. 23 to FIG. 37. Note that as for a material and a formation method of each component, portions similar to the portions described in Embodiment 1 are not described in some cases. The structure of the light-emitting device will be described in detail in Embodiment 5.

Thin films included in the display apparatus (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like. Examples of a CVD method include a plasma-enhanced CVD (PECVD) method and a thermal CVD method. An example of a thermal CVD method is a metal organic chemical vapor deposition (MOCVD) method.

Alternatively, thin films included in the display apparatus (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

Specifically, for manufacture of the light-emitting device, a vacuum process such as an evaporation method and a solution process such as a spin coating method or an inkjet method can be used. Examples of an evaporation method include physical vapor deposition methods (PVD methods) such as a sputtering method, an ion plating method, an ion beam evaporation method, a molecular beam evaporation method, and a vacuum evaporation method, and a chemical vapor deposition method (CVD method). Specifically, functional layers (e.g., a hole-injection layer, a hole-transport layer, a hole-blocking layer, a light-emitting layer, an electron-blocking layer, an electron-transport layer, an electron-injection layer, and a charge-generation layer) included in the EL layer can be formed by a method such as an evaporation method (e.g., a vacuum evaporation method), a coating method (e.g., a dip coating method, a die coating method, a bar coating method, a spin coating method, or a spray coating method), or a printing method (e.g., an inkjet method, a screen printing (stencil) method, an offset printing (planography) method, a flexography (relief printing) method, a gravure printing method, or a micro-contact printing method).

Thin films included in the display apparatus can be processed by a photolithography method or the like. Alternatively, the thin films may be processed by a nanoimprinting method, a sandblasting method, a lift-off method, or the like. Alternatively, island-shaped thin films may be directly formed by a film formation method using a shielding mask such as a metal mask.

There are the following two typical examples of photolithography methods. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light used for light exposure in a photolithography method, it is possible to use light with the i-line (wavelength: 365 nm), light with the g-line (wavelength: 436 nm), light with the h-line (wavelength: 405 nm), or combined light of any of them. Alternatively, ultraviolet rays, KrF laser light, ArF laser light, or the like can be used. Light exposure may be performed by liquid immersion light exposure technique. As the light used for light exposure, extreme ultraviolet (EUV) light or X-rays may also be used. Furthermore, instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, a dry etching method, a wet etching method, a sandblast method, or the like can be used.

A method for manufacturing the display apparatus illustrated in FIG. 19 is described. Here, a structure in which an oxide semiconductor is used for the semiconductor layer 231 of each of the transistor 205R, the transistor 205G, and the transistor 205B is described as an example.

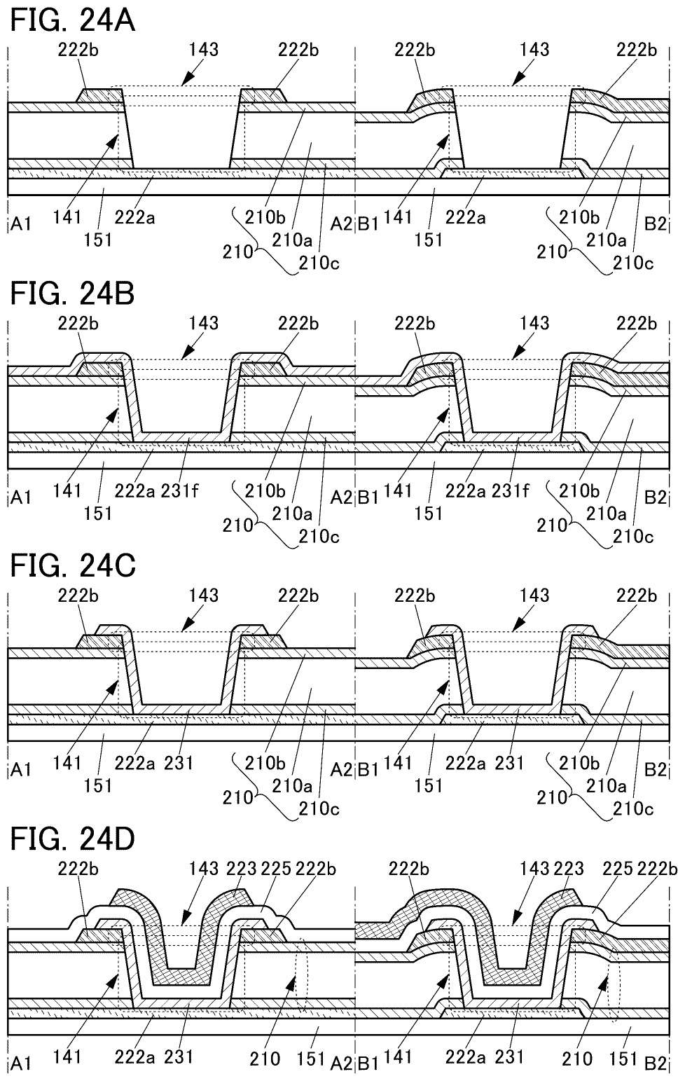

First, the transistor 205R, the transistor 205G, and the transistor 205B are formed over the substrate 151. Here, description is made with reference to FIG. 23A to FIG. 24D using the transistor 205R as an example. Note that FIG. 23A to FIG. 24D are cross-sectional views at respective stages of the manufacturing process of the transistor 205R, and FIG. 23A to FIG. 24D are cross-sectional views each illustrating a cut plane along the dashed-dotted line A1-A2 and a cut plane along the dashed-dotted line B1-B2 side by side.

[Formation of Conductive Layer 222a]

A conductive film to be the conductive layer 222a is formed over the substrate 151. For the formation of the conductive film, a sputtering method can be suitably used, for example. After a resist mask is formed over the conductive film by a photolithography process, the conductive film is processed, whereby the island-shaped conductive layer 222a functioning as one of the source electrode and the drain electrode is formed (FIG. 23A). For the processing of the conductive layer, one or both of a wet etching method and a dry etching method are used.

[Formation of Insulating Film 210cf and Insulating Film 210af]

Next, an insulating film 210cf to be the insulating layer 210c and an insulating film 210af to be the insulating layer 210a are formed over the substrate 151 and the conductive layer 222a (FIG. 23B).

For the formation of the insulating film 210cf and the insulating film 210af, a PECVD method can be suitably used, for example. After the insulating film 210cf is formed, the insulating film 210af is preferably formed successively in a vacuum without exposure of the surface of the insulating film 210cf to the air. When the insulating film 210cf and the insulating film 210af are successively formed, attachment of impurities derived from the air to the surface of the insulating film 210cf can be inhibited. Examples of the impurities include water and organic substances.

The substrate temperature at the time of forming the insulating film 210cf and the insulating film 210af is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperature at the time of forming the insulating film 210cf and the insulating film 210af is in the above range, release of impurities (e.g., water and hydrogen) from the insulating film 210cf and the insulating film 210af themselves can be reduced, so that diffusion of impurities into the semiconductor layer 231 can be inhibited. Consequently, the transistor can have favorable electrical characteristics and high reliability.

Note that since the insulating film 210cf and the insulating film 210af are formed earlier than the semiconductor layer 231, there is no need to consider the oxygen release from the semiconductor layer 231 due to heat applied thereto at the time of the formation of the insulating film 210cf and the insulating film 210af.

Heat treatment may be performed after the insulating film 210cf and the insulating film 210af are formed. By the heat treatment, water or hydrogen can be released from the surface and inside of the insulating film 210cf and the insulating film 210af.

The temperature of the heat treatment is preferably higher than or equal to 150° C. and lower than the strain point of the substrate, further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. The heat treatment can be performed in an atmosphere containing one or more of a noble gas, nitrogen, and oxygen. As a nitrogen-containing atmosphere or an oxygen-containing atmosphere, clean dry air (CDA) may be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating film 210cf and the insulating film 210af can be prevented as much as possible. An oven, a rapid thermal annealing (RTA) apparatus, or the like can be used for the heat treatment. The use of the RTA apparatus can shorten the heat treatment time.

Next, a metal oxide layer 249 is formed over the insulating film 210af (FIG. 23C).

The metal oxide layer 249 may be an insulating layer or a conductive layer. For the metal oxide layer 249, aluminum oxide, hafnium oxide, hafnium aluminate, indium oxide, indium tin oxide (ITO), or indium tin oxide containing silicon (ITSO) can be used, for example.

For the metal oxide layer 249, an oxide material containing one or more elements that are the same as those of the semiconductor layer 231 is preferably used. It is particularly preferable to use an oxide semiconductor material that can be used for the semiconductor layer 231.

A metal oxide film formed using a sputtering target having the same composition as the semiconductor layer 231 can be used as the metal oxide layer 249. The sputtering target having the same composition as the semiconductor layer 231 is preferably used, in which case the same manufacturing apparatus and the same sputtering target can be used.

When a metal oxide material containing indium and gallium is used for both the semiconductor layer 231 and the metal oxide layer 249, a material whose composition (content percentage) of gallium is higher than that in the semiconductor layer 231 can be used for the metal oxide layer 249. It is preferable to use a material whose composition (content ratio) of gallium is high for the metal oxide layer 249, in which case an oxygen blocking property can be further enhanced. Here, when the semiconductor layer 231 is formed using a material whose composition of indium is higher than that in the metal oxide layer 249, the field-effect mobility of the transistor can be increased.

The metal oxide layer 249 is preferably formed in, for example, an oxygen-containing atmosphere. It is particularly preferable to form the metal oxide layer 249 by a sputtering method in an oxygen-containing atmosphere. Accordingly, oxygen can be suitably supplied to the insulating film 210af at the time of forming the metal oxide layer 249.

For example, the metal oxide layer 249 may be formed by a reactive sputtering method using oxygen as a film formation gas and a metal target. When aluminum is used for the metal target, for instance, an aluminum oxide film can be formed.

At the time of forming the metal oxide layer 249, as the oxygen flow rate ratio in the treatment chamber of the deposition apparatus or the oxygen partial pressure in the treatment chamber is made higher, the amount of oxygen supplied to the insulating film 210af can be increased. The oxygen flow rate ratio or the oxygen partial pressure is, for example, higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the metal oxide layer 249 is formed by a sputtering method in an oxygen-containing atmosphere in the above manner, release of oxygen from the insulating film 210af can be prevented while supplying oxygen to the insulating film 210af during the formation of the metal oxide film 210af. As a result, a large amount of oxygen can be enclosed in the insulating film 210af. Moreover, a large amount of oxygen can be supplied to the semiconductor layer 231 by heat treatment performed later. As a result, oxygen vacancies (Vo) and VoH in the semiconductor layer 231 can be reduced, and the transistor can have favorable electrical characteristics and high reliability.

After the metal oxide layer 249 is formed, heat treatment may be performed. The above description can be referred to for the heat treatment; thus, the detailed description thereof is omitted. By the heat treatment performed after the formation of the metal oxide layer 249, oxygen can be effectively supplied from the metal oxide layer 249 to the insulating film 210af.

After the formation of the metal oxide layer 249 or the above heat treatment, oxygen may be further supplied to the insulating film 210af through the metal oxide layer 249. As a method for supplying oxygen, for example, an ion implantation method, an ion doping method, a plasma immersion ion implantation method, plasma treatment, or the like can be used. An apparatus in which an oxygen gas is made to be plasma by high-frequency power can be suitably used for the plasma treatment. Examples of an apparatus for converting a gas into plasma with high-frequency power include a plasma etching apparatus and a plasma ashing apparatus.

Then, the metal oxide layer 249 is removed. There is no particular limitation on a method for removing the metal oxide layer 249, and wet etching can be suitably used. When wet etching is employed, the insulating film 210af can be inhibited from being etched at the time the metal oxide layer 249 is removed. This can inhibit a reduction in the thickness of the insulating layer 210af and the thickness of the insulating layer 210a can be uniform.

The treatment for supplying oxygen to the insulating film 210af is not limited to the above method. For example, as the oxygen supply treatment, an oxygen radical, an oxygen atom, an oxygen atomic ion, an oxygen molecular ion, or the like is supplied to the insulating film 210af by an ion doping method, an ion implantation method, plasma treatment, or the like. Alternatively, a film that suppresses oxygen release may be formed over the insulating film 210af, and then oxygen may be supplied to the insulating film 210af through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

[Formation of Insulating Film 210Bf and Formation of Conductive Film 222f]

Next, the insulating film 210bf to be the insulating layer 210b is formed over the insulating film 210af. The description of the formation of the insulating film 210af and the insulating film 210cf can be referred to for the formation of the insulating film 210bf; thus, the detailed description thereof is omitted.

Next, a conductive film 222f to be the conductive layer 222b is formed over the insulating film 210bf (FIG. 23D). For formation of the conductive film 222f, a sputtering method can be suitably used, for example.

### [Formation of Opening 141 and Formation of Opening 143]

Next, the conductive film 222f in a region overlapping with the conductive layer 222a is removed to form a conductive layer 222B including the opening 143. For the formation of the opening 143, one or both of a wet etching method and a dry etching method can be used. A wet etching method can be suitably used to form the opening 143, for example.

Next, an insulating film 210f (the insulating film 210af, the insulating film 210bf, and the insulating film 210cf) in a region overlapping with the conductive layer 222a is removed to form the insulating layer 210 including the opening 141 (FIG. 23E). For the formation of the opening 141, one or both of a wet etching method and a dry etching method can be used. A dry etching method, can be suitably used to form the opening 141, for example.

The opening 141 can be formed using the resist mask used for the formation of the opening 143, for example. Specifically, a resist mask is formed over the conductive film 222f, the conductive film 222f is removed using the resist mask to form the opening 143, and the insulating film 210f is removed using the resist mask to form the opening 141. Note that the processing the opening 143 to have the width D143 larger than the width of the mask enables manufacture of the transistor 200C illustrated in FIG. 10A and the like. The opening 143 may be formed using a resist mask different from the resist mask used for forming the opening 141.

[Formation of Conductive Layer 222b]

Then, the conductive layer 222B is processed into a desired shape to form the conductive layer 222b (FIG. 24A). For the formation of the conductive layer 222b, one or both of a wet etching method and a dry etching method can be used. A wet etching method can be suitably used to form the conductive layer 222b, for example.

### [Formation of Semiconductor Layer 231]

Next, the metal oxide film 231f to be the semiconductor layer 231 is formed to cover the opening 141 and the opening 143 (FIG. 24B). The metal oxide film 231f is provided in contact with the top surface and the side surface of the conductive layer 222b, the top surface and the side surface of the insulating layer 210, and the top surface of the conductive layer 222a.

The metal oxide film 231f is preferably formed by a sputtering method using a metal oxide target.

The metal oxide film 231f is preferably a dense film with as few defects as possible. The metal oxide film 231f is preferably a highly purified film in which impurities containing hydrogen elements are reduced as much as possible. It is particularly preferable to use a metal oxide film having crystallinity as the metal oxide film 231f.

In forming the metal oxide film 231f, an oxygen gas is preferably used. In the case of using an oxygen gas at the time of forming the metal oxide film 231f, oxygen can be suitably supplied into the insulating layer 210. For example, in the case where an oxide or an oxynitride is used for the insulating layer 210a, oxygen can be favorably supplied to the insulating layer 210a.

By the supply of oxygen to the insulating layer 210a, oxygen is supplied to the semiconductor layer 231 in a later step, so that oxygen vacancies (Vo) and VoH in the semiconductor layer 231 can be reduced.

In depositing the metal oxide film 231f, an inert gas (e.g., a helium gas, an argon gas, or a xenon gas) may be mixed in addition to the oxygen gas. Note that as the oxygen flow rate ratio or the oxygen partial pressure at the time of depositing the metal oxide film 231f is higher, the crystallinity of the metal oxide film 231f can be higher and a transistor with higher reliability can be obtained. By contrast, when the oxygen flow rate ratio or the oxygen partial pressure is lower, the crystallinity of the metal oxide film 231f is lower and a transistor with a high on-state current can be obtained.

In depositing the metal oxide film 231f, as the substrate temperature becomes higher, a denser metal oxide film having higher crystallinity can be formed. On the other hand, as the substrate temperature becomes lower, a metal oxide film 231f having lower crystallinity and higher electric conductivity can be formed.

The metal oxide film 231f is formed under the deposition conditions where a substrate temperature is higher than or equal to room temperature and lower than or equal to 250° C., preferably higher than or equal to room temperature and lower than or equal to 200° C., further preferably higher than or equal to room temperature and lower than or equal to 140° C. For example, when the substrate temperature is higher than or equal to room temperature and lower than 140° C., high productivity is achieved, which is preferable. Furthermore, when the metal oxide film 231f is deposited with the substrate temperature set at room temperature or without heating the substrate, the crystallinity can be made low.

It is preferable to perform at least one of treatment for desorbing water, hydrogen, an organic substance, and the like adsorbed onto the surface of the insulating layer 210 and treatment for supplying oxygen into the insulating layer 210 before the deposition of the metal oxide film 231f. For example, heat treatment can be performed at a temperature higher than or equal to 70° C. and lower than or equal to 200° C. in a reduced-pressure atmosphere. Alternatively, plasma treatment may be performed in an oxygen-containing atmosphere. Alternatively, oxygen may be supplied to the insulating layer 210 by plasma treatment in an atmosphere containing an oxidizing gas such as dinitrogen monoxide (N₂O). Performing plasma treatment containing a dinitrogen monoxide gas can supply oxygen to the insulating layer 210 while suitably removing an organic substance on the surface of the insulating layer 210. It is preferable that the metal oxide film 231f be deposited successively after such treatment, without exposure of the surface of the insulating layer 210 to the air.

Note that in the case where the semiconductor layer 231 has a stacked-layer structure, an upper metal oxide film is preferably deposited successively after deposition of a lower metal oxide film without exposure of the surface of the lower metal oxide layer to the air.

Next, the metal oxide film 231f is processed into an island shape to form the semiconductor layer 231 (FIG. 24C).

For the formation of the semiconductor layer 231, one or both of a wet etching method and a dry etching method can be used. For example, for the formation of the semiconductor layer 231, a wet etching method can be suitably used. At this time, part of the conductive layer 222b in the region that does not overlap with the semiconductor layer 231 is etched and thinned in some cases. Similarly, part of the insulating layer 210 in a region overlapping with neither the semiconductor layer 231 nor the conductive layer 222b is etched to have a small thickness in some cases. For example, in some cases, the insulating layer 210b of the insulating layer 210 is removed by etching and a surface of the insulating layer 210a is exposed. Note that when a material having high selectivity is used for the insulating layer 210b, a reduction in the thickness of the insulating layer 210b can be inhibited in etching of the metal oxide film 231f.

It is preferable that heat treatment be performed after the metal oxide film 231f is deposited or the metal oxide film 231f is processed into the semiconductor layer 231. By the heat treatment, hydrogen or water contained in the metal oxide film 231f or the semiconductor layer 231 or adsorbed on the surface of the metal oxide film 231f or the semiconductor layer 231 can be removed. Furthermore, the film quality of the metal oxide film 231f or the semiconductor layer 231 is improved (e.g., the number of defects is reduced or crystallinity is increased) by the heat treatment in some cases.

Furthermore, oxygen can be supplied from the insulating layer 210a to the metal oxide film 231f or the semiconductor layer 231 by heat treatment. In this case, it is further preferable that the heat treatment be performed before the metal oxide film 231f is processed into the semiconductor layer 231. The above description can be referred to for the heat treatment; thus, the detailed description thereof is omitted.

Note that the heat treatment is not necessarily performed. The heat treatment is not performed in this step, and instead heat treatment performed in a later step may also serve as the heat treatment in this step. In some cases, treatment at a high temperature (e.g., deposition step) or the like in a later step can serve as the heat treatment in this step.

### [Formation of Insulating Layer 225]

Next, the insulating layer 225 is formed to cover the semiconductor layer 231, the conductive layer 222b, and the insulating layer 210. For formation of the insulating layer 225, a PECVD method can be favorably used.

In the case where an oxide semiconductor is used for the semiconductor layer 231, the insulating layer 225 preferably functions as a barrier film that inhibits diffusion of oxygen. The insulating layer 225 having a function of inhibiting diffusion of oxygen inhibits diffusion of oxygen into the conductive layer 223 from above the insulating layer 225 and thus can inhibit oxidation of the conductive layer 223. Consequently, the transistor can have favorable electrical characteristics and high reliability.

When the temperature at the time of forming the insulating layer 225 functioning as a gate insulating layer is increased, an insulating layer with few defects can be formed. However, when the temperature at the time of forming the insulating layer 225 is high, oxygen is released from the semiconductor layer 231, and oxygen vacancies (Vo) and VoH in the semiconductor layer 231 are increased in some cases. The substrate temperature at the time of forming the insulating layer 225 is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating layer 225 is within the above range, release of oxygen from the semiconductor layer 231 can be inhibited while the defects in the insulating layer 225 can be reduced. Consequently, the transistor can have favorable electrical characteristics and high reliability.

Before the formation of the insulating layer 225, a surface of the semiconductor layer 231 may be subjected to plasma treatment. By the plasma treatment, an impurity adsorbed onto the surface of the semiconductor layer 231, such as water, can be reduced. Thus, impurities at the interface between the semiconductor layer 231 and the insulating layer 225 can be reduced and a highly reliable transistor can be obtained. The plasma treatment is particularly suitable in the case where the surface of the semiconductor layer 231 is exposed to the air after the formation of the semiconductor layer 231 and before the formation of the insulating layer 225. For example, plasma treatment can be performed in an atmosphere containing oxygen, ozone, nitrogen, dinitrogen monoxide, argon, or the like. The plasma treatment and the deposition of the insulating layer 225 are preferably performed successively without exposure to the air.

### [Formation of Conductive Layer 223]

Next, a conductive film to be the conductive layer 223 is formed over the insulating layer 225. For the formation of the conductive film, a sputtering method can be suitably used, for example. After a resist mask is formed over the conductive film by a photolithography process, the conductive film is processed, so that the island-shaped conductive layer 223 functioning as a gate electrode is formed (FIG. 24D).

Through the above process, the transistor 205R can be manufactured. The transistor 205G and the transistor 205B can be formed over the same substrate through the same process as the transistor 205R.

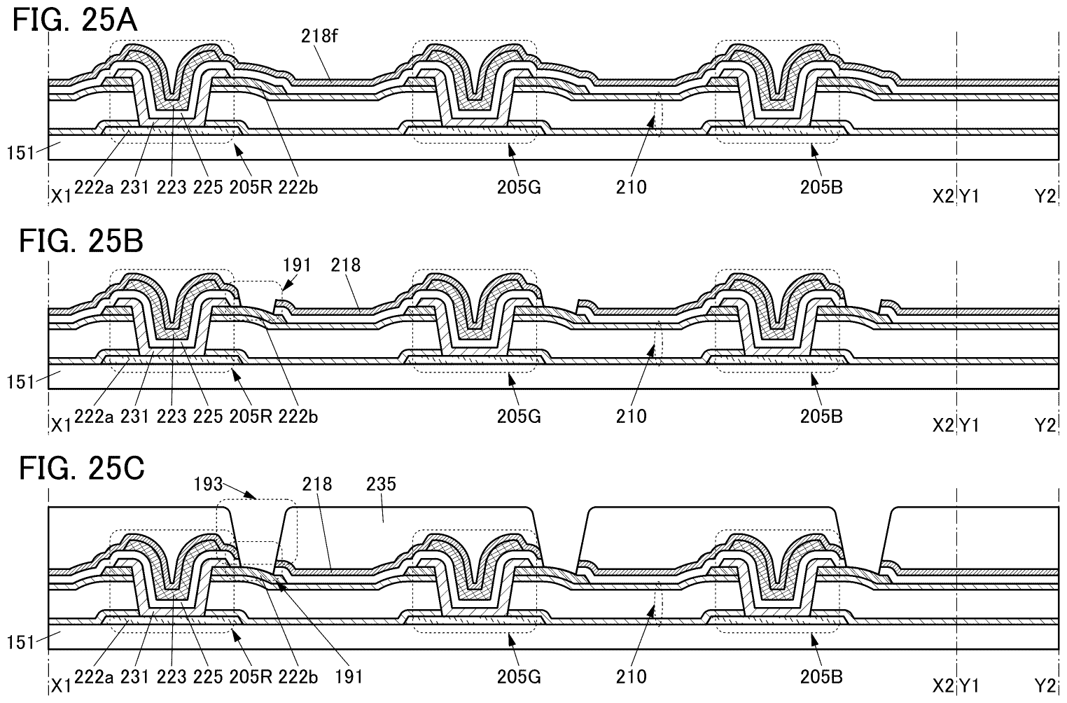

The following description will be made with reference to FIG. 25A to FIG. 37B. FIG. 25A to FIG. 37B illustrate the transistor 205R, the transistor 205G, and the transistor 205B. A cross-sectional view along the dashed-dotted line X1-X2 and a cross-sectional view along the dashed-dotted line Y1-Y2, which are illustrated in FIG. 19, are arranged side by side.

### [Formation of Insulating Layer 218, Insulating Layer 235, and Insulating Layer 239]

Next, an insulating film 218f to be the insulating layer 218 is formed to cover the transistor 205R, the transistor 205G, and the transistor 205B (FIG. 25A).

Increasing the temperature at the time of forming the insulating film 218f enhances a property of blocking impurities (e.g., water and hydrogen). However, when the temperature at the time of forming the insulating film 218f is high, oxygen is released from the semiconductor layer 231, and the oxygen vacancies (Vo) and VoH in the semiconductor layer 231 are increased in some cases. The substrate temperature at the time of forming the insulating film 218f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 218f is in the above range, release of oxygen from the semiconductor layer 231 can be inhibited while the blocking property of the insulating layer 218 can be enhanced. Consequently, the transistor can have favorable electrical characteristics and high reliability.

Heat treatment may be performed after the formation of the insulating film 218f. By the heat treatment, water or hydrogen can be released from the surface and inside of the insulating film 218f. The above description can be referred to for the heat treatment; thus, the detailed description thereof is omitted.

Note that the heat treatment is not necessarily performed. The heat treatment may be omitted in this step, and instead heat treatment performed in a later step may also serve as the heat treatment in this step. In the case where treatment at a high temperature (e.g., deposition step) is performed in a later step, such treatment can serve as the heat treatment in this step in some cases.

Next, parts of the insulating layer 225 and the insulating film 218f are etched to form the opening 191 (FIG. 25B). The opening 191 is provided in a region overlapping with the conductive layer 222b included in the transistor 205R, a region overlapping with the conductive layer 222b included in the transistor 205G, and a region overlapping with the conductive layer 222b included in the transistor 205B. The conductive layer 222b is exposed in the opening 191.

Next, the insulating layer 235 including the opening 193 is formed over the insulating layer 218 (FIG. 25C). The opening 193 is provided in a region overlapping with the conductive layer 222b included in the transistor 205R, a region overlapping with the conductive layer 222b included in the transistor 205G, and a region overlapping with the conductive layer 222b included in the transistor 205B.

For example, when a photosensitive organic material to be the insulating layer 235 is used for the insulating layer, the insulating layer 235 can be formed in the following manner: a composition containing an organic material is applied by a spin coating method, and then the composition is subjected to selective light exposure and development. In the case of using a photosensitive organic material, a positive-type photosensitive resin or negative-type photosensitive resin may be used. The light used for the light exposure preferably includes the i-line. The light used for the light exposure may include at least one of the g-line and the h-line. When the amount of light exposure is adjusted, the width of the opening can be controlled. As another formation method, one or more of a sputtering method, an evaporation method, a droplet discharging method (an inkjet method), a screen printing method, and an offset printing method may be used.

After the insulating layer 235 is formed, heat treatment is preferably performed. In the case where an organic material is used for the insulating layer 235, the heat treatment can cure the organic material.

The temperature of the heat treatment is preferably lower than the heat resistant temperature of the organic material. For example, the temperature of the heat treatment is preferably higher than or equal to 150° C. and lower than or equal to 350° C., further preferably higher than or equal to 180° C. and lower than or equal to 300° C., still further preferably higher than or equal to 200° C. and lower than or equal to 270° C., yet still further preferably higher than or equal to 200° C. and lower than or equal to 250° C., yet still further preferably higher than or equal to 220° C. and lower than or equal to 250° C.

The heat treatment can be performed in an atmosphere containing a noble gas or nitrogen. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment.

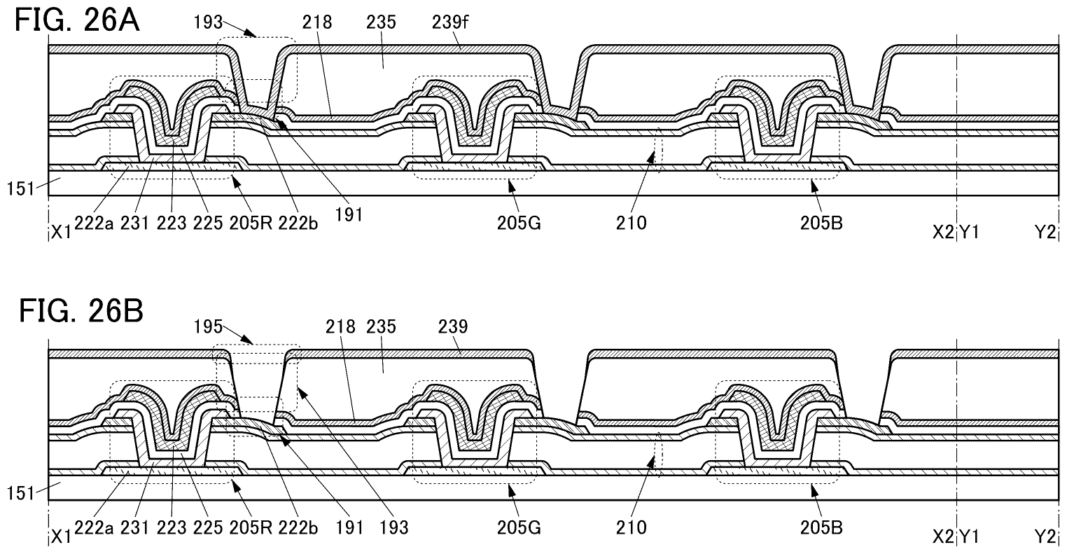

Next, an insulating film 239f to be the insulating layer 239 is formed to cover the insulating layer 235 (FIG. 26A). The insulating layer 239 can function as an etching protective film when the layer 113, the mask layer 118, and the mask layer 119 are formed.

Increasing the temperature at the time of forming the insulating film 239f allows the insulating layer 239 to have high etching endurance. However, when the temperature at the time of forming the insulating film 239f is high, oxygen is released from the semiconductor layer 231, and the oxygen vacancies (Vo) and VoH in the semiconductor layer 231 are increased in some cases. The substrate temperature at the time of forming the insulating film 239f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 239f is in the above range, release of oxygen from the semiconductor layer 231 can be inhibited while the etching resistance of the insulating layer 239 is enhanced. Consequently, the transistor can have favorable electrical characteristics and high reliability.

Then, the insulating film 239f is processed to form the insulating layer 239 including the opening 195 (FIG. 26B). For the processing of the insulating film 239f, one or both of a wet etching method and a dry etching method are used, and the opening 195 is formed in a region overlapping with the conductive layer 222b.

### [Formation of Pixel Electrode 111R, Pixel Electrode 111G, Pixel Electrode 111B, and Conductive Layer 123]

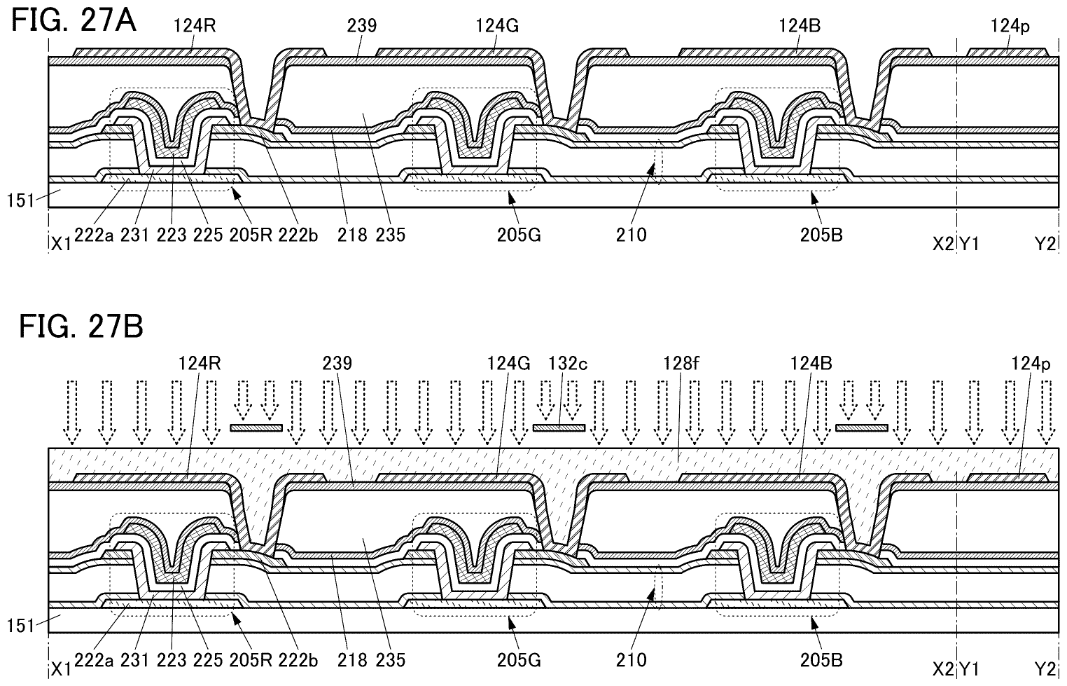

Next, a conductive film to be the conductive layer 124R, the conductive layer 124G, the conductive layer 124B, and the conductive layer 124p is formed, and the conductive film is processed to form the conductive layer 124R, the conductive layer 124G, the conductive layer 124B, and the conductive layer 124p (FIG. 27A). For the processing of the conductive film, one or both of a wet etching method and a dry etching method are used. At the time of processing the conductive film, part of the insulating layer 239 is removed in some cases. For example, the thickness of the insulating layer 239 in a region overlapping with none of the conductive layer 124R, the conductive layer 124G, and the conductive layer 124B may be smaller than the thickness of the insulating layer 239 in a region overlapping with any of the conductive layer 124R, the conductive layer 124G, and the conductive layer 124B.

Next, a film 128f to be the layer 128 is formed to cover the insulating layer 239, the conductive layer 124R, the conductive layer 124G, the conductive layer 124B, and the conductive layer 124p (FIG. 27B).

In the case where a photosensitive organic material is used for the insulating film 128f, the insulating layer 128 can be formed in the following manner: a composition containing an organic material is applied by a spin coating method, and then the composition is subjected to selective light exposure and development. In the case where the photosensitive organic material is used, a positive photosensitive resin or a negative photosensitive resin may be used. The light used for the light exposure preferably includes the i-line. The light used for the light exposure may include at least one of the g-line and the h-line. By adjusting the amount of light exposure, the width of the opening can be controlled. As another formation method, one or more of a sputtering method, an evaporation method, a droplet discharging method (an inkjet method), a screen printing method, and an offset printing method may be used.

FIG. 27B schematically illustrates a state in which a photosensitive organic material is used for the film 128f and a region not overlapping with the conductive layer 222b is exposed to light. In FIG. 27B, light is indicated by arrows; a region where the layer 128 is not formed is exposed to light, and a region where the layer 128 is formed is shielded from light by a mask 132c. At this time, the shape of the layer 128 can be controlled by adjusting the amount of light exposure.

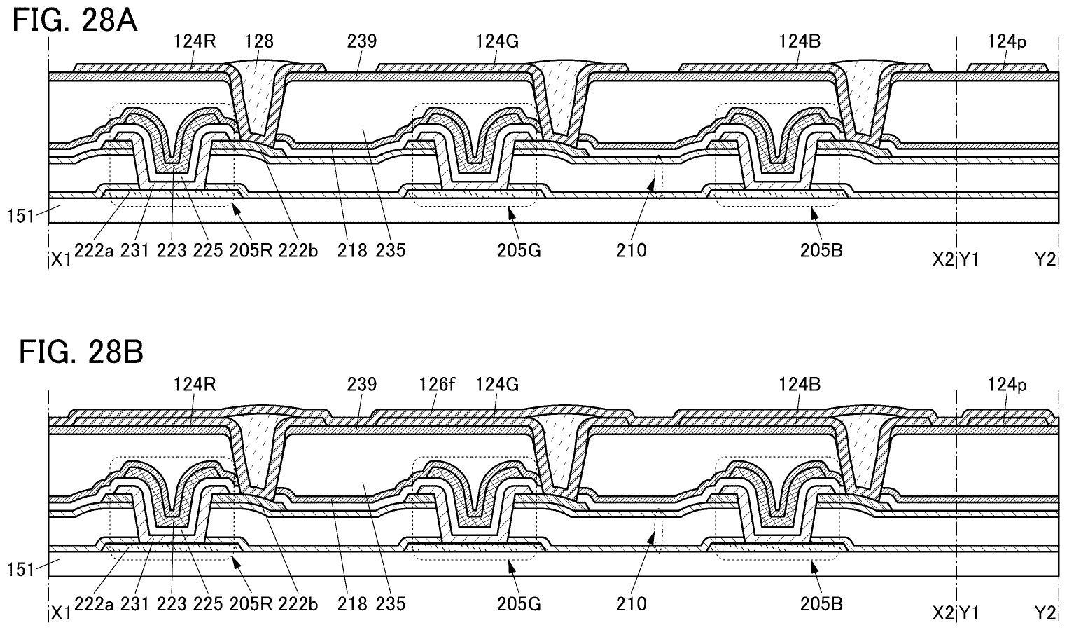

Next, development is performed to remove a region of the film 128f exposed to light, whereby the layer 128 is formed (FIG. 28A).

After the layer 128 is formed, heat treatment is preferably performed. The temperature of the heat treatment is preferably lower than the heat resistant temperature of the organic material. For example, the temperature of the heat treatment is preferably higher than or equal to 150° C. and lower than or equal to 350° C., further preferably higher than or equal to 180° C. and lower than or equal to 300° C., still further preferably higher than or equal to 200° C. and lower than or equal to 270° C., yet still further preferably higher than or equal to 200° C. and lower than or equal to 250° C., yet still further preferably higher than or equal to 220° C. and lower than or equal to 250° C. The heat treatment can be performed in an atmosphere containing a noble gas or nitrogen. Alternatively, heating may be performed in a dry air atmosphere. It is preferable that the atmosphere of the above heat treatment contain hydrogen, water, or the like as little as possible. An electric furnace, an RTA apparatus, or the like can be used for the heat treatment.

Next, a conductive film 126f to be the conductive layer 126R, the conductive layer 126G, the conductive layer 126B, and the conductive layer 126p is formed to cover the insulating layer 239, the conductive layer 124R, the conductive layer 124G, the conductive layer 124B, the conductive layer 124p, and the layer 128 (FIG. 28B).

Here, the conductive film 126f is provided over the insulating layer 239, the conductive layer 124R, the conductive layer 124G, the conductive layer 124B, the conductive layer 124p, and the layer 128. In the case where adhesion between the conductive film 126f and these films is low, film separation might occur. As a material used for the conductive film 126f, it is preferable to use a material having high adhesion to a formation surface of the conductive film 126f. For example, an alloy of silver, palladium, and copper (APC) has low adhesion with an insulating layer containing an inorganic material and film separation might occur when APC is provided over the insulating layer. In view of the above, in the case where an inorganic material is used for the insulating layer 239, a material that is highly adhesive to the insulating layer 239 is preferably used for the side of the conductive film 126f which is in contact with the insulating layer 239. For example, a stacked-layer structure of an In—Si—Sn oxide (ITSO), an alloy of silver, palladium, and copper (APC) over the In—Si—Sn oxide (ITSO) can be suitably used for the conductive film 126f. When a layer of the conductive film 126f which is in contact with the insulating layer 239 is an In—Si—Sn oxide (ITSO), film separation of the conductive film 126f can be inhibited even when an inorganic material is used for the insulating layer 239.

Note that a structure in which the insulating layer 239 is not provided and the conductive film 126f is provided over the insulating layer 235, the conductive layer 124R, the conductive layer 124G, the conductive layer 124B, the conductive layer 124p, and the layer 128 may be employed. In the case where an organic material is used for the insulating layer 235, a single-layer structure of silver, palladium, and copper (APC) can be used as the conductive film 126f.

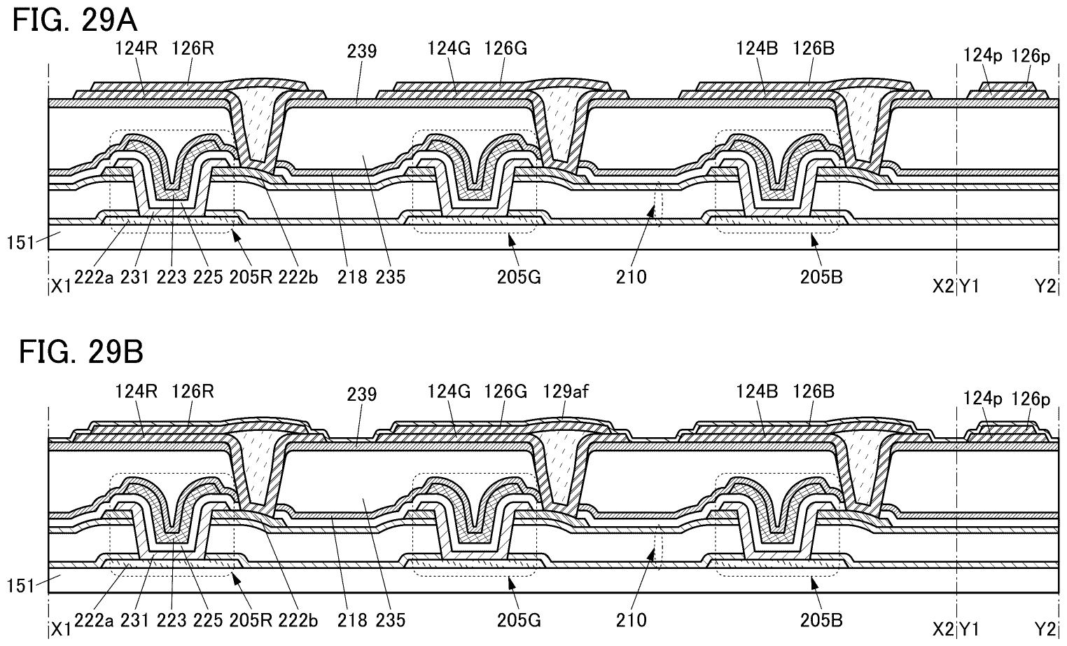

Next, the conductive film 126f is processed, whereby the conductive layer 126R, the conductive layer 126G, the conductive layer 126B, and the conductive layer 126p are formed (FIG. 29A). For processing of the conductive film 126f, one or both of a wet etching method and a dry etching method are used.

Next, the conductive layer 129R, the conductive layer 129G, the conductive layer 129B, and the conductive layer 129p are formed. Here, a manufacturing method in which the conductive layer 129R, the conductive layer 129G, and the conductive layer 129B each have a stacked-layer structure and the conductive layer 129p has a single-layer structure is described. Note that one embodiment of the present invention is not limited thereto. The conductive layer 129R, the conductive layer 129G, and the conductive layer 129B may each have a single-layer structure or a stacked-layer structure. The conductive layer 129p may have a single-layer structure or a stacked-layer structure.

A conductive film 129af to be parts of the conductive layer 129R, the conductive layer 129G, and the conductive layer 129B is formed to cover the insulating layer 239, the conductive layer 124R, the conductive layer 124G, the conductive layer 124B, the conductive layer 124p, the conductive layer 126R, the conductive layer 126G, the conductive layer 126B, and the conductive layer 126p (FIG. 29B).

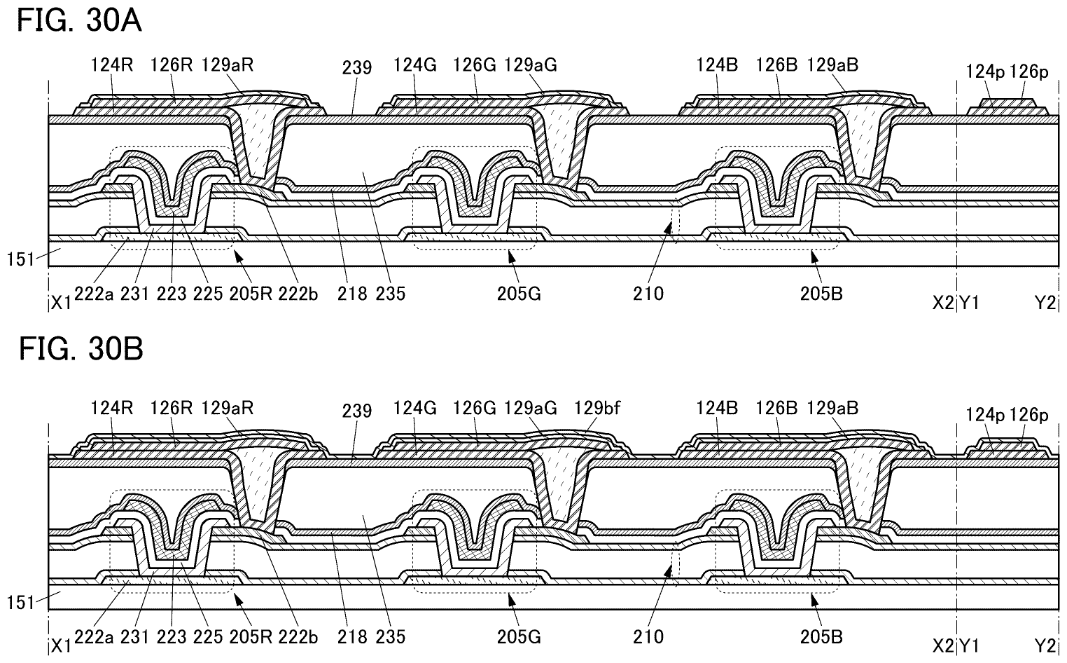

Next, the conductive film 129af is processed, whereby a conductive layer 129aR, a conductive layer 129aG, and a conductive layer 129aB are formed (FIG. 30A). For processing of the conductive film 129af, one or both of a wet etching method and a dry etching method are used.

Next, a conductive film 129bf to be parts of the conductive layer 129R, the conductive layer 129G, and the conductive layer 129B and the conductive layer 129p is formed to cover the insulating layer 239, the conductive layer 124R, the conductive layer 124G, the conductive layer 124B, the conductive layer 124p, the conductive layer 126R, the conductive layer 126G, the conductive layer 126B, the conductive layer 129aR, the conductive layer 129aG, the conductive layer 129aB, and the conductive layer 126p (FIG. 30B).

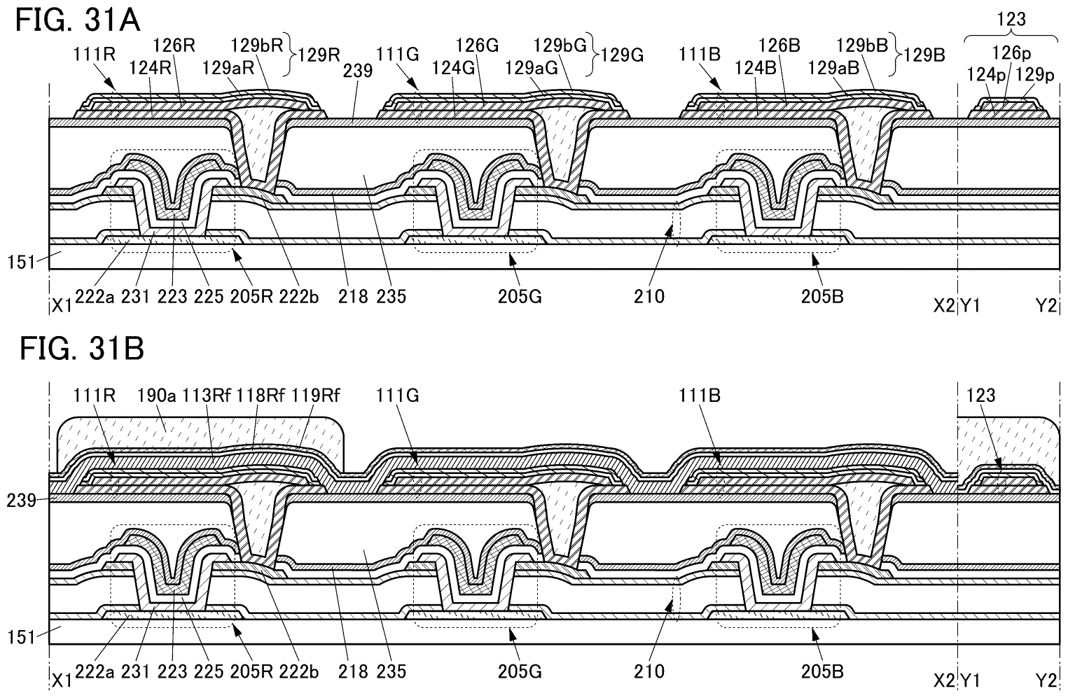

Next, the conductive film 129bf is processed, whereby a conductive layer 129bR, a conductive layer 129bG, a conductive layer 129bB, and the conductive layer 129p are formed (FIG. 31A). For processing of the conductive film 129bf, one or both of a wet etching method and a dry etching method are used.

Thus, the conductive layer 129R having a stacked-layer structure of the conductive layer 129aR and the conductive layer 129bR, the conductive layer 129G having a stacked-layer structure of the conductive layer 129aG and the conductive layer 129bG, and the conductive layer 129B having a stacked-layer structure of the conductive layer 129aB and the conductive layer 129bB can be formed. The thickness of the conductive layer 129p can be smaller than the thickness of each of the conductive layer 129R, the conductive layer 129G, and the conductive layer 129B. For formation of these conductive films, a sputtering method or a vacuum evaporation method can be used, for example.

Then, the pixel electrode is preferably subjected to hydrophobic treatment. The hydrophobic treatment can change the property of the surface of a processing target from hydrophilic to hydrophobic, or can improve the hydrophobic property of the surface of the processing target. The hydrophobic treatment for the pixel electrode can improve the adhesion between the pixel electrode and a film to be formed in a later step (here, a film 113Rf), thereby inhibiting film separation. Note that the hydrophobic treatment is not necessarily performed.

The hydrophobic treatment can be performed by fluorine modification of the pixel electrode, for example. The fluorine modification can be performed by treatment using a gas containing fluorine, heat treatment, plasma treatment in a gas atmosphere containing fluorine, or the like. A fluorine gas can be used as the gas containing fluorine, and for example, a fluorocarbon gas can be used. As the fluorocarbon gas, a low-molecular-weight carbon fluoride gas such as a carbon tetrafluoride (CF₄) gas, a C₄F₆ gas, a C₂F₆ gas, a C₄F₈ gas, or C₅F₈ can be used, for example. Alternatively, as the gas containing fluorine, an SF₆ gas, an NF₃ gas, a CHF₃ gas, or the like can be used, for example. Moreover, a helium gas, an argon gas, a hydrogen gas, or the like can be added to any of the above gases as appropriate.

Treatment using a silylating agent is performed on the surface of the pixel electrode after plasma treatment is performed in a gas atmosphere containing a Group 18 element such as argon, so that the surface of the pixel electrode can have a hydrophobic property. As the silylating agent, hexamethyldisilazane (HMDS), trimethylsilylimidazole (TMSI), or the like can be used. Alternatively, treatment using a silane coupling agent is performed on the surface of the pixel electrode after plasma treatment is performed in a gas atmosphere containing a Group 18 element such as argon, so that the surface of the pixel electrode can have a hydrophobic property.

Plasma treatment on the surface of the pixel electrode in a gas atmosphere containing a Group 18 element such as argon can apply damage to the surface of the pixel electrode. Accordingly, a methyl group included in the silylating agent such as HMDS is likely to bond to the surface of the pixel electrode. In addition, silane coupling by the silane coupling agent is likely to occur. As described above, treatment using a silylating agent or a silane coupling agent performed on the surface of the pixel electrode after plasma treatment in a gas atmosphere containing a Group 18 element such as argon enables the surface of the pixel electrode to have a hydrophobic property.

The treatment using a silylating agent, a silane coupling agent, or the like can be performed by application of the silylating agent, the silane coupling agent, or the like by a spin coating method, a dipping method, or the like. Alternatively, the treatment using a silylating agent, a silane coupling agent, or the like can be performed by forming a film containing the silylating agent, a film containing the silane coupling agent, or the like over the pixel electrode or the like by a gas phase method, for example. In a gas phase method, first, a material containing a silylating agent, a material containing a silane coupling agent, or the like is evaporated so that the silylating agent, the silane coupling agent, or the like is contained in an atmosphere. Next, a substrate where the pixel electrode and the like are formed is put in the atmosphere. Accordingly, a film containing the silylating agent, the silane coupling agent, or the like can be formed over the pixel electrode, so that the surface of the pixel electrode can have a hydrophobic property.

### [Formation of Layer 113R, Layer 113G, and Layer 113B]

Next, the layer 113R, the layer 113G, and the layer 113B are formed. Although a method in which the layer 113R, the layer 113G, and the layer 113B are formed in this order is described here, one embodiment of the present invention is not limited thereto. For example, the layer 113R, the layer 113G, and the layer 113B can be formed in descending order of heat resistance of the materials included in the layers. The layer formed first preferably has high heat resistance because the layer passes through steps of forming the other layers. When the layer that includes a material with low heat resistance is formed at last, damage during the process can be reduced.

The film 113Rf to be the layer 113R is formed over the pixel electrode 111.

Next, a mask film 118Rf to be the mask layer 118R and a mask film 119Rf to be a mask layer 119R are formed in this order over the film 113Rf and the conductive layer 123.

Next, a resist mask 190a is formed over the mask film 119Rf (FIG. 31B).

As illustrated in FIG. 31B, the film 113Rf is not formed over the conductive layer 123 in the cross-sectional view along the dashed-dotted line Y1-Y2. For example, by using an area mask, the film 113Rf can be formed only in a desired region. A light-emitting device can be manufactured through a relatively simple process, by employing a film formation step using an area mask and a processing step using a resist mask.

The upper temperature limit of a compound contained in the film 113Rf is preferably higher than or equal to 100° C. and lower than or equal to 180° C., further preferably higher than or equal to 120° C. and lower than or equal to 180° C., still further preferably higher than or equal to 140° C. and lower than or equal to 180° C. Accordingly, the reliability of the light-emitting device can be improved. In addition, the upper limit of the temperature that can be applied in the manufacturing process of the display apparatus can be increased. Thus, the range of choices of the materials and the formation method of the display apparatus can be widened, thereby improving the manufacturing yield and the reliability.

The film 113Rf can be formed by an evaporation method, specifically a vacuum evaporation method, for example. The film 113Rf may be formed by a method such as a transfer method, a printing method, an inkjet method, or a coating method.

Although this embodiment describes an example in which the mask film is formed with a two-layer structure of the mask film 118Rf and the mask film 119Rf, the mask film may have a single-layer structure of the mask film 118Rf or the mask film 119Rf or a stacked-layer structure of three or more layers.

Provision of the mask layer over the film 113Rf can reduce damage to the film 113Rf in the manufacturing process of the display apparatus, resulting in an improvement in reliability of the light-emitting device.

As the mask film 118Rf, a film highly resistant to the processing conditions of the film 113Rf, specifically, a film having high etching selectivity to the film 113Rf is used. As the mask film 119Rf, a film having high etching selectivity to the mask film 118Rf is used.

The mask film 118Rf and the mask film 119Rf are formed at a temperature lower than the upper temperature limit of the film 113Rf Each of the substrate temperatures at the time of forming the mask film 118Rf and the mask film 119Rf is preferably lower than or equal to 200° C., further preferably lower than or equal to 150° C., still further preferably lower than or equal to 120° C., yet still further preferably lower than or equal to 100° C., yet still further preferably lower than or equal to 80° C.

Examples of indicators of the upper temperature limit include the glass transition point, the softening point, the melting point, the thermal decomposition temperature, and the 5% weight loss temperature. The upper temperature limits of the layer 113R, the layer 113G, and the layer 113B can each be any of the above temperatures that are indicators of the upper temperature limit, preferably the lowest one among the temperatures.

As described above, a material with high heat resistance is used for the light-emitting device of the display apparatus of one embodiment of the present invention. Thus, the substrate temperature in formation of the mask film can be higher than or equal to 100° C., higher than or equal to 120° C., or higher than or equal to 140° C. For example, an inorganic insulating film formed at a higher temperature can be a film that is denser and has a higher barrier property. Thus, forming the mask film at such a temperature can further reduce damage to the film 113Rf and improve the reliability of the light-emitting device.

As each of the mask film 118Rf and the mask film 119Rf, a film that can be removed by a wet etching method is preferably used. The use of a wet etching method can reduce damage to the film 113Rf in processing of the mask film 118Rf and the mask film 119Rf as compared with the case of using a dry etching method.

The mask film 118Rf and the mask film 119Rf can be formed by a sputtering method, an ALD method (a thermal ALD method or a PEALD method), a CVD method, or a vacuum evaporation method, for example. Alternatively, the aforementioned wet film formation method may be used for the formation.

The mask film 118Rf, which is formed over and in contact with the film 113Rf, is preferably formed by a formation method that causes less damage to the film 113Rf than a formation method of the mask film 119Rf. For example, the mask film 118Rf is preferably formed by an ALD method or a vacuum evaporation method rather than a sputtering method.

As each of the mask film 118Rf and the mask film 119Rf, it is possible to use one or more of a metal film, an alloy film, a metal oxide film, a semiconductor film, an organic insulating film, and an inorganic insulating film, for example.

For each of the mask film 118Rf and the mask film 119Rf, it is possible to use a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials, for example. It is particularly preferable to use a low-melting-point material such as aluminum or silver. A metal material capable of blocking ultraviolet rays is preferably used for one or both of the mask film 118Rf and the mask film 119Rf, in which case the film 113Rf can be inhibited from being irradiated with ultraviolet rays and deterioration of the film 113Rf can be inhibited.

A metal film or an alloy film is preferably used as one or both of the mask film 118Rf and the mask film 119Rf, in which case the film 113Rf can be inhibited from being damaged by plasma and deterioration of the film 113Rf can be inhibited. Specifically, the film 113Rf can be inhibited from being damaged by plasma in a step using a dry etching method, a step performing ashing, or the like. It is particularly preferable to use a metal film such as a tungsten film or an alloy film as the mask film 119Rf.

For each of the mask film 118Rf and the mask film 119Rf, it is possible to use a metal oxide such as In—Ga—Zn oxide, indium oxide, In—Zn oxide, In—Sn oxide, indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or indium tin oxide containing silicon.

In addition, in place of gallium described above, an element M (M is one or more selected from of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used. In particular, M is preferably one or more kinds selected from gallium, aluminum, and yttrium.

As the mask film, a film containing a material having a light-blocking property with respect to light, particularly ultraviolet rays, can be used. For example, a film having a reflecting property with respect to ultraviolet rays or a film absorbing ultraviolet rays can be used. Although a variety of materials, such as a metal having a light-blocking property with respect to ultraviolet rays, an insulator, a semiconductor, and a metalloid, can be used as the material having a light-blocking property, a film capable of being processed by etching is preferable, and a film having good processability is particularly preferable because part or the whole of the mask film is removed in a later step.

For example, a semiconductor material such as silicon or germanium can be used as a material with a high affinity for the semiconductor manufacturing process. Alternatively, an oxide or a nitride of the semiconductor material can be used. Alternatively, a non-metallic material such as carbon or a compound thereof can be used. Alternatively, a metal, such as titanium, tantalum, tungsten, chromium, or aluminum, or an alloy containing one or more of them can be given. Alternatively, an oxide containing the above-described metal, such as titanium oxide or chromium oxide, or a nitride such as titanium nitride, chromium nitride, or tantalum nitride can be used.

The use of a film containing a material having a light-blocking property with respect to ultraviolet rays can inhibit the EL layer from being irradiated with ultraviolet rays in a light exposure step or the like. The EL layer is inhibited from being damaged by ultraviolet rays, so that the reliability of the light-emitting device can be improved.

Note that the film containing a material having a light-blocking property with respect to ultraviolet rays can have the same effect even when used as a material of an insulating film 125f that is described later.

As each of the mask film 118Rf and the mask film 119Rf, any of a variety of inorganic insulating films that can be used as the protective layer 131 can be used. In particular, an oxide insulating film is preferable because its adhesion to the film 113Rf is higher than that of a nitride insulating film. For example, an inorganic insulating material such as aluminum oxide, hafnium oxide, or silicon oxide can be used for each of the mask film 118Rf and the mask film 119Rf. As each of the mask film 118Rf and the mask film 119Rf, an aluminum oxide film can be formed by an ALD method, for example. The use of an ALD method is preferable because damage to a base (in particular, the EL layer) can be reduced.

For example, an inorganic insulating film (e.g., an aluminum oxide film) formed by an ALD method can be used as the mask film 118Rf, and an inorganic film (e.g., an In—Ga—Zn oxide film, a silicon film, or a tungsten film) formed by a sputtering method can be used as the mask film 119Rf.

Note that the same inorganic insulating film can be used for both the mask film 118Rf and the insulating layer 125 that is formed later. For example, an aluminum oxide film formed by an ALD method can be used for both the mask film 118Rf and the insulating layer 125. Here, for the mask film 118Rf and the insulating layer 125, the same film formation condition may be used or different film formation conditions may be used. For example, when the mask film 118Rf is formed under conditions similar to those for the insulating layer 125, the mask film 118Rf can be an insulating layer having a high barrier property against at least one of water and oxygen. Meanwhile, the mask film 118Rf is a layer most or all of which is to be removed in a later step, and thus is preferably easily processed. Thus, the mask film 118Rf is preferably formed at a substrate temperature lower than that in formation of the insulating layer 125.

An organic material may be used for one or both of the mask film 118Rf and the mask film 119Rf. For example, as the organic material, a material that can be dissolved in a solvent chemically stable with respect to at least the uppermost film of the film 113Rf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed under a reduced-pressure atmosphere, in which case the solvent can be removed at a low temperature in a short time and thermal damage to the film 113Rf can be accordingly reduced.

For each of the mask film 118Rf and the mask film 119Rf, an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluororesin such as perfluoropolymer may be used.

For example, an organic film (e.g., a PVA film) formed by an evaporation method or the above wet film formation method can be used as the mask film 118Rf, and an inorganic film (e.g., a silicon nitride film) formed by a sputtering method can be used as the mask film 119Rf.

Note that in the display apparatus of one embodiment of the present invention, part of the mask film remains as the mask layer in some cases.

The resist mask 190a is provided at a position overlapping with the pixel electrode 111R. The resist mask 190a is preferably provided also at a position overlapping with the conductive layer 123. This can inhibit the conductive layer 123 from being damaged during the manufacturing process of the display apparatus. Note that the resist mask 190a is not necessarily provided over the conductive layer 123.

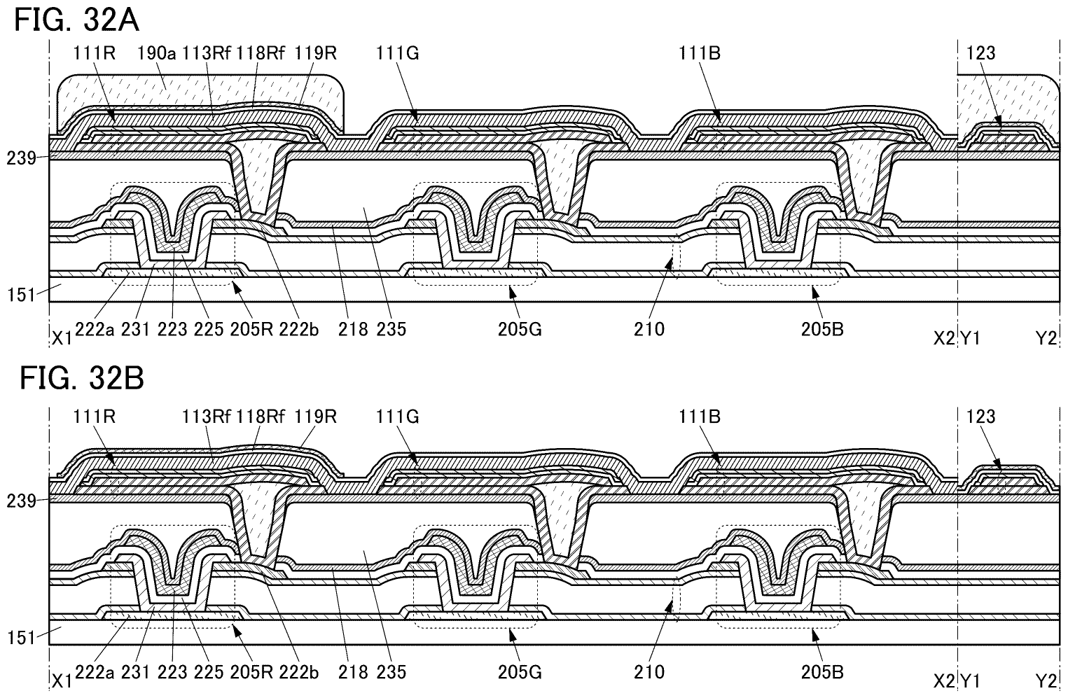

Next, part of the mask film 119Rf is removed with the use of the resist mask 190a as a mask to form the mask layer 119R (FIG. 32A). The mask layer 119R remains over the pixel electrode 111R and the conductive layer 123. After that, the resist mask 190a is removed (FIG. 32B). Next, part of the mask film 118Rf is removed using the mask layer 119R as a mask (also referred to as a hard mask) to form the mask layer 118R.

The mask film 118Rf and the mask film 119Rf can be processed by a wet etching method or a dry etching method. The mask film 118Rf and the mask film 119Rf are preferably processed by anisotropic etching.

The use of a wet etching method can reduce damage to the film 113Rf in processing of the mask film 118Rf and the mask film 119Rf as compared with the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a mixed solution containing two or more of these acids, for example.

Since the film 113Rf is not exposed in processing of the mask film 119Rf, the range of choices of the processing method is wider than that for processing of the mask film 118Rf. Specifically, deterioration of the film 113Rf can be further inhibited even when a gas containing oxygen is used as an etching gas for processing the mask film 119Rf.

In the case of using a dry etching method for processing the mask film 118Rf, deterioration of the film 113Rf can be inhibited by not using a gas containing oxygen as the etching gas. In the case of using a dry etching method, it is preferable to use a gas containing CF₄, C₄F₈, SF₆, CHF₃, Cl₂, H₂O, or BCl₃ or a noble gas such as He as the etching gas, for example.

For example, when an aluminum oxide film formed by an ALD method is used as the mask film 118Rf, the mask film 118Rf can be processed by a dry etching method using CHF₃ and He or CHF₃, He, and CH₄. In the case where an In—Ga—Zn oxide film formed by a sputtering method is used as the mask film 119Rf, the mask film 119Rf can be processed by a wet etching method using a diluted phosphoric acid. Alternatively, the mask film 119Rf may be processed by a dry etching method using CH₄ and Ar. Alternatively, the mask film 119Rf can be processed by a wet etching method using a diluted phosphoric acid. When a tungsten film formed by a sputtering method is used as the mask film 119Rf, the mask film 119Rf can be processed by a dry etching method using SF₆, CF₄, and O₂ or CF₄, Cl₂, and O₂.

The resist mask 190a can be removed by ashing using oxygen plasma, for example. Alternatively, an oxygen gas and any of CF₄, C₄F₈, SF₆, CHF₃, Cl₂, H₂O, BCl₃, and a noble gas such as He may be used. Alternatively, the resist mask 190a may be removed by wet etching. At this time, the mask film 119R is positioned on the outermost surface, and the film 113Rf is not exposed; thus, the film 113Rf can be inhibited from being damaged in the step of removing the resist mask 190a. In addition, the range of choices of the method for removing the resist mask 190a can be widened.

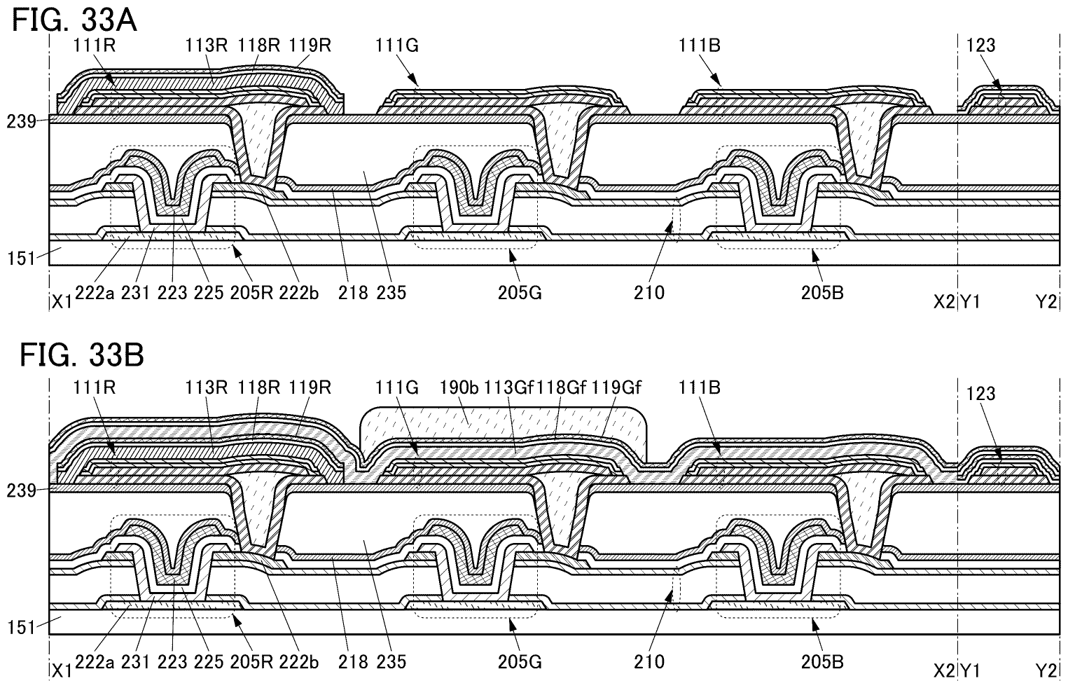

Next, the film 113Rf is processed to form the layer 113R. For example, part of the film 113Rf is removed using the mask layer 119R and the mask layer 118R as a hard mask, so that the layer 113R is formed (FIG. 33A).

Accordingly, as illustrated in FIG. 33A, the stacked-layer structure of the layer 113R, the mask layer 118R, and the mask layer 119R remains over the pixel electrode 111R. In addition, the pixel electrode 111G and the pixel electrode 111B are exposed.

Here, when the film 113Rf is processed, the surface of the pixel electrode 111G and the surface of the pixel electrode 111B are exposed to an etching gas or an etchant. On the other hand, the surface of the pixel electrode 111R is not exposed to an etching gas, an etchant, or the like. As described above, in the light-emitting device of the color formed first, the surface of the pixel electrode is not damaged by the etching process, whereby the interface between the pixel electrode and the EL layer can be kept favorable.

The film 113Rf is preferably processed by anisotropic etching. In particular, anisotropic dry etching is preferable. Alternatively, wet etching may be employed.

When the film 113Rf is processed by a dry etching method, the exposed surface is exposed to plasma. A metal film or an alloy film is preferably used for one or both of the mask layer 118R and the mask layer 119R, in which case a portion of the film 113Rf to be the layer 113R can be inhibited from being damaged by the plasma and thus deterioration of the layer 113R can be inhibited. In particular, a metal film such as a tungsten film or an alloy film is preferably used for the mask layer 119R.

In the case of using a dry etching method, deterioration of the film 113Rf can be inhibited by not using a gas containing oxygen as the etching gas.

A gas containing oxygen may be used as the etching gas. When the etching gas contains oxygen, the etching rate can be increased. Therefore, the etching can be performed under a low-power condition while an adequately high etching rate is maintained. Thus, damage to the film 113Rf can be reduced. Furthermore, a defect such as attachment of a reaction product generated at the etching can be inhibited.

In the case of using a dry etching method, it is preferable to use, as the etching gas, a gas containing one or more of H₂, CF₄, C₄F₈, SF₆, CHF₃, C₁₂, H₂O, BCl₃, and a noble gas such as He and Ar, for example. Alternatively, a gas containing oxygen and one or more of the above is preferably used as the etching gas. Alternatively, an oxygen gas may be used as the etching gas. Specifically, for example, a gas containing H₂ and Ar or a gas containing CF₄ and He can be used as the etching gas. As another example, a gas containing CF₄, He, and oxygen can be used as the etching gas. As another example, a gas containing H₂ and Ar and a gas containing oxygen can be used as the etching gas.

A dry etching apparatus including a high-density plasma source can be used as the dry etching apparatus. As the dry etching apparatus including a high-density plasma source, an inductively coupled plasma (ICP) etching apparatus can be used, for example. Alternatively, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes.

FIG. 33A illustrates an example where the end portion of the layer 113R is positioned outward from the end portion of the pixel electrode 111R. Such a structure enables a high aperture ratio of a pixel. The insulating layer 239 can function as an etching protective film at the time of forming the layer 113, the mask layer 118, and the mask layer 119. When the insulating layer 239 is provided over the insulating layer 235, part of the insulating layer 235 can be inhibited from being removed at the time of forming the layer 113, the mask layer 118, and the mask layer 119.

When the layer 113R covers the top surface and side surfaces of the pixel electrode 111R, the following steps can be performed without exposing the pixel electrode 111R. When the end portions of the pixel electrode 111R are exposed, corrosion might occur in the etching step or the like. A product generated by corrosion of the electrode 111R might be unstable; for example, the product might be dissolved in a solution in wet etching and might be diffused in an atmosphere in dry etching. The product dissolved in a solution or diffused in an atmosphere might be attached to a surface to be processed, the side surface of the layer 113B, and the like, which may adversely affect the characteristics of the light-emitting device or may form a leakage path between the plurality of light-emitting devices. In a region where the end portion of the pixel electrode 111R is exposed, the adhesion between contacting layers is reduced, which might facilitate film separation of the layer 113R or the pixel electrode 111R. Thus, when the layer 113R covers the top surface and side surfaces of the pixel electrode 111R, the yield and characteristics of the light-emitting device can be improved, for example.

When the layer 113R covers the top surface and the side surface of the pixel electrode 111R, the layer 113R is provided with a dummy region outside the light-emitting region (a region positioned between the pixel electrode 111R and the common electrode 115). Here, the end portion of the layer 113R is sometimes damaged at the time of processing the film 113Rf In addition, the end portion of the layer 113R is sometimes damaged by being exposed to plasma in a later step. The end portion of the layer 113R and the vicinity thereof are dummy regions and not used as light-emitting regions; thus, such regions are less likely to adversely affect the characteristics of the light-emitting device even when being damaged. Meanwhile, the light-emitting region of the layer 113R is covered with the mask layer, and thus is not exposed to plasma and plasma damage is sufficiently reduced. The mask layer is preferably provided to cover not only the top surface of a flat portion of the layer 113R overlapping with the top surface of the pixel electrode 111R, but also top surfaces of an inclined portion and a flat portion of the layer 113R that are positioned on the outer side of the top surface of the pixel electrode 111R. A portion of the layer 113R with reduced damage in the manufacturing process is used as the light-emitting region in this manner; thus, a light-emitting device having high emission efficiency and a long lifetime can be achieved.

In a region corresponding to the connection portion 140, a stacked-layer structure of the mask layer 118R and the mask layer 119R remains over the conductive layer 123.

As described above, in one embodiment of the present invention, the resist mask 190a is formed over the mask film 119Rf and part of the mask film 119Rf is removed using the resist mask 190a, so that the mask layer 119R is formed. After that, part of the film 113Rf is removed using the mask layer 119R as a hard mask, so that the layer 113R is formed. Thus, it can be said that the layer 113R is formed by processing the film 113Rf by a photolithography method. Note that part of the film 113Rf may be removed using the resist mask 190a. Then, the resist mask 190a may be removed.

Next, the pixel electrode is preferably subjected to hydrophobic treatment. In processing of the film 113Rf, the surface state of the pixel electrode changes to a hydrophilic state in some cases. The hydrophobic treatment for the pixel electrode can improve the adhesion between the pixel electrode and a film to be formed in a later step (here, the film 113Gf), thereby inhibiting film separation. Note that the hydrophobic treatment is not necessarily performed.

Next, the film 113Gf to be the layer 113G is formed over the pixel electrode 111G, the pixel electrode 111B, and the mask layer 119R.

Next, over the film 113Gf, a mask film 118Gf to be the mask layer 118G and a mask film 119Gf to be a mask layer 119G later are formed in this order, and then a resist mask 190b is formed (FIG. 33B). The resist mask 190b is provided at a position overlapping with the pixel electrode 111G.

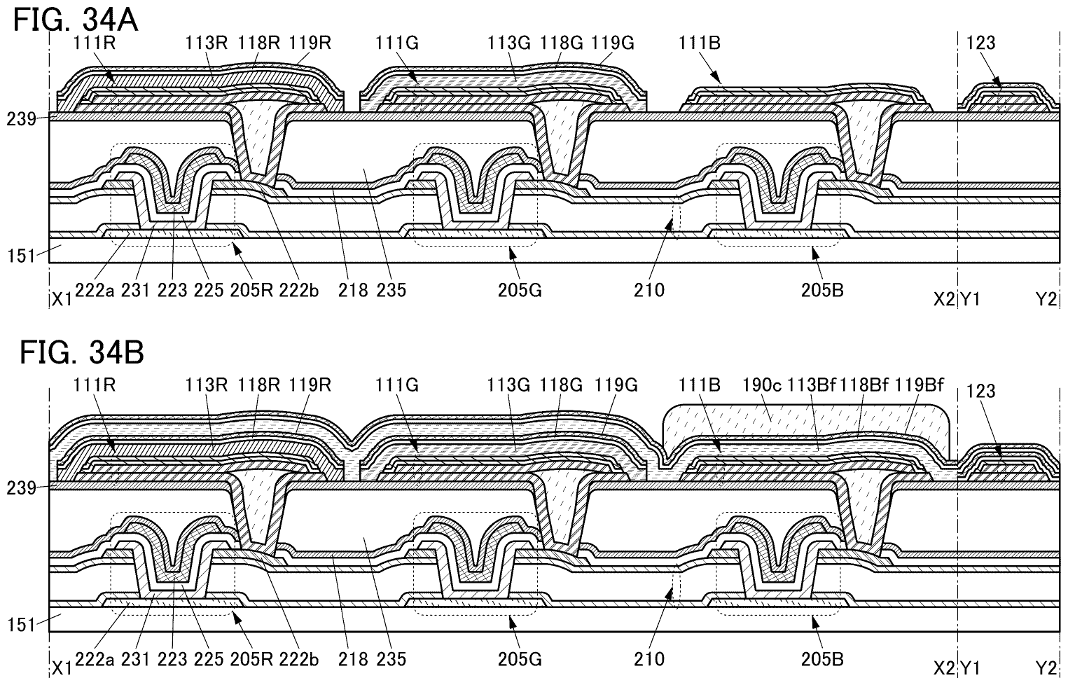

Next, part of the mask film 119Gf is removed with the use of the resist mask 190b, so that the mask layer 119G is formed. Next, part of the mask film 118Gf is removed using the mask layer 119G as a mask, so that the mask layer 118G is formed. Next, the film 113Gf is processed to form the layer 113G (FIG. 34A). Thus, a stacked-layer structure of the layer 113G, the mask layer 118G, and the mask layer 119G remains over the pixel electrode 111G. In addition, the mask layer 119R and the pixel electrode 111B are exposed. The description of the layer 113R can be referred to for the formation of the layer 113G; thus, the detailed description thereof is omitted.

Next, the pixel electrode is preferably subjected to hydrophobic treatment. The hydrophobic treatment for the pixel electrode can improve the adhesion between the pixel electrode and a film to be formed in a later step (here, a film 113Bf), thereby inhibiting film separation. Note that the hydrophobic treatment is not necessarily performed.

Next, the film 113Bf to be the layer 113B is formed over the pixel electrode 111B, the mask layer 119R, and the mask layer 119G.

Next, over the film 113Bf, a mask film 118Bf to be the mask layer 118B and a mask film 119Bf to be a mask layer 119B are formed in this order, and then a resist mask 190c is formed (FIG. 34B). The resist mask 190c is provided at a position overlapping with the pixel electrode 111B.

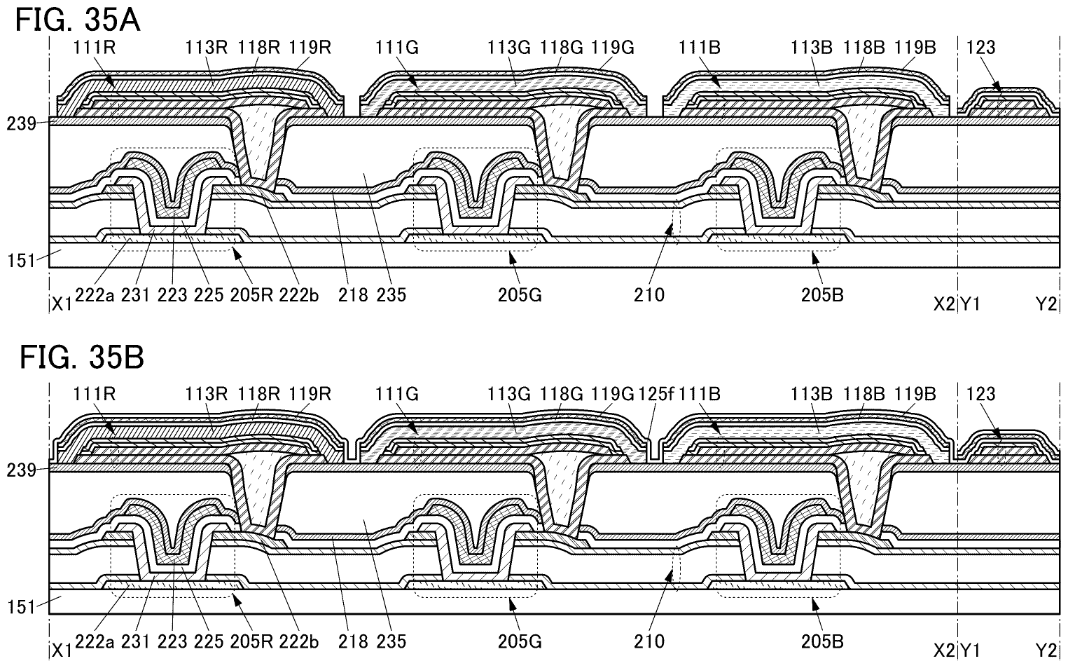

Next, part of the mask film 119Bf is removed with the use of the resist mask 190c as a mask, so that the mask layer 119B is formed. Next, part of the mask film 118Bf is removed using the mask layer 119B as a mask to form the mask layer 118B. Next, the film 113Bf is processed to form the layer 113B (FIG. 35A). Accordingly, a stacked-layer structure of the layer 113B, the mask layer 118B, and the mask layer 119B remains over the pixel electrode 111B. In addition, the mask layer 119R and the mask layer 119G are exposed. The description of the layer 113R can be referred to for the formation of the layer 113B; thus, the detailed description thereof is omitted.

Note that side surfaces of the layer 113R, the layer 113G, and the layer 113B are preferably perpendicular or substantially perpendicular to their formation surfaces. For example, the angle between the formation surfaces and these side surfaces is preferably greater than or equal to 600 and less than or equal to 90°.

As described above, the distance between adjacent two layers among the layer 113R, the layer 113G, and the layer 113B formed by a photolithography method can be shortened to less than or equal to 8 μm, less than or equal to 5 μm, less than or equal to 3 μm, less than or equal to 2 μm, or less than or equal to 1 μm. Here, the distance can be determined by, for example, the distance between facing end portions of adjacent two layers among the layer 113B, the layer 113G, and the layer 113R. When the distance between the island-shaped EL layers is shortened in this manner, a display apparatus with a high definition and a high aperture ratio can be provided.

Next, the mask layer 119B, the mask layer 119G, and the mask layer 119R may be removed. For example, in the case where the mask layer 119R, the mask layer 119G, and the mask layer 119B each contain the aforementioned material having a light-blocking property with respect to ultraviolet rays, the mask layers preferably remain without being removed, in which case the island-shaped EL layers can be protected from ultraviolet rays.

In the case where the mask layers are removed, a method similar to that for the step of processing the mask layers can be used. In particular, the use of a wet etching method can reduce damage to the layer 113R, the layer 113G, and the layer 113B at the time of removing the mask layers compared with the case of using a dry etching method.

The use of a metal film or an alloy film for the mask layer 119R, the mask layer 119G, and the mask layer 119B can reduce plasma damage to the EL layer. Thus, a dry etching method can be used in the process of manufacturing the light-emitting device.

The mask layer may be removed by being dissolved in a solvent such as water or alcohol. Examples of alcohol include ethyl alcohol, methyl alcohol, isopropyl alcohol (IPA), and glycerin.

After the mask layers are removed, drying treatment may be performed to remove water contained in the layer 113R, the layer 113G, and the layer 113B and water adsorbed onto the surfaces of the layer 113R, the layer 113G, and the layer 113B. For example, heat treatment in an inert gas atmosphere such as a nitrogen atmosphere or a reduced-pressure atmosphere can be performed. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. A reduced-pressure atmosphere is preferable because drying at a lower temperature is possible.

### [Formation of Insulating Layer 125 and Insulating Layer 127]

Next, the insulating film 125f to be the insulating layer 125 is formed to cover the insulating layer 239, the layer 113R, the layer 113G, the layer 113B, the mask layer 118R, the mask layer 118G, the mask layer 118B, the mask layer 119R, the mask layer 119G, the mask layer 119B, and the conductive layer 123 (FIG. 35B).

After that, an insulating film 127f to be the insulating layer 127 is formed in contact with the top surface of the insulating film 125f. Thus, the top surface of the insulating film 125f preferably has high adhesion to a resin composite (e.g., a photosensitive resin composite containing an acrylic resin) that is used for the insulating film 127f. To improve the adhesion, the top surface of the insulating film 125f is preferably made hydrophobic (or more hydrophobic) by surface treatment. For example, the treatment is preferably performed using a silylating agent such as hexamethyldisilazane (HMIDS). By making the top surface of the insulating film 125f hydrophobic in this manner, the insulating film 127f to be the insulating layer 127 can be formed with high adhesion. Note that the above-described hydrophobic treatment may be performed as the surface treatment.

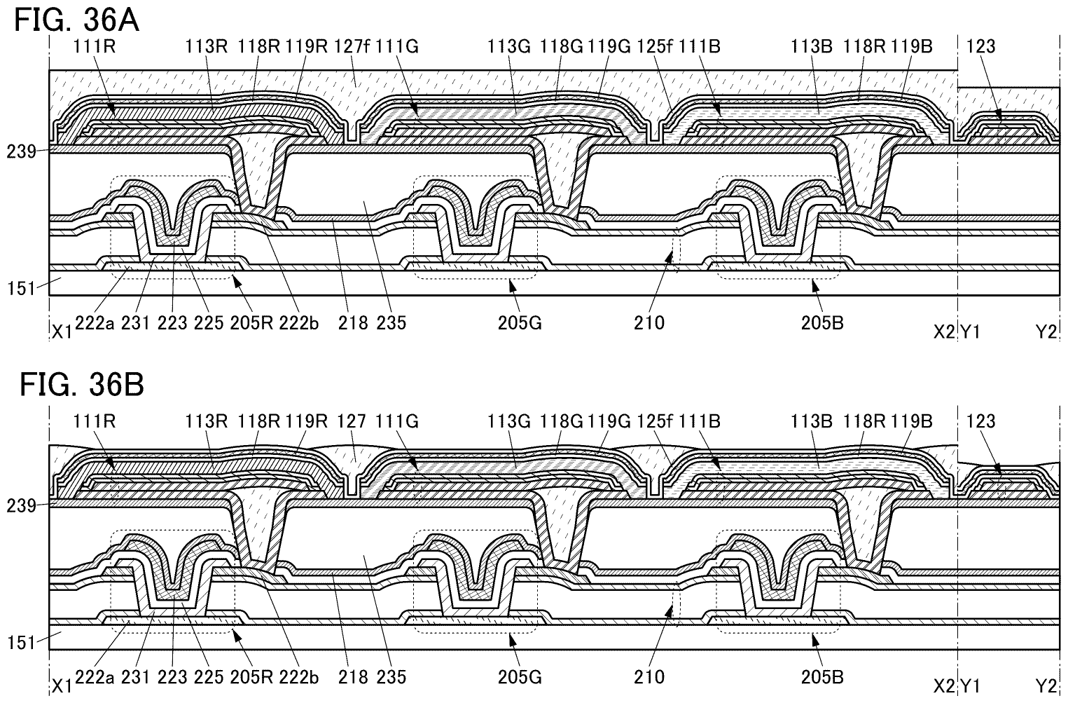

Then, the insulating film 127f to be the insulating layer 127 is formed over the insulating film 125f (FIG. 36A).

The insulating film 125f and the insulating film 127f are preferably formed by a formation method that causes less damage to the layer 113R, the layer 113G, and the layer 113B. In particular, the insulating film 125f, which is formed in contact with the side surfaces of the layer 113R, the layer 113G, and the layer 113B, is preferably formed by a formation method that causes less damage to the layer 113R, the layer 113G, and the layer 113B than the method of forming the insulating film 127f.

The insulating film 125f and the insulating film 127f are formed at a temperature lower than the upper temperature limits of the layer 113R, the layer 113G, and the layer 113B. When the insulating film 125f is formed at a high substrate temperature, the formed film, even with a small thickness, can have a low impurity concentration and a high barrier property against at least one of water and oxygen.

The insulating film 125f and the insulating film 127f are preferably formed at a substrate temperature higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As described above, a material with high heat resistance is used for the light-emitting device of the display apparatus of one embodiment of the present invention. Thus, the substrate temperature in formation of the insulating film 125f and the insulating film 127f can be higher than or equal to 100° C., higher than or equal to 120° C., or higher than or equal to 140° C. For example, an inorganic insulating film formed at a higher temperature can be a film that is denser and has a higher barrier property. Thus, forming the insulating film 125f at such a temperature can further reduce damage to the layer 113B, the layer 113G, and the layer 113R and improve the reliability of the light-emitting device.

As the insulating film 125f, an insulating film is preferably formed within the above substrate temperature range to have a thickness larger than or equal to 3 nm, larger than or equal to 5 nm, or larger than or equal to 10 nm and smaller than or equal to 200 nm, smaller than or equal to 150 nm, smaller than or equal to 100 nm, or smaller than or equal to 50 nm.

The insulating film 125f is preferably formed by an ALD method, for example. The use of an ALD method can reduce deposition damage to the formation surface of the insulating film 125f and improve the coverage with the insulating film 125f. As the insulating film 125f, an aluminum oxide film formed by an ALD method can be suitably used, for example.

Alternatively, the insulating film 125f may be formed by a sputtering method, a CVD method, or a PECVD method that provides a higher film formation speed than an ALD method. In this case, a highly reliable display apparatus can be manufactured with high productivity.

The insulating film 127f is preferably formed by the aforementioned wet film formation method. For example, the insulating film 127f is preferably formed by spin coating using a photosensitive resin, specifically, a photosensitive resin composite containing an acrylic resin.

Heat treatment (also referred to as pre-baking) is preferably performed after formation of the insulating film 127f. The heat treatment is performed at a temperature lower than the upper temperature limits of the layer 113R, the layer 113G, and the layer 113B. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, a solvent contained in the insulating film 127f can be removed.

Next, a region of the insulating film 127f is exposed to light. At this time, the shape of the insulating layer 127 can be controlled by adjusting the amount of light exposure. The insulating layer 127 is preferably processed to include a portion overlapping with the top surface of the pixel electrode 111.

Next, development is performed to remove a region of the insulating film 127f exposed to light, whereby the insulating layer 127 is formed (FIG. 36B). The insulating layer 127 is provided in a region between adjacent pixel electrodes 111 and a region surrounding the conductive layer 123. For example, in the case where an acrylic resin is used for the insulating film 127f, an alkaline solution is preferably used as a developer, and for example, an aqueous solution of tetramethyl ammonium hydroxide (TMAH) can be used.

Although an example in which a positive photosensitive resin is used for the insulating film 127f is described here, the present invention is not limited thereto. For example, a negative photosensitive resin may be used for the insulating film 127f.

After that, heat treatment (also referred to as post-baking) may be performed. The heat treatment can change the shape of the side surface of the insulating layer 127. Specifically, the taper angle of the insulating layer 127 can be small. The heat treatment is performed at a temperature lower than the upper temperature limit of the EL layers. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. A reduced-pressure atmosphere is preferable because drying at a lower temperature is possible. The heat treatment in this step is preferably performed at a higher substrate temperature than the heat treatment (pre-baking) after formation of the insulating film 127f. In this case, the adhesion between the insulating layer 127 and the insulating layer 125 and the corrosion resistance of the insulating layer 127 can be improved.

Note that the side surface of the insulating layer 127 might have a concave shape depending on the materials for the insulating layer 127, or the temperature, time, and atmosphere of the post-baking. For example, the insulating layer 127 is more likely to be changed in shape to have a concave shape as the temperature is higher or the time is longer in the post-baking conditions. In addition, as described above, in the case where light exposure is not performed on the insulating layer 127 after development, the shape of the insulating layer 127 is sometimes easily changed at the time of the post-baking.

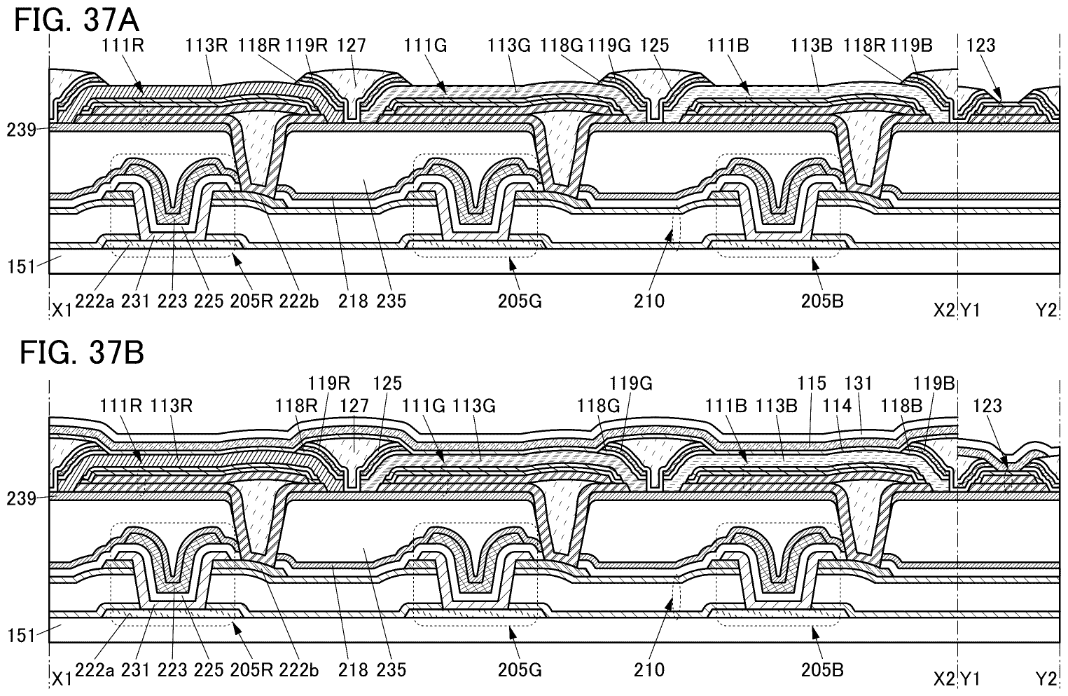

Next, parts of the insulating film 125f, the mask layer 119R, the mask layer 119G, the mask layer 119B, the mask layer 118R, the mask layer 118G, and the mask layer 118B are removed using the insulating layer 127 as a mask. Thus, the insulating layer 125 is formed and openings are formed in the mask layer 119R, the mask layer 119G, the mask layer 119B, the mask layer 118R, the mask layer 118G, and the mask layer 118B to expose parts of the top surfaces of the layer 113R, the layer 113G, the layer 113B, and the conductive layer 123 (FIG. 37A).

For the processing of the insulating film 125f, the mask layer 119R, the mask layer 119G, the mask layer 119B, the mask layer 118R, the mask layer 118G, and the mask layer 118B, one or both of a wet etching method and a dry etching method may be used. Using a wet etching method can reduce damage to the layer 113B, the layer 113G, and the layer 113R, as compared with the case of using a dry etching method. For example, for wet etching of an aluminum oxide film, it is preferable to use an aqueous solution of tetramethyl ammonium hydroxide (TMAH) that is an alkaline solution. For wet etching of an In—Ga—Zn oxide film, phosphoric acid or an etchant containing phosphoric acid is preferably used.

In the case of using a dry etching method, a chlorine-based gas is preferably used. As the chlorine-based gas, Cl₂, BCl₃, SiCl₄, CCl₄, or the like can be used alone or two or more of the gases can be mixed and used. Moreover, one or more of an oxygen gas, a hydrogen gas, a helium gas, an argon gas, and the like can be mixed with the chlorine-based gas. Moreover, an oxygen gas, a hydrogen gas, a helium gas, an argon gas, or the like or a mixture of two or more of the gases can be added to the chlorine-based gas.

As described above, provision of the insulating layer 127, the insulating layer 125, the mask layer 118R, the mask layer 118G, the mask layer 118B, the mask layer 119R, the mask layer 119G, and the mask layer 119B can inhibit the common layer 114 and the common electrode 115 between the light-emitting devices from having connection defects due to a disconnected portion and an increase in electric resistance due to a locally thinned portion. Thus, the display quality of the display apparatus of one embodiment of the present invention can be improved.

After parts of the layer 113B, the layer 113G, and the layer 113R are exposed, additional heat treatment may be performed. The heat treatment can remove water contained in the EL layer, water adsorbed onto the surface of the EL layer, and the like. In addition, the heat treatment changes the shape of the insulating layer 127 in some cases. Specifically, the insulating layer 127 may extend to cover at least one of end portions of the insulating layer 125, the mask layer 118R, the mask layer 118G, the mask layer 118B, the mask layer 119R, the mask layer 119G, and the mask layer 119B (see FIG. 16B). Furthermore, the insulating layer 127 may extend to cover at least one of the top surfaces of the layer 113R, the layer 113G, and the layer 113B (see FIG. 17A and FIG. 17B). For example, heat treatment in an inert gas atmosphere or a reduced-pressure atmosphere can be performed. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. A reduced-pressure atmosphere is preferable because dehydration at a lower temperature is possible. Note that the temperature range of the heat treatment is preferably determined as appropriate in consideration of the upper temperature limit of the EL layer. In consideration of the upper temperature limit of the EL layer, temperatures higher than or equal to 70° C. and lower than or equal to 120° C. are particularly preferable in the above temperature range.

Here, when the insulating layer 125 and the mask layer are collectively etched after the post-baking, the insulating layer 125 and the mask layer below the end portion of the insulating layer 127 are eliminated by side etching and accordingly a cavity is formed in some cases. The cavity causes unevenness in the formation surface of the common layer 114 and the common electrode 115, so that step disconnection is likely to occur in the common layer 114 and the common electrode 115. To avoid this, the etching treatment for the insulating layer 125 and etching treatment for the mask layer are preferably performed separately before and after the post-baking.

Next, the common layer 114, the common electrode 115, and the protective layer 131 are formed over the insulating layer 127, the layer 113R, the layer 113G, and the layer 113B (FIG. 37B).

The common layer 114 can be formed by a method such as an evaporation method (including a vacuum evaporation method), a transfer method, a printing method, an inkjet method, or a coating method.

The common electrode 115 can be formed by a sputtering method or a vacuum evaporation method, for example. Alternatively, a film formed by an evaporation method and a film formed by a sputtering method may be stacked.

Examples of methods for forming the protective layer 131 include a vacuum evaporation method, a sputtering method, a CVD method, and an ALD method.

Next, the substrate 120 is prepared, and the light-blocking layer 117 is formed over the substrate 120. Then, the substrate 120 and the light-blocking layer 117 are bonded to each other with the resin layer 122 over the protective layer 131, whereby the display apparatus can be manufactured (FIG. 19).

A film to be the layer 113R, the layer 113G, and the layer 113B is formed on an entire surface and then the film is processed to form the layer 113R with an island shape, the layer 113G with an island shape, and the layer 113B with an island shape; in this manner, an island-shaped layer with a uniform thickness can be formed. Consequently, a high-definition display apparatus or a high-aperture ratio display apparatus can be obtained. Furthermore, even when the definition or the aperture ratio is high and the distance between subpixels is extremely short, the layer 113R, the layer 113G, and the layer 113B can be inhibited from being in contact with one another between adjacent subpixels. Accordingly, generation of leakage current between subpixels can be inhibited. This can prevent unintended light emission due to crosstalk, so that a display apparatus with extremely high contrast can be obtained.

Provision of the insulating layer 127 having a tapered end portion between adjacent island-shaped EL layers can inhibit formation of step disconnection and prevent formation of a locally thinned portion in the common electrode 115 at the time of forming the common electrode 115. This can inhibit the common layer 114 and the common electrode 115 from having connection defects due to the disconnected portion and an increased electric resistance due to the locally thinned portion. Thus, the display apparatus of one embodiment of the present invention can have both a higher definition and higher display quality.

This embodiment can be combined with the other embodiments as appropriate.

### Embodiment 3

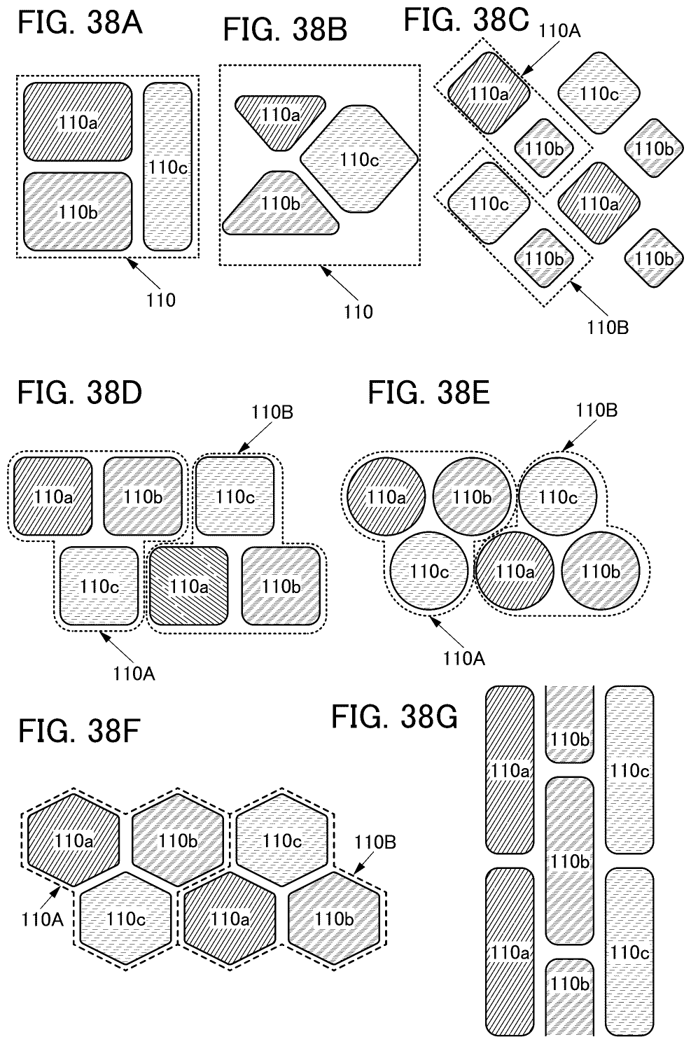

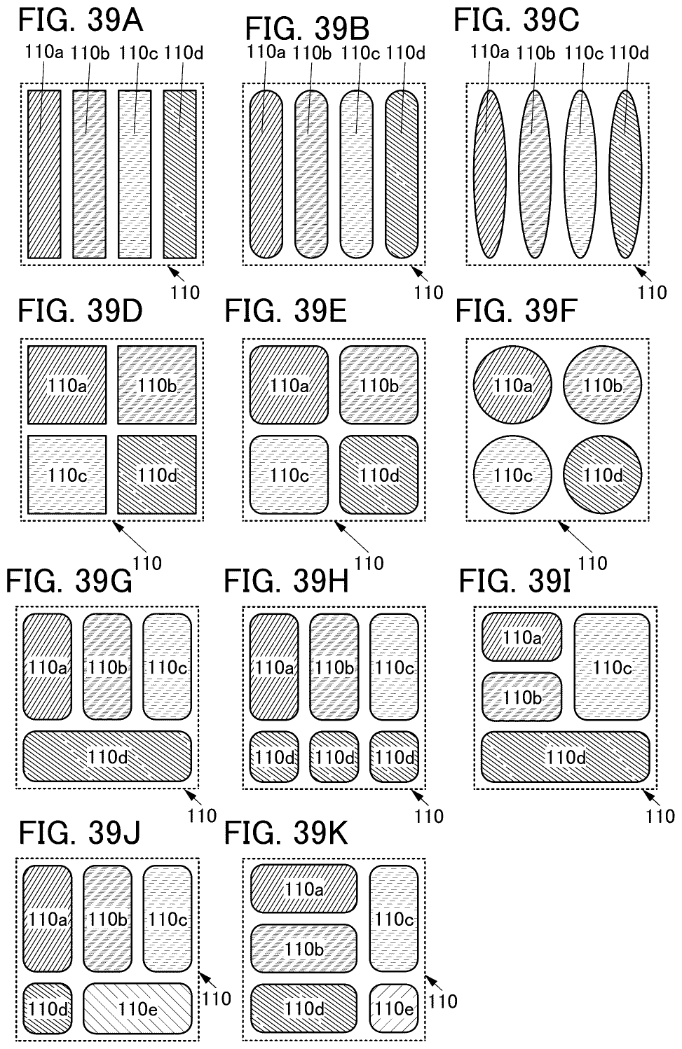

In this embodiment, a display apparatus of one embodiment of the present invention is described with reference to FIG. 38 and FIG. 39.

### [Pixel Layout]

Pixel layouts different from that in FIG. 1 will be mainly described in this embodiment. There is no particular limitation on the arrangement of subpixels, and any of a variety of methods can be employed. Examples of the arrangement of subpixels include stripe arrangement, S-stripe arrangement, matrix arrangement, delta arrangement, Bayer arrangement, and PenTile arrangement.

The top surface shape of the subpixel illustrated in a diagram in this embodiment corresponds to the top surface shape of a light-emitting region (or a light-receiving region).

Examples of a top surface shape of the subpixel include polygons such as a triangle, a tetragon (including a rectangle and a square), and a pentagon; polygons with rounded corners; an ellipse; and a circle.

The range of the circuit layout for forming the subpixel is not limited to the range of the subpixel illustrated in a diagram and may be placed outside the range of the subpixel.

The pixel 110 illustrated in FIG. 38A employs S-stripe arrangement. The pixel 110 illustrated in FIG. 38A is composed of three kinds of subpixels: the subpixel 110a, the subpixel 110b, and the subpixel 110c.

The pixel 110 illustrated in FIG. 38B includes the subpixel 110a, the subpixel 110b whose top surface has a rough triangle shape with rounded corners, and the subpixel 110c whose top surface has a rough tetragonal or rough hexagonal shape with rounded corners. The subpixel 110b has a larger light-emitting area than the subpixel 110a. In this manner, the shapes and sizes of the subpixels can be determined independently. For example, the size of a subpixel including a light-emitting device with higher reliability can be smaller.

A pixel 110A and a pixel 110B illustrated in FIG. 38C employ PenTile arrangement. FIG. 38C illustrates an example in which the pixels 110A including the subpixel 110a and the subpixel 110b and the pixels 110B including the subpixel 110b and the subpixel 110c are alternately arranged.

The pixel 110A and the pixel 110B illustrated in FIG. 38D to FIG. 38F employ delta arrangement. The pixel 110A includes two subpixels (the subpixel 110a and the subpixel 110b) in the upper row (first row) and one subpixel (the subpixel 110c) in the lower row (second row). The pixel 110B includes one subpixel (the subpixel 110c) in the upper row (first row) and two subpixels (the subpixel 110a and the subpixel 110b) in the lower row (second row).

FIG. 38D illustrates an example in which each subpixel has a rough tetragonal top surface shape with rounded corners, FIG. 38E illustrates an example in which each subpixel has a circular top surface shape, and FIG. 38F illustrates an example in which each subpixel has a rough hexagonal top surface shape with rounded corners.

In FIG. 38F, subpixels are placed in respective hexagonal regions that are arranged densely. Focusing on one of the subpixels, the subpixel is placed so as to be surrounded by six subpixels. The subpixels are arranged such that subpixels that emit light of the same color are not adjacent to each other. For example, focusing on the subpixel 110a, three subpixels 110b and three subpixels 110c are arranged to surround the subpixel 110a, so that the subpixel 110a, the subpixel 110b, and the subpixel 110c are alternately arranged.

FIG. 38G illustrates an example in which subpixels of different colors are arranged in a zigzag manner. Specifically, the positions of the top sides of two subpixels arranged in the row direction (e.g., the subpixel 110a and the subpixel 110b or the subpixel 110b and the subpixel 110c) are not aligned in the top view.

For example, in each pixel illustrated in FIG. 38A to FIG. 38G, it is preferable that the subpixel 110a be a subpixel R emitting red light, the subpixel 110b be a subpixel G emitting green light, and the subpixel 110c be a subpixel B emitting blue light. Note that the structure of the subpixels is not limited to this, and the colors and arrangement order of the subpixels can be determined as appropriate. For example, the subpixel 110b may be the subpixel R emitting red light and the subpixel 110a may be the subpixel G emitting green light.

In a photolithography method, as a pattern to be processed becomes finer, the influence of light diffraction becomes more difficult to ignore; Thus, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel has a polygonal shape with rounded corners, an elliptical shape, a circular shape, or the like, in some cases.

Furthermore, in the method for manufacturing the display apparatus of one embodiment of the present invention, the EL layer is processed into an island shape using a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film may have a shape different from a desired shape after being processed. As a result, the top surface of the EL layer may have a polygonal shape with rounded corners, an elliptical shape, a circular shape, or the like. For example, when a resist mask whose top surface has a square shape is intended to be formed, a resist mask whose top surface has a circular shape may be formed, and the top surface of the EL layer may have a circular shape.

Note that to obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

As illustrated in FIG. 39A to FIG. 39I, the pixel can include four types of subpixels.

The pixels 110 illustrated in FIG. 39A to FIG. 39C employ stripe arrangement.

FIG. 39A illustrates an example in which each subpixel has a rectangular top surface shape, FIG. 39B illustrates an example in which each subpixel has a top surface shape formed by combining two half circles and a rectangle, and FIG. 39C illustrates an example in which each subpixel has an elliptical top surface shape.

The pixels 110 illustrated in FIG. 39D to FIG. 39F employ matrix arrangement.

FIG. 39D illustrates an example in which each subpixel has a square top surface shape, FIG. 39E illustrates an example in which each subpixel has a rough square top surface shape with rounded corners, and FIG. 39F illustrates an example in which each subpixel has a circular top surface shape.

FIG. 39G and FIG. 39H each illustrate an example in which one pixel 110 is composed of two rows and three columns.

The pixel 110 illustrated in FIG. 39G includes three subpixels (the subpixels 110a, 110b, and 110c) in the upper row (first row) and one subpixel (the subpixel 110d) in the lower row (second row). In other words, the pixel 110 includes the subpixel 110a in the left column (first column), the subpixel 110b in the center column (second column), the subpixel 110c in the right column (third column), and the subpixel 110d across these three columns.

The pixel 110 illustrated in FIG. 39H includes three subpixels (the subpixels 110a, 110b, and 110c) in the upper row (first row) and three subpixels 110d in the lower row (second row). In other words, the pixel 110 includes the subpixel 110a and the subpixel 110d in the left column (first column), the subpixel 110b and the subpixel 110d in the center column (second column), and the subpixel 110c and the subpixel 110d in the right column (third column). Matching the positions of the subpixels in the upper row and the lower row as illustrated in FIG. 39H enables efficient removal of dust and the like that would be produced in the manufacturing process. Thus, a display apparatus with high display quality can be provided.

FIG. 39I illustrates an example in which one pixel 110 is composed of three rows and two columns.

The pixel 110 illustrated in FIG. 39I includes the subpixel 110a in the upper row (first row), the subpixel 110b in the center row (second row), the subpixel 110c across the first and second rows, and one subpixel (the subpixel 110d) in the lower row (third row). In other words, the pixel 110 includes the subpixel 110a and the subpixel 110b in the left column (first column), the subpixel 110c in the right column (second column), and the subpixel 110d across these two columns.

The pixels 110 illustrated in FIG. 39A to FIG. 39I are each composed of four subpixels: the subpixel 110a, the subpixel 110b, the subpixel 110c, and the subpixel 110d.

The subpixel 110a, the subpixel 110b, the subpixel 110c, and the subpixel 110d can include light-emitting devices whose emission colors are different. The subpixel 110a, the subpixel 110b, the subpixel 110c, and the subpixel 110d are subpixels of four colors of R, G, B, and white (W), subpixels of four colors of R, G, B, and Y, or subpixels of R, G, B, and infrared light (IR), for example.

In the pixels 110 illustrated in FIG. 39A to FIG. 39I, it is preferable that the subpixel 110a be the subpixel R emitting red light, the subpixel 110b be the subpixel G emitting green light, the subpixel 110c be the subpixel B emitting blue light, and the subpixel 110d be any of a subpixel W emitting white light, a subpixel Y emitting yellow light, and a subpixel IR emitting near-infrared light, for example. In the case of such a structure, stripe arrangement is employed as the layout of R, G, and B in the pixels 110 illustrated in FIG. 39G and FIG. 39H, leading to higher display quality. In addition, what is called S-stripe arrangement is employed as the layout of R, G, and B in the pixel 110 illustrated in FIG. 39I, leading to higher display quality.

The pixel 110 may include a subpixel including a light-receiving device.

In the pixels 110 illustrated in FIG. 39A to FIG. 39I, any one of the subpixel 110a to the subpixel 110d may be a subpixel including a light-receiving device.

In the pixels 110 illustrated in FIG. 39A to FIG. 39I, for example, it is preferable that the subpixel 110a be the subpixel R emitting red light, the subpixel 110b be the subpixel G emitting green light, the subpixel 110c be the subpixel B emitting blue light, and the subpixel 110d be a subpixel S including a light-receiving device. In the case of such a structure, stripe arrangement is employed as the layout of R, G, and B in the pixels 110 illustrated in FIG. 39G and FIG. 39H, leading to higher display quality. In addition, what is called S-stripe arrangement is employed as the layout of R, G, and B in the pixel 110 illustrated in FIG. 39I, leading to higher display quality.

There is no particular limitation on the wavelength of light detected by the subpixel S including a light-receiving device. The subpixel S can have a structure in which one or both of visible light and infrared light are detected.

As illustrated in FIG. 39J and FIG. 39K, the pixel can include five types of subpixels.

FIG. 39J illustrates an example in which one pixel 110 is composed of two rows and three columns.

The pixel 110 illustrated in FIG. 39J includes three subpixels (the subpixels 110a, 110b, and 110c) in the upper row (first row) and two subpixels (the subpixel 110d and a subpixel 110e) in the lower row (second row). In other words, the pixel 110 includes the subpixels 110a and 110d in the left column (first column), the subpixel 110b in the center column (second column), the subpixel 110c in the right column (third column), and the subpixel 110e across the second and third columns.

FIG. 39K illustrates an example in which one pixel 110 is composed of three rows and two columns.

The pixel 110 illustrated in FIG. 39K includes the subpixel 110a in the upper row (first row), the subpixel 110b in the center row (second row), the subpixel 110c across the first and second rows, and two subpixels (the subpixels 110d and 110e) in the lower row (third row). In other words, the pixel 110 includes the subpixels 110a, 110b, and 110d in the left column (first column), and the subpixels 110c and 110e in the right column (second column).

In the pixels 110 illustrated in FIG. 39J and FIG. 39K, for example, it is preferable that the subpixel 110a be the subpixel R emitting red light, the subpixel 110b be the subpixel G emitting green light, and the subpixel 110c be the subpixel B emitting blue light. In the case of such a structure, stripe arrangement is employed as the layout of R, G, and B in the pixel 110 illustrated in FIG. 39J, leading to higher display quality. In addition, what is called S-stripe arrangement is employed as the layout of R, G, and B in the pixel 110 illustrated in FIG. 39K, leading to higher display quality.

In the pixels 110 illustrated in FIG. 39J and FIG. 39K, for example, it is preferable to use the subpixel S including a light-receiving device as at least one of the subpixel 110d and the subpixel 110e. In the case where light-receiving devices are used in both the subpixel 110d and the subpixel 110e, the light-receiving devices may have different structures. For example, the wavelength ranges of detected light may be different at least partly. Specifically, one of the subpixel 110d and the subpixel 110e may include a light-receiving device mainly detecting visible light and the other may include a light-receiving device mainly detecting infrared light.

In the pixels 110 illustrated in FIG. 39J and FIG. 39K, it is preferable that, for example, the subpixel S including a light-receiving device be used as one of the subpixel 110d and the subpixel 110e and a subpixel including a light-emitting device that can be used as a light source be used as the other. For example, it is preferable that one of the subpixel 110d and the subpixel 110e be the subpixel IR emitting infrared light and the other be the subpixel S including a light-receiving device detecting infrared light.

In a pixel including the subpixels R, G, B, IR, and S, while an image is displayed using the subpixels R, G, and B, reflected light of infrared light emitted by the subpixel IR that is used as a light source can be detected by the subpixel S.

As described above, the pixel composed of the subpixels each including the light-emitting device can employ any of a variety of layouts in the display apparatus of one embodiment of the present invention. The display apparatus of one embodiment of the present invention can have a structure in which the pixel includes both a light-emitting device and a light-receiving device. Also in this case, any of a variety of layouts can be employed.

This embodiment can be combined with any of the other embodiments as appropriate.

### Embodiment 4

In this embodiment, a display apparatus of one embodiment of the present invention will be described.

The display apparatus in this embodiment can be a high-definition display apparatus. Accordingly, the display apparatus in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The display apparatus of this embodiment can be a high-resolution display apparatus or a large-sized display apparatus. Accordingly, the display apparatus in this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

### [Display Apparatus 100A]

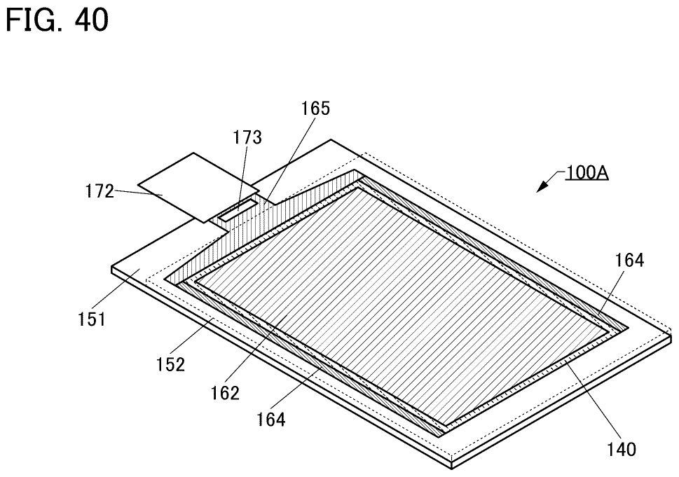

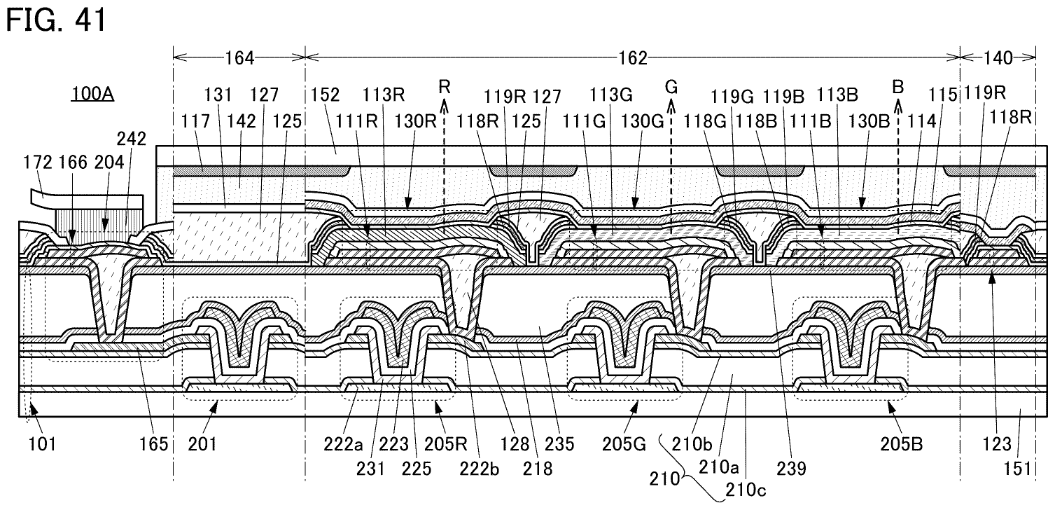

FIG. 40 is a perspective view of a display apparatus 100A, and FIG. 41 is a cross-sectional view of the display apparatus 100A.

In the display apparatus 100A, a substrate 152 and the substrate 151 are bonded to each other. In FIG. 40, the substrate 152 is indicated by a dashed line.

The display apparatus 100A includes a display portion 162, the connection portion 140, a circuit 164, a wiring 165, and the like. FIG. 40 illustrates an example in which an IC 173 and an FPC 172 are mounted on the display apparatus 100A. Thus, the structure illustrated in FIG. 40 can also be regarded as a display module including the display apparatus 100A, the IC (integrated circuit), and the FPC.

The connection portion 140 is provided outside the display portion 162. The connection portion 140 can be provided along one or more sides of the display portion 162. The number of the connection portions 140 can be one or more. FIG. 40 illustrates an example in which the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 40 illustrates an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100A and the display module are not necessarily provided with an IC. The IC may be mounted on the FPC by a COF method or the like.

FIG. 41 illustrates an example of cross sections of part of a region including the FPC 172, part of the circuit 164, part of the display portion 162, part of the connection portion 140, and part of a region including an end portion of the display apparatus 100A.

The display apparatus 100A illustrated in FIG. 41 includes a transistor 201, a transistor 205, the light-emitting device 130R, the light-emitting device 130G, the light-emitting device 130B, and the like between the substrate 151 and the substrate 152.

A side surface and part of the top surface of each of the layer 113R, the layer 113G, and the layer 113B are covered with the insulating layer 125 and the insulating layer 127. The mask layer 118R and the mask layer 119R are positioned between the layer 113R and the insulating layer 125. The mask layer 118G and the mask layer 119G are positioned between the layer 113G and the insulating layer 125, and the mask layer 118B and the mask layer 119B are positioned between the layer 113B and the insulating layer 125. The common layer 114 is provided over the layer 113B, the layer 113G, the layer 113R, the insulating layers 125, and the insulating layer 127, and the common electrode 115 is provided over the common layer 114. The common layer 114 and the common electrode 115 are each a continuous film provided to be shared by a plurality of light-emitting devices.

The protective layer 131 is provided over the light-emitting device 130R, the light-emitting device 130G, and the light-emitting device 130B. The protective layer 131 and the substrate 152 are bonded to each other with an adhesive layer 142. The substrate 152 is provided with a light-blocking layer 117. A solid sealing structure, a hollow sealing structure, or the like can be employed to seal the light-emitting devices. In FIG. 41, a solid sealing structure is employed in which a space between the substrate 152 and the substrate 151 is filled with the adhesive layer 142. Alternatively, a hollow sealing structure may be employed, in which the space is filled with an inert gas (e.g., nitrogen or argon). Here, the adhesive layer 142 may be provided not to overlap with the light-emitting device. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit 164. It is also preferable that the protective layer 131 be provided to extend to an end portion of the display apparatus 100A. Meanwhile, a connection portion 204 has a portion not provided with the protective layer 131 so that the FPC 172 and a conductive layer 166 are electrically connected to each other.

A connection portion 204 is provided in a region of the substrate 151 where the substrate 152 does not overlap. In the connection portion 204, the wiring 165 is electrically connected to the FPC 172 through the conductive layer 166 and a connection layer 242. The conductive layer 166 can be formed in the same step as the pixel electrode 111R, the pixel electrode 111G, the pixel electrode 111B, and the conductive layer 123. The conductive layer 166 is exposed on the top surface of the connection portion 204. Thus, the connection portion 204 and the FPC 172 can be electrically connected to each other through the connection layer 242.

For example, the protective layer 131 is formed over the entire surface of the display apparatus 100A and then a region of the protective layer 131 overlapping with the conductive layer 166 is removed, so that the conductive layer 166 can be exposed.

A stacked-layer structure of at least one organic layer and a conductive layer may be provided over the conductive layer 166, and the protective layer 131 may be provided over the stacked-layer structure. Then, a peeling trigger (a portion that can be a trigger of peeling) may be formed in the stacked-layer structure using a laser or a sharp cutter (e.g., a needle or a utility knife) to selectively remove the stacked-layer structure and the protective layer 131 thereover, so that the conductive layer 166 may be exposed. For example, the protective layer 131 can be selectively removed when an adhesive roller is pressed to the substrate 151 and then moved relatively while being rolled. Alternatively, an adhesive tape may be attached to the substrate 151 and then peeled. Since the adhesion between the organic layer and the conductive layer or between the organic layers is low, separation occurs at the interface between the organic layer and the conductive layer or in the organic layer. Thus, a region of the protective layer 131 overlapping with the conductive layer 166 can be selectively removed. Note that when the organic layer and the like remain over the conductive layer 166, the remaining organic layer and the like can be removed by an organic solvent or the like.

As the organic layer, it is possible to use at least one of the organic layers (the layer functioning as the light-emitting layer, the carrier-blocking layer, the carrier-transport layer, or the carrier-injection layer) used for the layer 113B, the layer 113G, and the layer 113R, for example. The organic layer may be formed concurrently with the layer 113B, the layer 113G, and the layer 113R, or may be provided separately. The conductive layer can be formed using the same step and the same material as those for the common electrode 115. An ITO film is preferably formed as the common electrode 115 and the conductive layer, for example. Note that in the case where a stacked-layer structure is used for the common electrode 115, at least one of the layers included in the common electrode 115 is provided as the conductive layer.

The top surface of the conductive layer 166 may be covered with a mask so that the protective layer 131 is not provided over the conductive layer 166. As the mask, a metal mask (area metal mask) or a tape or a film having adhesiveness or attachability may be used. The protective layer 131 is formed while the mask is placed and then the mask is removed, so that the conductive layer 166 can be kept exposed even after the protective layer 131 is formed.

With such a method, a region not provided with the protective layer 131 can be formed in the connection portion 204, and the conductive layer 166 and the FPC 172 can be electrically connected to each other through the connection layer 242 in the region.

The conductive layer 123 is provided over the insulating layer 235 in the connection portion 140. The conductive layer 123 can be formed in the same step as the pixel electrode 111R, the pixel electrode 111G, and the pixel electrode 111B. Alternatively, the conductive layer 123 can be formed in the same step as part of the steps of forming the pixel electrode 111R, the pixel electrode 111G, and the pixel electrode 111B. An end portion of the conductive layer 123 is covered with the mask layer 118R, the mask layer 119R, the insulating layer 125, and the insulating layer 127. The common layer 114 is provided over the conductive layer 123, and the common electrode 115 is provided over the common layer 114. The conductive layer 123 and the common electrode 115 are electrically connected to each other through the common layer 114. Note that the common layer 114 is not necessarily formed in the connection portion 140. In this case, the conductive layer 123 and the common electrode 115 are in direct contact with each other to be electrically connected to each other.

The display apparatus 100A has a top-emission structure. Light emitted by the light-emitting device is emitted toward the substrate 152 side. For the substrate 152, a material having a high visible-light-transmitting property is preferably used. The pixel electrode contains a material reflecting visible light, and the counter electrode (the common electrode 115) contains a material transmitting visible light.

Both of the transistor (e.g., the transistor 201) included in the circuit 164 and the transistor (e.g., the transistor 205R) included in the display portion 162 are formed over the substrate 151. These transistors can be formed using the same material in the same process. For example, the transistor described in Embodiment 1 can be suitably used.

The transistors included in the circuit 164 and the transistors included in the display portion 162 may have the same structure or different structures. A plurality of transistors included in the circuit 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. A structure in which an LTPS transistor and an OS transistor are used in combination is referred to as LTPO in some cases. It is further preferable that an OS transistor be used as a transistor functioning as a switch for controlling conduction or non-conduction between wirings, and an LTPS transistor be used as, for example, a transistor for controlling current.

For example, one transistor included in the display portion 162 functions as a transistor for controlling current flowing through the light-emitting device and can also be referred to as a driving transistor. One of a source and a drain of the driving transistor is electrically connected to the pixel electrode of the light-emitting device. An LTPS transistor is preferably used as the driving transistor. Thus, current flowing through the light-emitting device in the pixel circuit can be increased.

In contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

As described above, the display apparatus of one embodiment of the present invention can have all of a high aperture ratio, high definition, high display quality, and low power consumption.

Note that the display apparatus of one embodiment of the present invention has a structure including the OS transistor and the light-emitting device having an MIL (metal maskless) structure. This structure can significantly reduce the leakage current that might flow through a transistor, and the leakage current that might flow between adjacent light-emitting devices (also referred to as a lateral leakage current or a side leakage current). With the structure, a viewer can observe any one or more of image crispness, image sharpness, a high chroma, and a high contrast ratio in an image displayed on the display apparatus. Note that when the leakage current that might flow through a transistor and the lateral leakage current between light-emitting devices are extremely low, light leakage or the like (what is called black blurring) that might occur in black display can be reduced as much as possible.

In particular, in the case where a light-emitting device having the MML structure employs the above-described SBS structure, a layer provided between light-emitting devices (for example, an organic layer shared by the light-emitting devices, also referred to as a common layer) is disconnected; accordingly, lateral leakage can be eliminated or reduced as much as possible.

The light-blocking layer 117 is preferably provided on the surface of the substrate 152 that faces the substrate 151. The light-blocking layer 117 can be provided between adjacent light-emitting devices, in the connection portion 140, and in the circuit 164, for example. A variety of optical members can be arranged on the outer surface of the substrate 152.

The material that can be used for the substrate 120 can be used for each of the substrate 151 and the substrate 152.

The material that can be used for the resin layer 122 can be used for the adhesive layer 142.

As the connection layer 242, an anisotropic conductive film (ACF), an anisotropic conductive paste (ACP), or the like can be used.

### [Display Apparatus 100B]

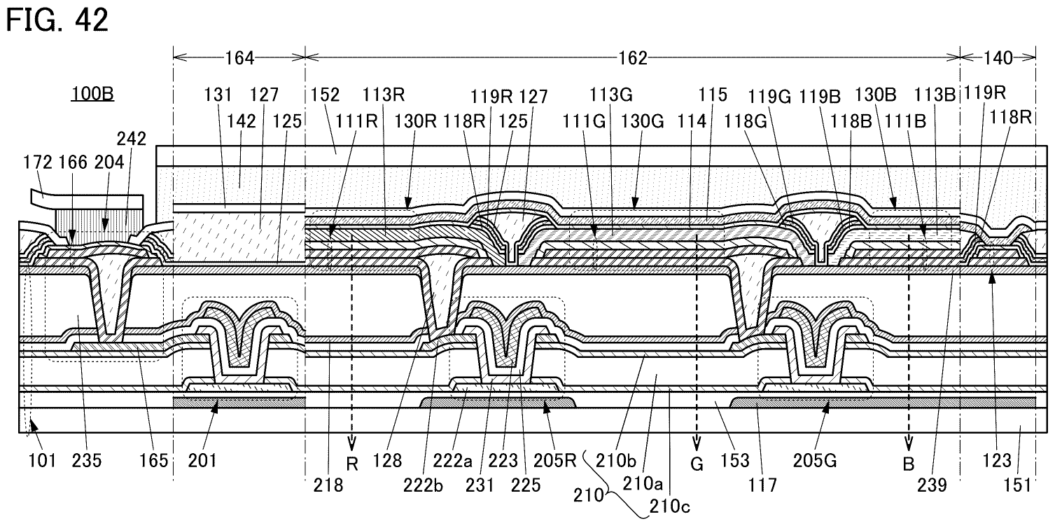

A display apparatus 100B illustrated in FIG. 42 is different from the display apparatus 100A mainly in being a bottom-emission display apparatus.

Light emitted by the light-emitting device is emitted toward the substrate 151 side. For the substrate 151, a material having a high visible-light-transmitting property is preferably used. In contrast, there is no limitation on the light-transmitting property of a material used for the substrate 152.

The light-blocking layer 117 is preferably formed between the substrate 151 and the transistor 201 and between the substrate 151 and the transistor 205. FIG. 42 illustrates an example in which the light-blocking layer 117 is provided over the substrate 151, an insulating layer 153 is provided over the light-blocking layer 117, and the transistors 201 and 205 and the like are provided over the insulating layer 153.

A material having a high visible-light-transmitting property is used for each of the layers included in the pixel electrode 111. A material reflecting visible light is preferably used for the common electrode 115.

### [Display Apparatus 100C]

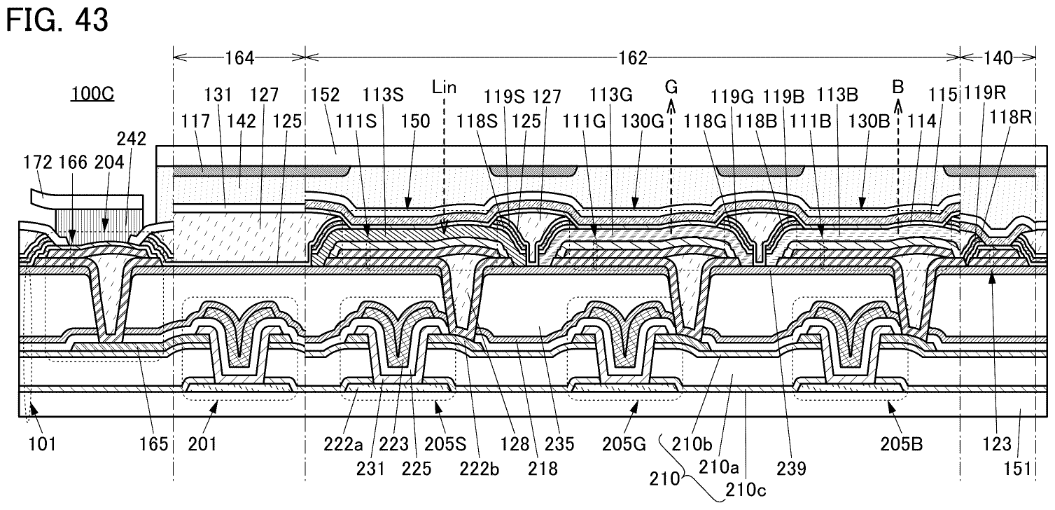

A display apparatus 100C illustrated in FIG. 43 is different from the display apparatus 100A mainly in including the light-receiving device 150.

The light-receiving device 150 includes the pixel electrode 111S, the layer 113S, the common layer 114, and the common electrode 115. The layer 113S includes at least an active layer. The pixel electrode 111S can be formed through the same process as the pixel electrode 111R, the pixel electrode 111G, and the pixel electrode 111B.

The pixel electrode 111S is connected to the conductive layer 222b included in the transistor 205S through the openings provided in the insulating layer 225, the insulating layer 218, the insulating layer 235, and the insulating layer 239.

The top surface and the side surface of the pixel electrode 111S are covered with the layer 113S.

The side surface and part of the top surface of the layer 113S are covered with the insulating layer 125 and the insulating layer 127. The mask layer 118S and the mask layer 119S are positioned between the layer 113S and the insulating layer 125. The common layer 114 is provided over the layer 113S and the insulating layer 125 and the insulating layer 127, and the common electrode 115 is provided over the common layer 114. The common layer 114 is a continuous film provided to be shared by the light-receiving device and the light-emitting devices.

The display apparatus 100C can employ any of the pixel layouts that are described in Embodiment 3 with reference to FIG. 39A to FIG. 39K, for example. Embodiment 1 and Embodiment 6 can be referred to for the details of the display apparatus including the light-receiving device.

This embodiment can be combined with any of the other embodiments as appropriate.

### Embodiment 5

In this embodiment, a light-emitting device that can be used in the display apparatus of one embodiment of the present invention is described.

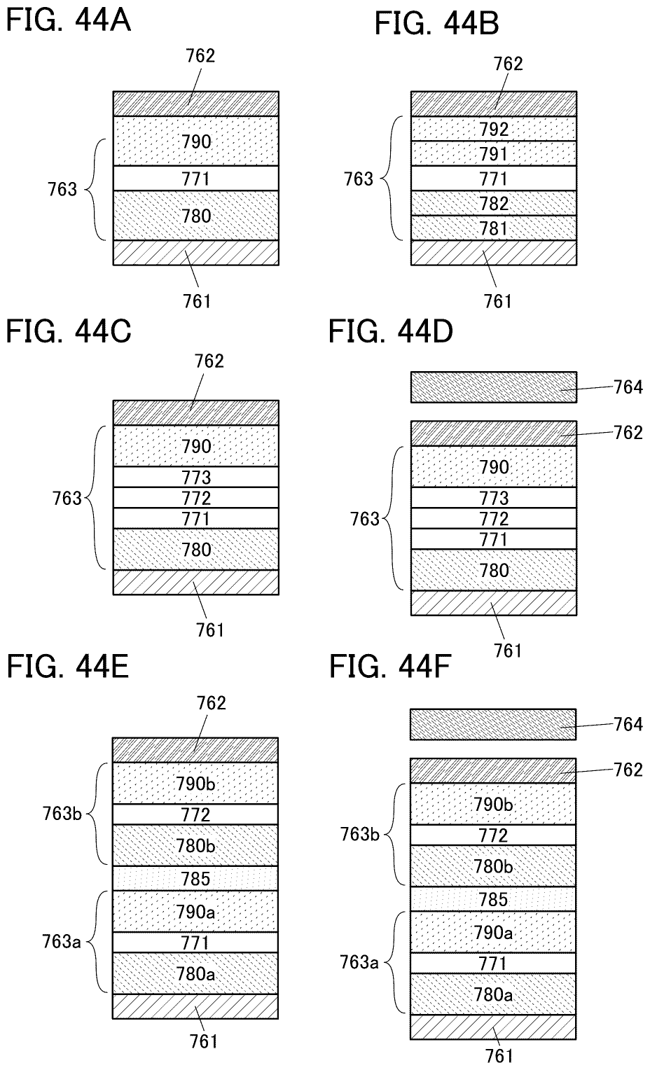

As illustrated in FIG. 44A, the light-emitting device includes an EL layer 763 between a pair of electrodes (a lower electrode 761 and an upper electrode 762). The EL layer 763 can be formed with a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layers 780 and 790 are interchanged.

The structure including the layer 780, the light-emitting layer 771, and the layer 790, which is provided between the pair of electrodes, can function as a single light-emitting unit, and the structure in FIG. 44A is referred to as a single structure in this specification.

FIG. 44B is a modification example of the EL layer 763 included in the light-emitting device illustrated in FIG. 44A. Specifically, the light-emitting device illustrated in FIG. 44B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (light-emitting layers 771, 772, and 773) are provided between the layers 780 and 790 as illustrated in FIG. 44C and FIG. 44D are other variations of the single structure. Although FIG. 44C and FIG. 44D each illustrate an example in which three light-emitting layers are included, the number of light-emitting layers in a light-emitting device having a single structure may be two or four or more. A light-emitting device having a single structure may include a buffer layer between two light-emitting layers. A carrier-transport layer (a hole-transport layer and an electron-transport layer) can be used as the buffer layer, for example.

A structure in which a plurality of light-emitting units (light-emitting units 763a and 763b) are connected in series with a charge-generation layer (also referred to as an intermediate layer) 785 therebetween as illustrated in FIG. 44E and FIG. 44F is referred to as a tandem structure in this specification. The tandem structure may be referred to as a stack structure. The tandem structure enables a light-emitting device capable of high-luminance light emission. Furthermore, the tandem structure allows the amount of current needed for obtaining the same luminance to be reduced as compared with the case of using a single structure, and thus can improve the reliability.

Note that FIG. 44D and FIG. 44F each illustrate an example in which the display apparatus includes a layer 764 overlapping with the light-emitting device. FIG. 44D illustrates an example in which the layer 764 overlaps with the light-emitting device illustrated in FIG. 44C and FIG. 44F illustrates an example in which the layer 764 overlaps with the light-emitting device illustrated in FIG. 44E. In FIG. 44D and FIG. 44F, a conductive film that transmits visible light is used for the upper electrode 762 so that light is extracted through the upper electrode 762.

One or both of a color conversion layer and a color filter (coloring layer) can be used as the layer 764.

In FIG. 44C and FIG. 44D, light-emitting materials that emit light of the same color or the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In each of a subpixel that emits red light and a subpixel that emits green light, a color conversion layer is provided as the layer 764 illustrated in FIG. 44D for converting blue light emitted from the light-emitting device into light with a longer wavelength, so that red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and color purity of light exhibited by a subpixel can be improved.

In FIG. 44C and FIG. 44D, light-emitting substances that emit light of different colors may be used for the light-emitting layer 771, the light-emitting layer 772, and the light-emitting layer 773. White light emission can be obtained by mixing of light emitted from the light-emitting layer 771, the light-emitting layer 772, and the light-emitting layer 773. The light-emitting device having a single structure preferably includes a light-emitting layer including a light-emitting substance emitting blue light and a light-emitting layer including a light-emitting substance emitting visible light with a longer wavelength than blue light, for example.

A color filter may be provided as the layer 764 illustrated in FIG. 44D. When white light passes through a color filter, light of a desired color can be obtained.

In the case where the light-emitting device having a single structure includes three light-emitting layers, for example, a light-emitting layer including a light-emitting substance emitting red (R) light, a light-emitting layer including a light-emitting substance emitting green (G) light, and a light-emitting layer including a light-emitting substance emitting blue (B) light are preferably included. The stacking order of the light-emitting layers can be RGB or RBG from an anode side, for example. In that case, a buffer layer may be provided between R and G or between R and B.

In the case where the light-emitting device having a single structure includes two light-emitting layers, for example, a light-emitting layer including a light-emitting substance emitting blue (B) light and a light-emitting layer including a light-emitting substance emitting yellow (Y) light are preferably included. Such a structure may be referred to as a BY single structure.

In the light-emitting device that emits white light, two or more kinds of light-emitting substances are preferably included. The light emitting substances are selected such that white light is obtained by mixing light emitted from the light-emitting substances. For example, when emission colors of a first light-emitting layer and a second light-emitting layer are complementary colors, the light-emitting device can emit white light as a whole. Similarly, in the case of a light-emitting device including three or more light-emitting layers, the light-emitting device emitting white light can be obtained by mixing light emitted from the light-emitting layers.

In FIG. 44C and FIG. 44D, the layer 780 and the layer 790 may each have a stacked-layer structure of two or more layers as illustrated in FIG. 44B.

In FIG. 44E and FIG. 44F, light-emitting substances that emit light of the same color, or the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In the subpixel that emits blue light, blue light emitted from the light-emitting device can be extracted. In each of the subpixel that emits red light and the subpixel that emits green light, a color conversion layer is provided as the layer 764 illustrated in FIG. 44F for converting blue light emitted from the light-emitting device into light with a longer wavelength, so that red light or green light can be extracted. As the layer 764, both a color conversion layer and a coloring layer are preferably used.

In the case where light-emitting devices with the structure illustrated in FIG. 44E or FIG. 44F are used in subpixels emitting light of different colors, light-emitting substances may be different between the subpixels. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light may be used for each of the light-emitting layer 771 and the light-emitting layer 772. In the light-emitting device included in the subpixel emitting blue light, a light-emitting substance that emits blue light may be used for each of the light-emitting layer 771 and the light-emitting layer 772. A display apparatus with such a structure includes a light-emitting device with a tandem structure and can be regarded to have an SBS structure. Thus, the display apparatus can have advantages of both of a tandem structure and an SBS structure. Accordingly, a highly reliable light-emitting device capable of high-luminance light emission can be obtained.

In FIG. 44E and FIG. 44F, light-emitting substances that emit light of different colors may be used for the light-emitting layer 771 and the light-emitting layer 772. When the light-emitting layer 771 and the light-emitting layer 772 emit light of complementary colors, white light emission can be obtained. A color filter may be provided as the layer 764 illustrated in FIG. 44F. When white light passes through a color filter, light of a desired color can be obtained.

Although FIG. 44E and FIG. 44F each illustrate an example in which the light-emitting unit 763a includes one light-emitting layer 771 and the light-emitting unit 763b includes one light-emitting layer 772, one embodiment of the present invention is not limited to the example. Each of the light-emitting unit 763a and the light-emitting unit 763b may include two or more light-emitting layers.

Although FIG. 44E and FIG. 44F each illustrate an example of a light-emitting device including two light-emitting units, one embodiment of the present invention is not limited to the example. The light-emitting device may include three or more light-emitting units. Note that a structure including two light-emitting units and a structure including three light-emitting units may be referred to as a two-unit tandem structure and a three-unit tandem structure, respectively.

In each of FIG. 44E and FIG. 44F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. Furthermore, the layer 790a and the layer 790b each include one or more of an electron-injection layer, an electron-transport layer, and a hole-blocking layer. In the case where the lower electrode 761 is a cathode and the upper electrode 762 is an anode, the structures of the layer 780a and the layer 790a are interchanged and the structures of the layer 780b and the layer 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes to the other when voltage is applied between the pair of electrodes.

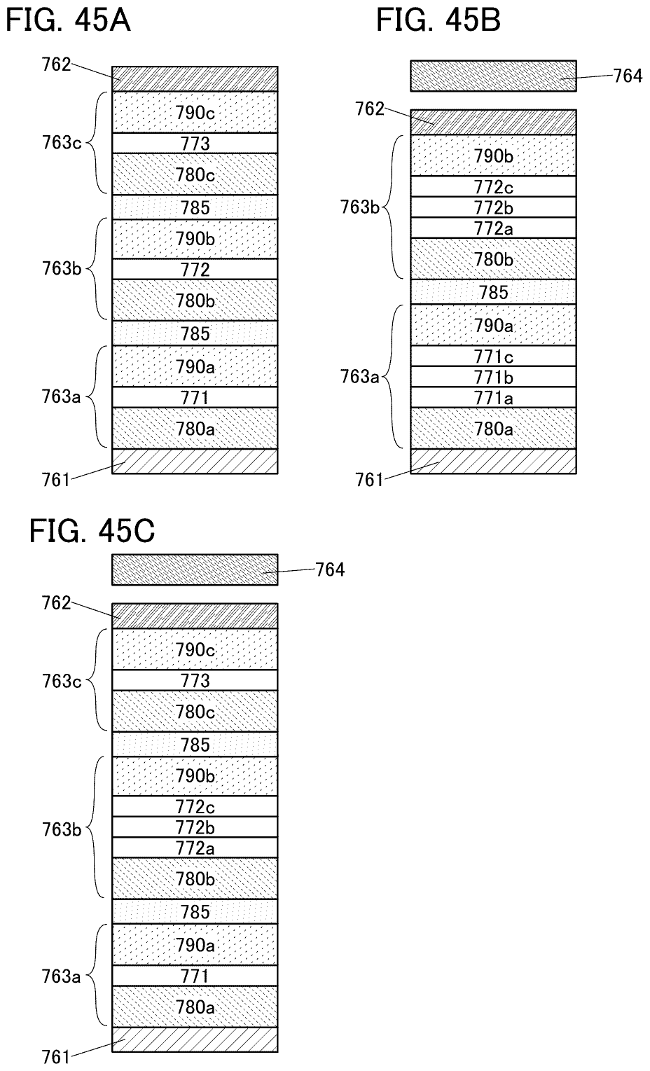

Examples of the light-emitting device with a tandem structure are structures illustrated in FIG. 45A to FIG. 45C.

FIG. 45A illustrates a structure including three light-emitting units. In the structure illustrated in FIG. 45A, a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 45A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (i.e., an R\R\R three-unit tandem structure), can each include a light-emitting substance that emits green (G) light (i.e., a G\G\G three-unit tandem structure), or can each include a light-emitting substance that emits blue (B) light (i.e., a B\B\B three-unit tandem structure). Note that “a\b” means that a light-emitting unit including a light-emitting substance that emits light of a color “b” is provided over a light-emitting unit including a light-emitting substance that emits light of a color “a” with a charge-generation layer therebetween, and “a” and “b” each mean a color.

In FIG. 45A, light-emitting substances that emit light of different colors may be used for some or all of the light-emitting layer 771, the light-emitting layer 772, and the light-emitting layer 773. Examples of the combination of emission colors for the light-emitting layer 771, the light-emitting layer 772, and the light-emitting layer 773 include a combination of blue (B) for two of them and yellow (Y) for the other; and a combination of red (R) for one of them, green (G) for another, and blue (B) for the other.

Note that the light-emitting substances that emit light of the same color is not limited to the above structure. For example, a light-emitting device with a tandem structure may be employed in which light-emitting units each including a plurality of light-emitting layers are stacked as illustrated in FIG. 45B. FIG. 45B illustrates a structure in which two light-emitting units (light-emitting unit 763a and light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 45B, the light-emitting substances can be selected such that the light-emitting unit 763a emits white light (W) by mixing light emitted from the light-emitting layer 771a, the light-emitting layer 771b, and the light-emitting layer 771c. In addition, the light-emitting substances can be selected such that the light-emitting unit 763b emits white light (W) by mixing light emitted from the light-emitting layer 772a, the light-emitting layer 772b, and the light-emitting layer 772c. That is, the structure illustrated in FIG. 45B is a two-unit tandem structure of W\W. Note that there is no particular limitation on the stacking order of the light-emitting substances. The practitioner can select the optimal stacking order as appropriate. Although not illustrated, a three-unit tandem structure of W\W\W or a tandem structure with four or more units may be employed.

In the case of a light-emitting device with a tandem structure, any of the following structure may be employed, for example: a two-unit tandem structure of B\Y or Y\B including a light-emitting unit that emits yellow (Y) light and a light-emitting unit that emits blue (B) light; a two-unit tandem structure of R·G\B or B\R·G including a light-emitting unit that emits red (R) and green (G) light and a light-emitting unit that emits blue (B) light; a three-unit tandem structure of B\Y\B including a light-emitting unit that emits blue (B) light, a light-emitting unit that emits yellow (Y) light, and a light-emitting unit that emits blue (B) light in this order; a three-unit tandem structure of B\Y\G\B including a light-emitting unit that emits blue (B) light, a light-emitting unit that emits yellow-green (YG) light, and a light-emitting unit that emits blue (B) light in this order; and a three-unit tandem structure of B\G\B including a light-emitting unit that emits blue (B) light, a light-emitting unit that emits green (G) light, and a light-emitting unit that emits blue (B) light in this order. Note that “a-b” means that one light-emitting unit contains a light-emitting substance that emits light of a color “a” and a light-emitting substance that emits light of a color “b”.

Alternatively, a light-emitting unit including one light-emitting layer and a light-emitting unit including a plurality of light-emitting layers may be used in combination as illustrated in FIG. 45C.

Specifically, in the structure illustrated in FIG. 45C, a plurality of light-emitting units (light-emitting unit 763a, light-emitting unit 763b, and light-emitting unit 763c) are connected in series with the charge-generation layer 785 provided between each two light-emitting units. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 45C can be, for example, a three-unit tandem structure of B\R·G·YG\B in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display apparatus includes a light-emitting device emitting infrared light, a conductive film transmitting visible light and infrared light is preferably used for the electrode through which light is extracted, and a conductive film reflecting visible light and infrared light is preferably used for the electrode through which light is not extracted.

A conductive film transmitting visible light may be used also for the electrode through which light is not extracted. In that case, the electrode is preferably placed between a reflective layer and the EL layer 763. In other words, light emitted from the EL layer 763 may be reflected by the reflective layer to be extracted from the display apparatus.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Thus, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

The transparent electrode has a light transmittance higher than or equal to 40%. For example, an electrode having a visible light (light at a wavelength greater than or equal to 400 nm and less than 750 nm) transmittance higher than or equal to 40% is preferably used as the transparent electrode in the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer including any of a substance having a high hole-injection property, a substance having a high hole-transport property, a hole-blocking material, a substance having a high electron-transport property, an electron-blocking material, a substance having a high electron-injection property, a substance having a bipolar property (a substance with a high electron- and hole-transport property), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer includes one or more kinds of light-emitting substances. As the light-emitting substance, a substance whose emission color is blue, violet, bluish violet, green, yellowish green, yellow, orange, red, or the like is appropriately used. Alternatively, as the light-emitting substance, a substance that emits near-infrared light can be used.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a substance with a high hole-transport property which can be used for the hole-transport layer and will be described later. As the electron-transport material, it is possible to use a substance having a high electron-transport property which can be used for the electron-transport layer and will be described later. Alternatively, as one or more kinds of organic compounds, a bipolar material or a TADF material may be used.

The light-emitting layer preferably includes a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

The hole-injection layer injects holes from the anode to the hole-transport layer and includes a substance having a high hole-injection property. Examples of a substance having a high hole-injection property include an aromatic amine compound and a composite material including a hole-transport material and an acceptor material (electron-accepting material).

As the hole-transport material, any of after-mentioned substances each having a high hole-transport property that can be used for a hole-transport layer can be used.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferred because it is stable in the air, has a low hygroscopic property, and is easy to handle. Alternatively, an organic acceptor material containing fluorine can be used. Alternatively, organic acceptor materials such as a quinodimethane derivative, a chloranil derivative, and a hexaazatriphenylene derivative can be used.

As the substance having a high hole-injection property, a material containing a hole-transport material and the above-described oxide of a metal belonging to Group 4 to Group 8 of the periodic table (typically, molybdenum oxide) may be used, for example.

The hole-transport layer transports holes injected from the anode by the hole-injection layer, to the light-emitting layer. The hole-transport layer includes a hole-transport material. The hole-transport material preferably has a hole mobility higher than or equal to 1×10⁻⁶ cm²/Vs. Note that other substances can also be used as long as the substances have a hole-transport property higher than an electron-transport property. As the hole-transport material, substances having a high hole-transport property, such as a Tc-electron rich heteroaromatic compound (e.g., a carbazole derivative, a thiophene derivative, and a furan derivative) and an aromatic amine (a compound having an aromatic amine skeleton), are preferred.

The electron-blocking layer is provided in contact with the light-emitting layer. The electron-blocking layer is a layer having a hole-transport property and including a material that can block an electron. Among the above-described hole-transport materials, a material having an electron-blocking property can be used for the electron-blocking layer.

Since the electron-blocking layer has a hole-transport property, the electron-blocking layer can also be referred to as a hole-transport layer. Among hole-transport layers, a layer having an electron-blocking property can also be referred to as an electron-blocking layer.

The electron-transport layer transports electrons injected from the cathode by the electron-injection layer, to the light-emitting layer. The electron-transport layer includes an electron-transport material. The electron-transport material preferably has an electron mobility higher than or equal to 1×10⁻⁶ cm²/Vs. Note that other substances can also be used as long as the substances have an electron-transport property higher than a hole-transport property. As the electron-transport material, any of the following substances having a high electron-transport property can be used, for example: a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a Tc-electron deficient heteroaromatic compound such as a nitrogen-containing heteroaromatic compound.

The hole-blocking layer is provided in contact with the light-emitting layer. The hole-blocking layer is a layer having an electron-transport property and including a material that can block a hole. Among the above-described electron-transport materials, a material having a hole-blocking property can be used for the hole-blocking layer.

Since the hole-blocking layer has an electron-transport property, the hole-blocking layer can also be referred to as an electron-transport layer. Among electron-transport layers, a layer having a hole-blocking property can also be referred to as a hole-blocking layer.

The electron-injection layer injects electrons from the cathode to the electron-transport layer and includes a substance having a high electron-injection property. As the substance having a high electron-injection property, an alkali metal, an alkaline earth metal, or a compound thereof can be used. As the substance having a high electron-injection property, a composite material including an electron-transport material and a donor material (electron-donating material) can also be used.

The difference between the lowest unoccupied molecular orbital (LUMO) level of the substance with a high electron-injection property and the work function value of the material used for the cathode is preferably small (specifically, less than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. As an example of the stacked-layer structure, a structure in which lithium fluoride is used for the first layer and ytterbium is used for the second layer is given.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material. For example, the charge-generation region preferably includes the above-described hole-transport material and acceptor material that can be used for the hole-injection layer.

The charge-generation layer preferably includes a layer including a substance having a high electron-injection property. The layer can also be referred to as an electron-injection buffer layer. The electron-injection buffer layer is preferably provided between the charge-generation region and the electron-transport layer. The electron-injection buffer layer can reduce an injection barrier between the charge-generation region and the electron-transport layer; thus, electrons generated in the charge-generation region can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, and further preferably includes an inorganic compound containing lithium and oxygen (e.g., lithium oxide (Li₂O)). Alternatively, a material that can be used for the electron-injection layer can be favorably used for the electron-injection buffer layer.

The charge-generation layer preferably includes a layer including a substance having a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing an interaction between the charge-generation region and the electron-injection buffer layer (or the electron-transport layer) to transfer electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the charge-generation region, the electron-injection buffer layer, and the electron-relay layer cannot be clearly distinguished from one another on the basis of the cross-sectional shape or properties in some cases.

The charge-generation layer may contain a donor material instead of an acceptor material. For example, the charge-generation layer may include a layer including the above-described electron-transport material and donor material that can be used for the electron-injection layer.

When the charge-generation layer is provided between two light-emitting units to be stacked, an increase in driving voltage can be inhibited.

This embodiment can be combined with any of the other embodiments as appropriate.

### Embodiment 6

In this embodiment, a light-receiving device that can be used for the display apparatus of one embodiment of the present invention and a display apparatus having a light-emitting and light-receiving function will be described.

### [Light-Receiving Device]

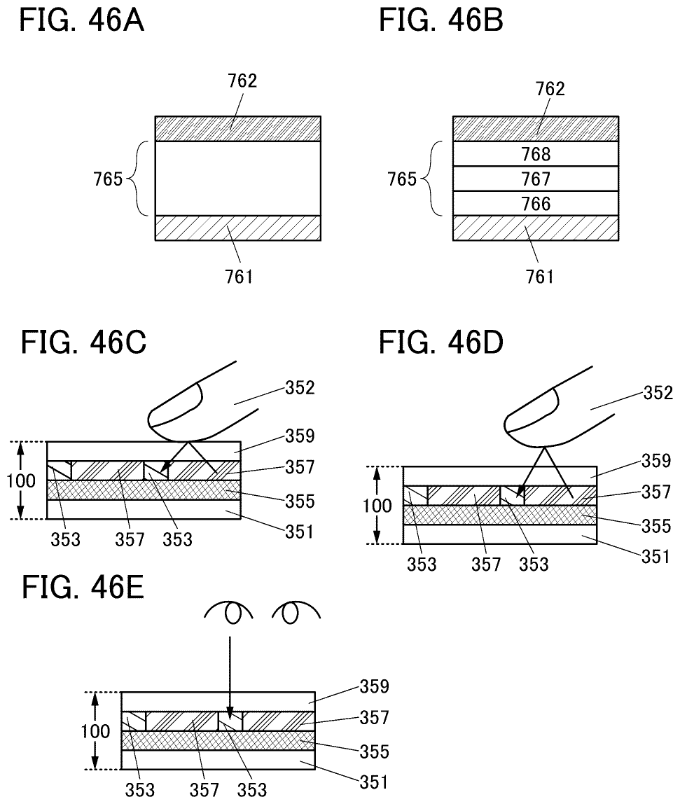

As illustrated in FIG. 46A, the light-receiving device includes a layer 765 between a pair of electrodes (the lower electrode 761 and the upper electrode 762). The layer 765 includes at least one active layer, and may further include another layer.

FIG. 46B is a variation example of the EL layer 765 included in the light-receiving device illustrated in FIG. 46A. Specifically, the light-receiving device illustrated in FIG. 46B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the structures of the layer 766 and the layer 768 are replaced with each other.

Next, materials that can be used for the light-receiving device will be described.

Either a low molecular compound or a high molecular compound can be used for the light-receiving device, and an inorganic compound may also be contained. Each layer included in the light-receiving device can be formed by an evaporation method (including a vacuum evaporation method), a transfer method, a printing method, an inkjet method, a coating method, or the like.

The active layer included in the light-receiving device includes a semiconductor. Examples of the semiconductor include an inorganic semiconductor such as silicon and an organic semiconductor including an organic compound. This embodiment describes an example where an organic semiconductor is used as the semiconductor included in the active layer. The use of an organic semiconductor is preferable because the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ and C₇₀) and fullerene derivatives. Examples of the fullerene derivative include [6,6]-Phenyl-C₇₁-butyric acid methyl ester (abbreviation: PC70BM), [6,6]-Phenyl-C₆₁-butyric acid methyl ester (abbreviation: PC60BM), and 1′,1″,4′,4″-Tetrahydro-di[1,4]methanonaphthaleno[1,2:2′,3′,56,60:2″,3″][5,6]fullerene-C₆₀ (abbreviation: ICBA).

Other examples of an n-type semiconductor material include perylenetetracarboxylic acid derivatives such as N,N-dimethyl-3,4,9,10-perylenetetracarboxylic diimide (abbreviation: Me-PTCDI) and 2,2′-(5,5′-(thieno[3,2-b]thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin phthalocyanine (SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of similar kinds, which have molecular orbital energy levels close to each other, can increase the carrier-transport property.

For the active layer, a high molecular compound such as poly[[4,8-bis[5-(2-ethylhexyl)-2-thienyl]benzo[1,2-b:4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

Three or more kinds of materials may be used for the active layer. For example, a third material may be used in addition to an n-type semiconductor material and a p-type semiconductor material in order to extend the wavelength range. The third material may be a low molecular compound or a high molecular compound.

In addition to the active layer, the light-receiving device may further include a layer containing a substance with a high hole-transport property, a substance with a high electron-transport property, a substance with a bipolar property (a substance with a high electron-transport property and a high hole-transport property), or the like. Without limitation to the above, the light-receiving device may further include a layer containing a substance with a high hole-injection property, a hole-blocking material, a substance with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/poly(styrenesulfonic acid (abbreviation: PEDOT/PSS), or an inorganic compound such as molybdenum oxide or copper iodide (CuI) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, a biometric authentication device, a capacitive touch panel for scroll operation, or the like is not necessarily provided separately from the electronic device. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus using the organic EL device.

In the display apparatus including a light-emitting device and a light-receiving device in each pixel, the pixel has a light-receiving function; thus, the display apparatus can detect a contact or approach of an object while displaying an image. For example, all the subpixels included in the display apparatus can display an image; alternatively, some of the subpixels can emit light as a light source, and the other subpixels can display an image.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Thus, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the approach or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be controlled without an object directly contacting with the display apparatus. In other words, the display apparatus can be controlled in a contactless (touchless) manner. With the above structure, the display apparatus can have a reduced risk of being dirty or damaged, or can be operated without the object directly contacting with a dirt (e.g., dust or a virus) attached to the display apparatus.

The refresh rate can be variable in the display apparatus of one embodiment of the present invention. For example, the refresh rate is adjusted (adjusted in the range from 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display apparatus 100 illustrated in FIG. 46C to FIG. 46E includes a layer 353 including a light-receiving device, a functional layer 355, and a layer 357 including a light-emitting device, between a substrate 351 and a substrate 359.

The functional layer 355 includes a circuit for driving a light-receiving device and a circuit for driving a light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure including neither a switch nor a transistor may be employed.

For example, after light emitted by the light-emitting device in the layer 357 including the light-emitting device is reflected by a finger 352 in contact with the display apparatus 100 as illustrated in FIG. 46C, the light-receiving device in the layer 353 including the light-receiving device detects the reflected light. Thus, the contact of the finger 352 with the display apparatus 100 can be detected.

Alternatively, the display apparatus may have a function of detecting an object that is approaching (but is not in contact with) the display apparatus as illustrated in FIG. 46D and FIG. 46E or capturing an image of such an object. FIG. 46D illustrates an example where a human finger is detected, and FIG. 46E illustrates an example where information on the periphery, surface, or inside of the human eye (e.g., the number of blinks, movement of an eyeball, and movement of an eyelid) is detected.

This embodiment can be combined with the other embodiments as appropriate.

### Embodiment 7

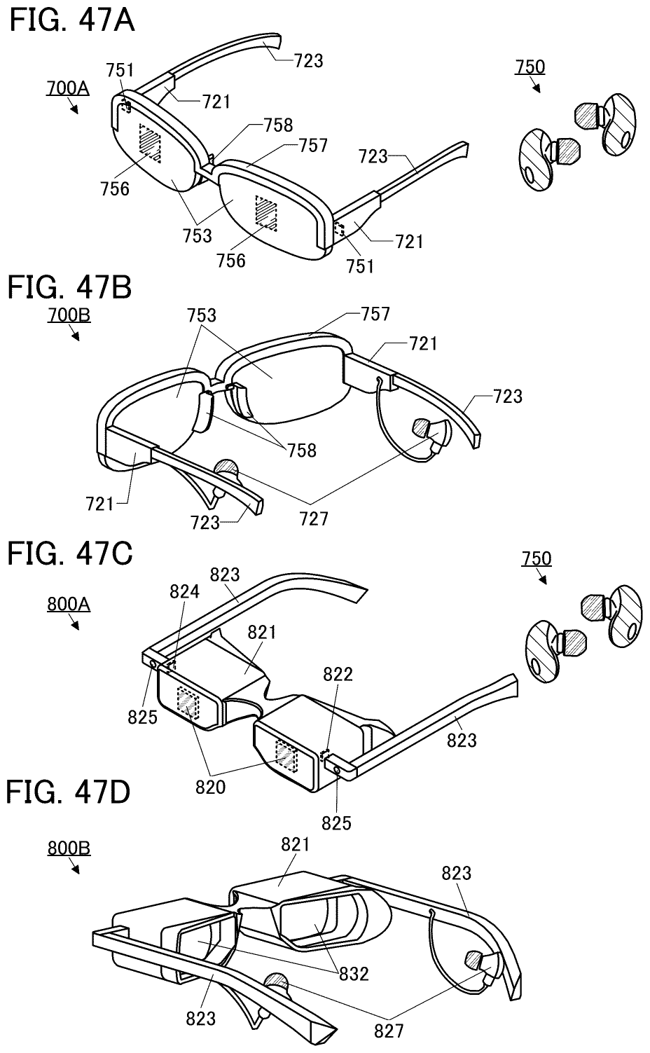

In this embodiment, electronic devices of one embodiment of the present invention will be described with reference to FIG. 47 to FIG. 49.

Electronic devices of this embodiment each include the display apparatus of one embodiment of the present invention in a display portion. The display apparatus of one embodiment of the present invention can be easily increased in definition and resolution. Thus, the display apparatus of one embodiment of the present invention can be used for a display portion of a variety of electronic devices.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine such as a pachinko machine.

In particular, the display apparatus of one embodiment of the present invention can have high definition, and thus can be suitably used for an electronic device including a relatively small display portion. Examples of such an electronic device include watch-type and bracelet-type information terminal devices (wearable devices) and wearable devices capable of being worn on a head, such as a VR device like a head-mounted display, a glasses-type AR device, and an MR device.

The resolution of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the resolution is preferably 4K, 8K, or higher. The pixel density (definition) of the display apparatus of one embodiment of the present invention is preferably 100 ppi or higher, further preferably 300 ppi or higher, further preferably 500 ppi or higher, further preferably 1000 ppi or higher, still further preferably 2000 ppi or higher, still further preferably 3000 ppi or higher, still further preferably 5000 ppi or higher, yet further preferably 7000 ppi or higher. With use of the display apparatus having one or both of such high resolution and high definition, electronic devices for portable use and home use can have higher realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 47A to FIG. 47D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher sense of immersion.

An electronic device 700A illustrated in FIG. 47A and an electronic device 700B illustrated in FIG. 47B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display apparatus of one embodiment of the present invention can be used for the display panels 751. Thus, the electronic device can perform display with extremely high definition.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

The electronic device 700A and the electronic device 700B are provided with a battery so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (photoelectric conversion element) can be used as a light-receiving device. One or both of an inorganic semiconductor and an organic semiconductor can be used for an active layer of the photoelectric conversion device.

An electronic device 800A illustrated in FIG. 47C and an electronic device 800B illustrated in FIG. 47D each include a pair of display portions 820, a housing 821, a communication portion 822, a pair of wearing portions 823, a control portion 824, a pair of image capturing portions 825, and a pair of lenses 832.

The display apparatus of one embodiment of the present invention can be used for the display portions 820. Thus, the electronic device can perform display with extremely high definition. This enables a user to feel high sense of immersion.

The display portions 820 are provided at a position inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B preferably include a mechanism for adjusting focus by changing the distance between the lenses 832 and the display portions 820.

The electronic device 800A or the electronic device 800B can be mounted on the user's head with the wearing portions 823. FIG. 47C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 47A has a function of transmitting information to the earphones 750 with the wireless communication function. As another example, the electronic device 800A in FIG. 47C has a function of transmitting information to the earphones 750 with the wireless communication function.

The electronic device may include an earphone portion. The electronic device 700B illustrated in FIG. 47B includes earphone portions 727. For example, the earphone portion 727 and the control portion can be connected to each other by wire. Part of a wiring that connects the earphone portion 727 and the control portion may be positioned inside the housing 721 or the wearing portion 723.

Similarly, the electronic device 800B illustrated in FIG. 47D includes earphone portions 827. For example, the earphone portion 827 and the control portion 824 can be connected to each other by wire. Part of a wiring that connects the earphone portion 827 and the control portion 824 may be positioned inside the housing 821 or the wearing portion 823. Alternatively, the earphone portions 827 and the wearing portions 823 may include magnets. This is preferred because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are preferable as the electronic device of one embodiment of the present invention.

The electronic device of one embodiment of the present invention can transmit information to earphones by wire or wirelessly.

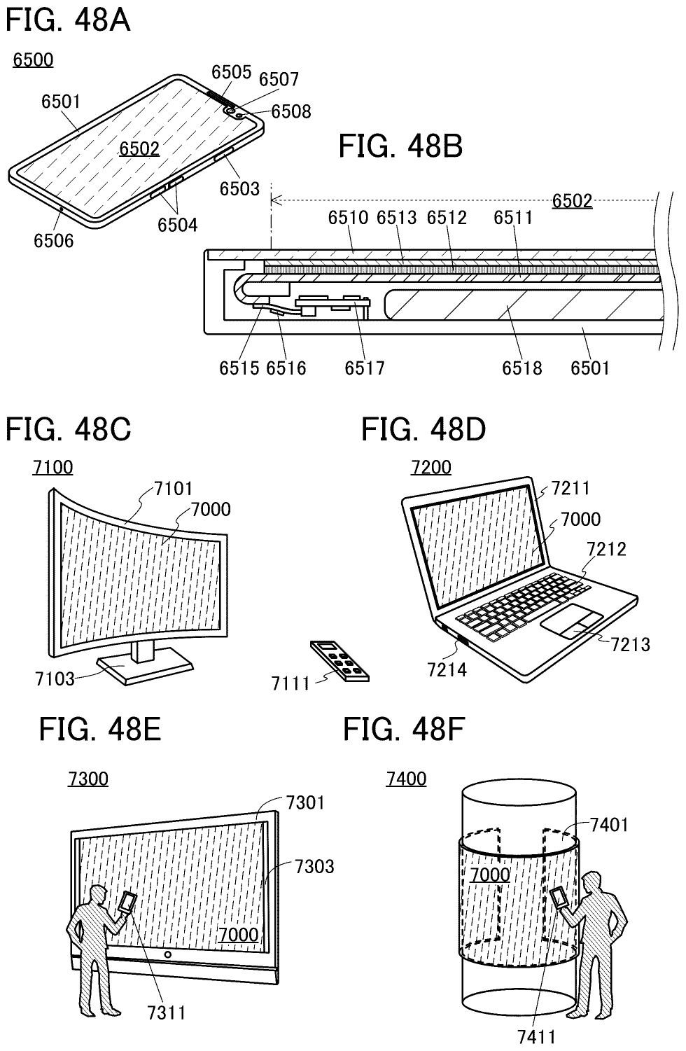

An electronic device 6500 illustrated in FIG. 48A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 48B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while an increase in thickness of the electronic device is suppressed. Moreover, part of the display panel 6511 is folded back so that a connection portion with the FPC 6515 is provided on the back side of the pixel portion, whereby an electronic device with a narrow bezel can be obtained.

FIG. 48C illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 48C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 48D illustrates an example of a laptop personal computer. A laptop personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 48E and FIG. 48F illustrate examples of digital signage.

Digital signage 7300 illustrated in FIG. 48E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 48F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 48E and FIG. 48F.

A larger area of the display portion 7000 can increase the amount of information that can be provided at a time. The larger the display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 48E and FIG. 48F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

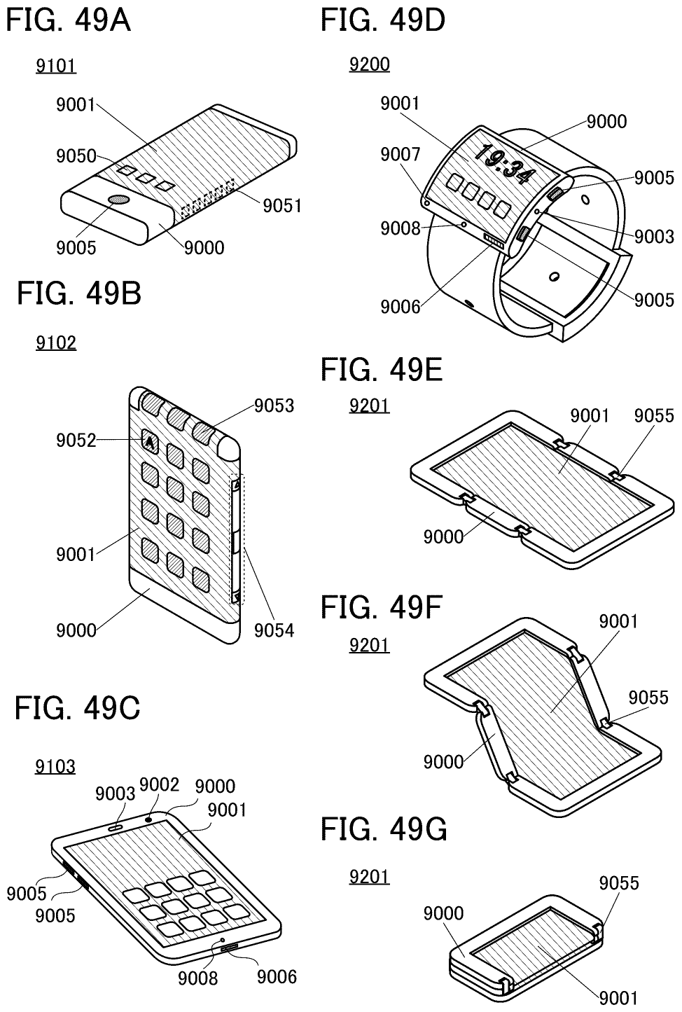

Electronic devices illustrated in FIG. 49A to FIG. 49G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. The display apparatus of one embodiment of the present invention can be used in the display portion 9001.

The electronic devices illustrated in FIG. 49A to FIG. 49G have a variety of functions. For example, the electronic devices can have a function of displaying a variety of data (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 49A to FIG. 49G are described in detail below.

FIG. 49A is a perspective view illustrating a portable information terminal 9101. For example, the portable information terminal 9101 can be used as a smartphone. Note that the portable information terminal 9101 may be provided with the speaker 9003, the connection terminal 9006, the sensor 9007, or the like. The portable information terminal 9101 can display characters and image information on its plurality of surfaces. FIG. 49A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 49B is a perspective view illustrating a portable information terminal 9102. The portable information terminal 9102 has a function of displaying information on three or more surfaces of the display portion 9001. Illustrated here is an example where information 9052, information 9053, and information 9054 are displayed on different surfaces. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 49C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 49D is a perspective view illustrating a watch-type portable information terminal 9200. For example, the portable information terminal 9200 can be used for a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 49E to FIG. 49G are perspective views illustrating a foldable portable information terminal 9201. FIG. 49E is a perspective view of an opened state of the portable information terminal 9201, FIG. 49G is a perspective view of a folded state thereof, and FIG. 49F is a perspective view of a state in the middle of change from one of FIG. 49E and FIG. 49G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### REFERENCE NUMERALS

100A: display apparatus, 100B: display apparatus, 100C: display apparatus, 100: display apparatus, 101: layer, 110a: subpixel, 110A: pixel, 110b: subpixel, 110B: pixel, 110c: subpixel, 110d: subpixel, 110e: subpixel, 110: pixel, 111B: pixel electrode, 111G: pixel electrode, 111R: pixel electrode, 111S: pixel electrode, 111: pixel electrode, 113_1: first region, 113_2: second 5 region, 113B: layer, 113Bf: film, 113G: layer, 113Gf: film, 113R: layer, 113Rf: film, 113S: layer, 113W: layer, 113: layer, 114: common layer, 115: common electrode, 117: light-blocking layer, 118B: mask layer, 118Bf: mask film, 118G: mask layer, 118Gf: mask film, 118R: mask layer, 118Rf: mask film, 118S: mask layer, 118: mask layer, 119B: mask layer, 119Bf: mask film, 119G: mask layer, 119Gf: mask film, 119R: mask layer, 119Rf: mask film, 119S: mask layer, 119: mask layer, 120: substrate, 122: resin layer, 123: conductive layer, 124B: conductive layer, 124G: conductive layer, 124p: conductive layer, 124R: conductive layer, 124S: conductive layer, 125f: insulating film, 125: insulating layer, 126B: conductive layer, 126f: conductive film, 126G: conductive layer, 126p: conductive layer, 126R: conductive layer, 126S: conductive layer, 127f: insulating film, 127: insulating layer, 128f: film, 128: layer, 129aB: conductive layer, 129af: conductive film, 129aG: conductive layer, 129aR: conductive layer, 129B: conductive layer, 129bB: conductive layer, 129bf: conductive film, 129bG: conductive layer, 129bR: conductive layer, 129G: conductive layer, 129p: conductive layer, 129R: conductive layer, 129S: conductive layer, 130B: light-emitting device, 130G: light-emitting device, 130R: light-emitting device, 130: light-emitting device, 131: protective layer, 132B: coloring layer, 132c: mask, 132G: coloring layer, 132R: coloring layer, 140: connection portion, 141: opening, 142: adhesive layer, 143: opening, 150: light-receiving device, 151: substrate, 152: substrate, 153: insulating layer, 162: display portion, 164: circuit, 165: wiring, 166: conductive layer, 172: FPC, 173: IC, 190a: resist mask, 190b: resist mask, 190c: resist mask, 191S: opening, 191: opening, 193S: opening, 193: opening, 195: opening, 200A: transistor, 200B: transistor, 200C: transistor, 200D: transistor, 200: transistor, 201: transistor, 204: connection portion, 205B: transistor, 205G: transistor, 205R: transistor, 205S: transistor, 205: transistor, 210a: insulating layer, 210a_1: insulating layer, 210a_2: insulating layer, 210af: insulating film, 210b: insulating layer, 210bf: insulating film, 210c: insulating layer, 210cf: insulating film, 210f: insulating film, 210: insulating layer, 218f: insulating film, 218: insulating layer, 222a: conductive layer, 222B: conductive layer, 222b: conductive layer, 222f: conductive film, 223: conductive layer, 225: insulating layer, 231f: metal oxide film, 231: semiconductor layer, 235: insulating layer, 239f: insulating film, 239: insulating layer, 242: connection layer, 249: metal oxide layer, 351: substrate, 352: finger, 353: layer, 355: functional layer, 357: layer, 359: substrate, 700A: electronic device, 700B: electronic device, 721: housing, 723: wearing portion, 727: earphone portion, 750: earphone, 751: display panel, 753: optical member, 756: display region, 757: frame, 758: nose pad, 761: lower electrode, 762: upper electrode, 763a: light-emitting unit, 763b: light-emitting unit, 763c: light-emitting unit, 763: EL layer, 764: layer, 765: layer, 766: layer, 767: active layer, 768: layer, 771a: light-emitting layer, 771b: light-emitting layer, 771c: light-emitting layer, 771: light-emitting layer, 772a: light-emitting layer, 772b: light-emitting layer, 772c: light-emitting layer, 772: light-emitting layer, 773: light-emitting layer, 780a: layer, 780b: layer, 780c: layer, 780: layer, 781: layer, 782: layer, 785: charge-generation layer, 790a: layer, 790b: layer, 790c: layer, 790: layer, 791: layer, 792: layer, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A display apparatus comprising:
a transistor;
a light-emitting device; and
a first insulating layer,
the transistor comprising:
a semiconductor layer;
a first conductive layer;
a second conductive layer;
a third conductive layer;
a second insulating layer; and
a third insulating layer,
wherein the second insulating layer is over the first conductive layer,
wherein the second insulating layer comprises a first opening reaching the first conductive layer,
wherein the second conductive layer is over the second insulating layer,
wherein the second conductive layer comprises a second opening in a region overlapping with the first opening,
wherein the semiconductor layer is in contact with a top surface of the first conductive layer, a side surface of the second insulating layer, and a top surface and a side surface of the second conductive layer,
wherein the third insulating layer is over the semiconductor layer,
wherein the third conductive layer is over the third insulating layer,
wherein the first insulating layer is over the transistor,
wherein the first insulating layer and the third insulating layer comprise a third opening reaching the second conductive layer,
wherein the light-emitting device is over the first insulating layer,
wherein the light-emitting device comprises a pixel electrode, a common electrode, and an EL layer interposed between the pixel electrode and the common electrode,
wherein the pixel electrode is electrically connected to the second conductive layer through the third opening, and
wherein the EL layer comprises a region in contact with a top surface and a side surface of the pixel electrode.

2. The display apparatus according to claim 1,
wherein the second insulating layer has a stacked-layer structure of a fourth insulating layer and a fifth insulating layer over the fourth insulating layer, and
wherein the fifth insulating layer comprises a region having a higher film density than the fourth insulating layer.

3. The display apparatus according to claim 1,
wherein the second insulating layer has a stacked-layer structure of a fourth insulating layer and a fifth insulating layer over the fourth insulating layer, and
wherein the fifth insulating layer comprises a region having a higher nitrogen content than the fourth insulating layer.

4. The display apparatus according to claim 2,
wherein the second insulating layer comprises a sixth insulating layer,
wherein the sixth insulating layer is positioned between the fourth insulating layer and the first conductive layer, and
wherein the sixth insulating layer comprises a region having a higher film density than the fifth insulating layer.

5. The display apparatus according to claim 2,
wherein the second insulating layer comprises a sixth insulating layer,
wherein the sixth insulating layer is positioned between the fourth insulating layer and the first conductive layer, and
wherein the sixth insulating layer comprises a region having a higher nitrogen content than the fifth insulating layer.

6. The display apparatus according to claim 3,
wherein the second insulating layer comprises a sixth insulating layer,
wherein the sixth insulating layer is positioned between the fourth insulating layer and the first conductive layer, and
wherein the sixth insulating layer comprises a region having a higher film density than the fifth insulating layer.

7. The display apparatus according to claim 3,
wherein the second insulating layer comprises a sixth insulating layer,
wherein the sixth insulating layer is positioned between the fourth insulating layer and the first conductive layer, and
wherein the sixth insulating layer comprises a region having a higher nitrogen content than the fifth insulating layer.

8. The display apparatus according to claim 1, further comprising a layer,
wherein the pixel electrode comprises a fourth conductive layer and a fifth conductive layer over the fourth conductive layer,
wherein the fourth conductive layer covers a top surface of the first insulating layer and the third opening,
wherein the fourth conductive layer comprises a concave portion along a shape of a side surface of the first insulating layer and the top surface of the second conductive layer,
wherein the layer is provided to fill the concave portion, and
wherein the fifth conductive layer covers a top surface of the fourth conductive layer and a top surface of the layer.

9. The display apparatus according to claim 8,
wherein the layer is an insulating layer.

10. The display apparatus according to claim 8,
wherein the layer is a conductive layer.

11. The display apparatus according to claim 1, further comprising a seventh insulating layer and an eighth insulating layer,
wherein the seventh insulating layer covers a side surface and a part of a top surface of the EL layer,
wherein the eighth insulating layer covers the side surface and the part of the top surface of the EL layer with the seventh insulating layer therebetween, and
wherein the common electrode covers the eighth insulating layer.

12. The display apparatus according to claim 11,
wherein the seventh insulating layer comprises an inorganic material, and
wherein the eighth insulating layer comprises an organic material.
